(19) United States
(12) Patent Application Publication
(10) Pub. No.: US 2017/0222163 A1
(43) Pub. Date: Aug. 3, 2017

(54) LIGHT-EMITTING DEVICE

(71) Applicants: Sumitomo Chemical Company, Limited, Chuo-ku, Tokyo (JP); Cambridge Display Technology Limited, Cambridgeshire (GB)

(72) Inventors: Makoto ANRYU, Osaka-shi, Osaka (JP); Simon KING, Cambridgeshire (GB); Annette Regine STEUDEL, Dresden (DE); Martin John HUMPHRIES, Cambridgeshire (GB)

(21) Appl. No.: 15/515,225

(22) PCT Filed: Sep. 25, 2015
(86) PCT No.: PCT/JP2015/077113

§ 371 Date: Mar. 29, 2017

(30) Foreign Application Priority Data
Sep. 30, 2014 (JP) 2014-201264

(51) Int. Cl. H01L 51/00; C09K 11/06; C08G 61/12; C09K 11/02

(52) U.S. Cl. CPC H01L 51/0085; C09K 11/025; C09K 11/06; H01L 51/0039; H01L 51/0043; C08G 61/128; H01L 51/5016

(57) ABSTRACT

A light-emitting device having an anode, a cathode, a first organic layer disposed between the anode and the cathode, and a second organic layer disposed between the anode and the first organic layer and adjacent to the first organic layer is provided. The first organic layer contains a phosphorescent compound of formula (1), and the second organic layer contains a crosslinked body formed from a polymer compound having a crosslinkable group in which the average number of the crosslinkable groups in the polymer compound per molecular weight of 1000 is at least 0.5.

### TECHNICAL FIELD

The present invention relates to a light-emitting device.

### BACKGROUND ART

Light-emitting devices such as organic electroluminescence devices (organic EL devices), because having properties such as a high external quantum efficiency and a low-voltage drive, can suitably be used in applications of display and illumination, and have recently attracted attention. The light-emitting devices comprise organic layers such as a light emitting layer and a charge transporting layer.

Patent Literatures 1 and 2 describe light-emitting devices comprising a light emitting layer formed by using a blue phosphorescent compound having a ligand formed from a 6-membered ring and a 5-membered ring, and a hole transporting layer formed by using a polymer compound comprising an aromatic amine constitutional unit and a crosslinkable constitutional unit.

The blue phosphorescent compound described in Patent Literature 2 is a phosphorescent compound represented by the following formula. The polymer compound comprising an aromatic amine constitutional unit and a crosslinkable constitutional unit described in Patent Literature 2 is a polymer compound represented by the following formula. The value of (Y₁×1000)/X₁ described later of the polymer compound is calculated, and is 0.09.

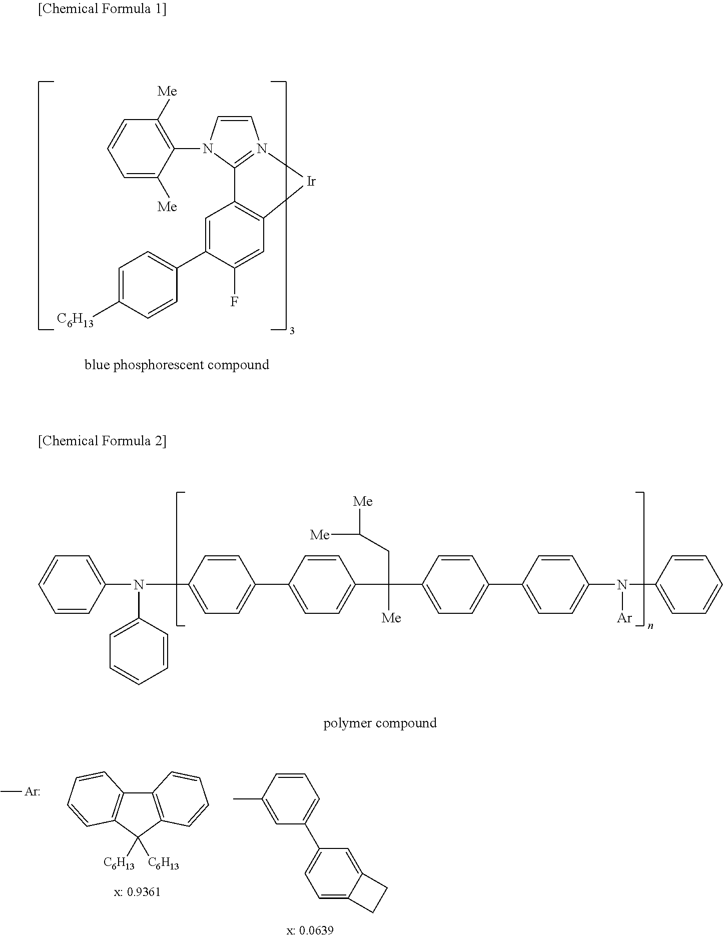

### CITATION LIST

### Patent Literature

Patent Literature 1: International Publication No. WO2013/191086

Patent Literature 2: Japanese Unexamined Patent Publication No. 2013-216789

### SUMMARY OF INVENTION

### Technical Problem

As a light-emitting device, one having an excellent external quantum efficiency is demanded. Then, the present invention has an object to provide a light-emitting device excellent in the external quantum efficiency.

### Solution to Problem

One aspect of the present invention relates to the following light-emitting devices.

[1] A light-emitting device comprising an anode, a cathode, a first organic layer disposed between the anode and the cathode, and a second organic layer disposed between the anode and the first organic layer and adjacent to the first organic layer,

wherein the first organic layer comprises a phosphorescent compound represented by the formula (1);

the second organic layer comprises a cured polymer product formed from a polymer composition in which one or two or more polymer compounds including a crosslinkable polymer compound having a crosslinkable group compounded; and

with respect to each monomer unit constituting the polymer compounds, a value x obtained by multiplying a molar ratio C of the each monomer unit to a total mol of all the monomer units by a molecular weight M of the each monomer unit, and a value y obtained by multiplying the molar ratio C by a number n of the crosslinkable groups in the each monomer unit are determined, a value of (Y₁×1000)/X₁ calculated from a total X₁ of the values x and a total Y₁ of the values y being 0.5 or more:

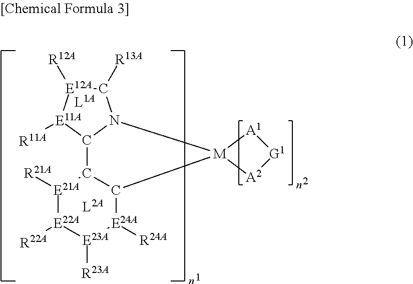

wherein,

M represents a ruthenium atom, a rhodium atom, a palladium atom, an iridium atom or a platinum atom;

n¹ represents an integer of 1 to 3, n² represents an integer of 0 to 2, and n¹+n² is 2 or 3; and n¹+n² is 3 when M is a ruthenium atom, a rhodium atom or an iridium atom, while n¹+n² is 2 when M is a palladium atom or a platinum atom;

E^{11A}, E^{12A}, E^{21A}, E^{22A}, E^{23A} and E^{24A} each independently represent a nitrogen atom or a carbon atom; when a plurality of E^{11A}, E^{12A}, E^{21A}, E^{22A}, E^{23A} and E^{24A} are present, they may be the same or different at each occurrence, provided that one of E^{11A} and E^{12A} is a carbon atom and the other is a nitrogen atom; and when E^{21A}, E^{22A}, E^{23A} and E^{24A} are nitrogen atoms, R^{21A}, R^{22A}, R^{23A} and R^{24A} are not present; R^{11A}, R^{12A}, R^{13A}, R^{21A}, R^{22A}, R^{23A} and R^{24A} each independently represent a hydrogen atom, an alkyl group, a cycloalkyl group, an alkoxy group, a cycloalkoxy group, an aryl group, an aryloxy group, a monovalent heterocyclic group, a substituted amino group or a halogen atom, and these groups each optionally have a substituent; when a plurality of R^{11A}, R^{12A}, R^{13A}, R^{21A}, R^{22A}, R^{23A} and R^{24A} are present, they may be the same or different at each occurrence; and R^{11A} and R^{12A}, R^{12A} and R^{13A}, R^{11A} and R^{21A}, R^{21A} and R^{22A}, R^{22A} and R^{23A}, and R^{23A} and R^{24A} each may be combined together to form a ring together with the atoms to which they are attached;

a ring L^{1A} represents an imidazole ring constituted of a nitrogen atom, two carbon atoms, E^{11A} and E^{12A};

a ring L^{2A} represents a benzene ring, a pyridine ring or a pyrimidine ring constituted of two carbon atoms, E^{21A}, E^{22A}, E^{23A} and E^{24A}; and

A¹-G¹-A² represents an anionic bidentate ligand; A¹ and A² each independently represent a carbon atom, an oxygen atom or a nitrogen atom, and these atoms may be atoms constituting a ring; G¹ represents a single bond, or an atomic group constituting the bidentate ligand together with A¹ and A²; and when a plurality of A¹-G¹-A² are present, they may be the same or different at each occurrence.

[2] The light-emitting device according to [1], wherein the value of (Y₁×1000)/X₁ is 0.65 or more.
[3] The light-emitting device according to [1] or [2], wherein at least one selected from the group consisting of the R^{11A}, R^{12A}, R^{13A}, R^{21A}, R^{22A}, R^{23A} and R^{24A} is a group represented by the formula (D-A) or (D-B):

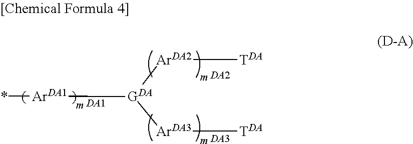

wherein,

m^{DA1}, m^{DA2} and m^{DA3} each independently represent an integer of 0 or more;

G^{DA} represents a nitrogen atom, an aromatic hydrocarbon group or a heterocyclic group, and these groups each optionally have a substituent;

Ar^{DA1}, Ar^{DA2} and Ar^{DA3} each independently represent an arylene group or a divalent heterocyclic group, and these groups each optionally have a substituent; and when a plurality of Ar^{D}, Ar^{D} and Ar^{DA} are present, they may be the same or different at each occurrence; and

T^{DA} represents an aryl group or a monovalent heterocyclic group, and these groups each optionally have a substituent; and the plurality of T^{DA} may be the same or different; and

* represents a bonding position, and

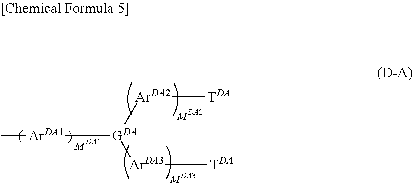

wherein,

m^{DA1}, m^{DA2}, m^{DA3}, m^{DA4}, m^{DA5}, m^{DA6} and m^{DA7} each independently represent an integer of 0 or more;

G^{DA} represents a nitrogen atom, an aromatic hydrocarbon group or a heterocyclic group, and these groups each optionally have a substituent, and the plurality of G^{DA} may be the same or different;

Ar^{DA1}, Ar^{DA2}, Ar^{DA3}, Ar^{DA4}, Ar^{DA5}, Ar^{DA6} and Ar^{DA7} each independently represent an arylene group or a divalent heterocyclic group, and these groups each optionally have a substituent; and when a plurality of Ar^{DA1}, Ar^{DA2}, Ar^{DA3}, Ar^{DA4}, Ar^{DA5}, Ar^{DA6} and Ar^{DA7} are present, they may be the same or different at each occurrence; and

T^{DA} represents an aryl group or a monovalent heterocyclic group, and these groups each optionally have a substituent, and the plurality of T^{DA} may be the same or different; and

* represents a bonding position.

[4] The light-emitting device according to any of [1] to [3], wherein the phosphorescent compound is represented by the formula (1-1) or (1-2):

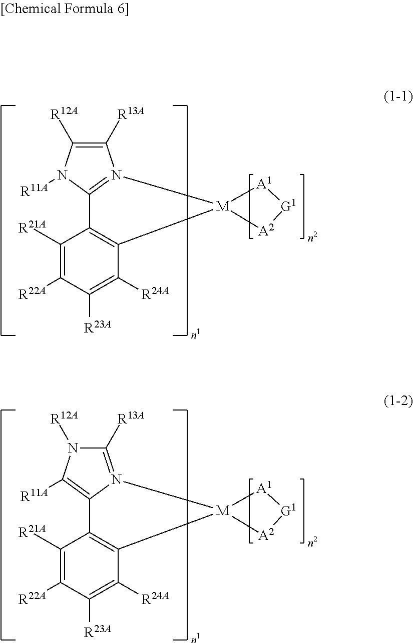

wherein M, n¹, n², R^{11A}, R^{12A}, R^{13A}, R^{21A}, R^{22A}, R^{23A} and R^{24A} and A¹-G¹-A² represent the same meanings as described above.
[5] The light-emitting device according to any of [1] to [4], wherein the crosslinkable polymer compound comprises a constitutional unit represented by the formula (2):

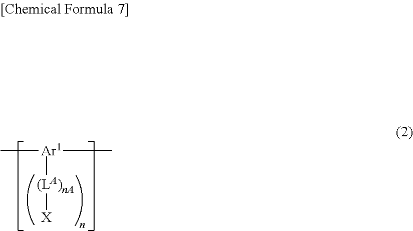

wherein,

nA represents an integer of 0 to 5, and n represents 1 or 2;

Ar¹ represents an aromatic hydrocarbon group or a heterocyclic group, and these groups each optionally have a substituent;

L^{A} represents an alkylene group, a cycloalkylene group, an arylene group, a divalent heterocyclic group, a group represented by —NR′—, an oxygen atom or a sulfur atom, and these groups each optionally have a substituent; R′ represents a hydrogen atom, an alkyl group, a cycloalkyl group, an aryl group or a monovalent heterocyclic group, and these groups each optionally have a substituent: and when a plurality of L^{A} are present, they may be the same or different; and

X represents a crosslinkable group, and when a plurality of X are present, they may be the same or different.

[6] The light-emitting device according to any of [1] to [5], wherein the crosslinkable polymer compound comprises a constitutional unit represented by the formula (3):

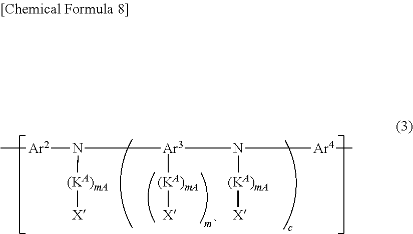

wherein,

mA represents an integer of 0 to 5, m represents an integer of 1 to 4, c represents 0 or 1, and when a plurality of mA are present, they may be the same or different;

Ar³ represents an aromatic hydrocarbon group, a heterocyclic group or a group in which at least one aromatic hydrocarbon ring and at least one heterocyclic ring are bonded directly to each other, and these groups each optionally have a substituent;

Ar² and Ar⁴ each independently represent an arylene group or a divalent heterocyclic group, and these groups each optionally have a substituent;

each of Ar², Ar³ and Ar⁴ may be bonded directly or via an oxygen atom or a sulfur atom to a group that is different from that group and that is attached to the nitrogen atom to which that group is attached, thereby forming a ring;

K^{A} represents an alkylene group, a cycloalkylene group, an arylene group, a divalent heterocyclic group, a group represented by —NR″—, an oxygen atom or a sulfur atom, and these groups each optionally have a substituent; and R″ represents a hydrogen atom, an alkyl group, a cycloalkyl group, an aryl group or a monovalent heterocyclic group, and these groups each optionally have a substituent; and when a plurality of K^{A} are present, they may be the same or different; and

X′ represents a crosslinkable group, a hydrogen atom, an alkyl group, a cycloalkyl group, an aryl group or a monovalent heterocyclic group, and these groups each optionally have a substituent; and when a plurality of X′ are present, they may be the same or different; provided that at least one X′ is a crosslinkable group.

[7] The light-emitting device according to any of [1] to [6], wherein the polymer compound has at least one crosslinkable group selected from Group A of crosslinkable groups;

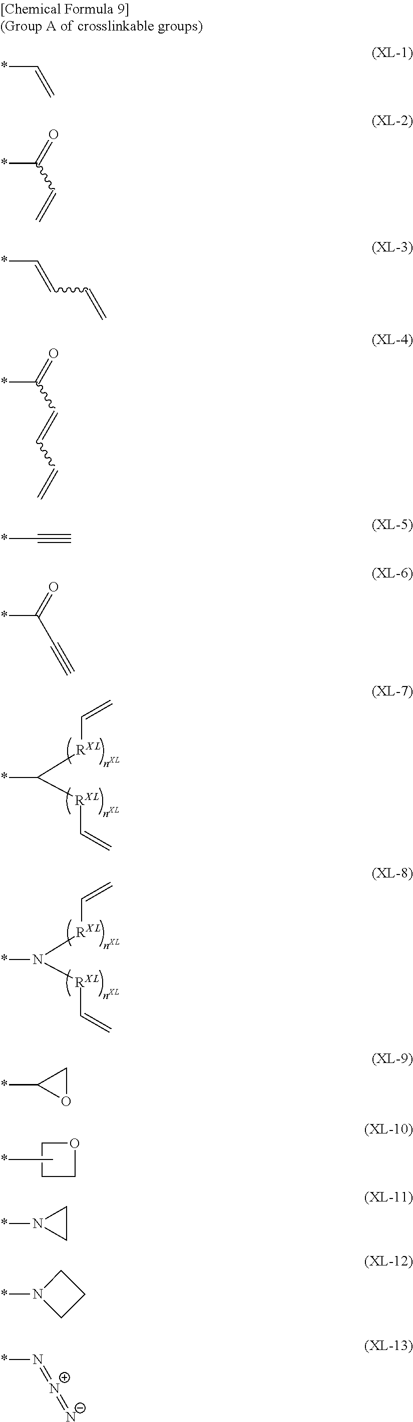

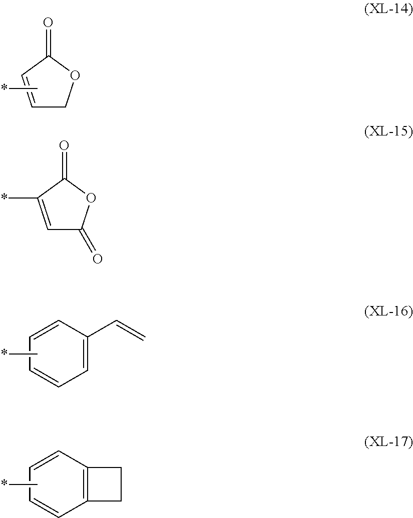

wherein R^{XL} represents a methylene group, an oxygen atom or a sulfur atom, and n^{XL} represents an integer of 0 to 5; when a plurality of R^{XL} are present, they may be the same or different; and when a plurality of n^{XL} are present, they may be the same or different; * represents a bonding position; and these crosslinkable groups each optionally have a substituent.
[8] The light-emitting device according to any of [1] to [7], wherein the first organic layer further comprises a polymer compound comprising a constitutional unit represented by the formula (Y):

[Chemical Formula 10]

Ar^{Y1} (Y)

wherein Ar^{Y1} represents an arylene group, a divalent heterocyclic group, or a divalent group in which at least one arylene group and at least one divalent heterocyclic group are bonded directly to each other, and these groups each optionally have a substituent.
[9] The light-emitting device according to any of [1] to [7], wherein the first organic layer further comprises a compound represented by the formula (H-1):

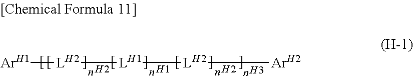

wherein,

Ar^{H1} and Ar^{H2} each independently represent an aryl group or a monovalent heterocyclic group, and these groups each optionally have a substituent;

n and n^{H2} each independently represent 0 or 1; when a plurality of n^{H1} are present, they may be the same or different; and when a plurality of n^{H2} are present, they may be the same or different;

n^{H3} represents an integer of 0 or more;

L^{H1} represents an arylene group, a divalent heterocyclic group or a group represented by —[C(R^{H11})₂]n^{H11}-, and these groups each optionally have a substituent; and when a plurality of L^{H1} are present, they may be the same or different;

n^{H11} represents an integer of 1 to 10; R^{H11} represents a hydrogen atom, an alkyl group, a cycloalkyl group, an alkoxy group, a cycloalkoxy group, an aryl group or a monovalent heterocyclic group, and these groups each optionally have a substituent; the plurality of R^{H11} may be the same or different and may be combined together to form a ring together with the carbon atoms to which they are attached;

L^{H2} represents a group represented by —N(-L^{H21}-R^{H21})—; and when a plurality of L^{H2} are present, they may be the same or different; and

L^{H21} represents a single bond, an arylene group or a divalent heterocyclic group, and these groups each optionally have a substituent; and R^{H21} represents a hydrogen atom, an alkyl group, a cycloalkyl group, an aryl group or a monovalent heterocyclic group, and these groups each optionally have a substituent.

### Advantageous Effects of Invention

According to the present invention, a light-emitting device excellent in the external quantum efficiency can be provided.

### MODES FOR CARRYING OUT THE INVENTION

Suitable embodiments of the present invention will be illustrated in detail below.

<Explanation of Common Term>

Terms commonly used in the present specification have the following meanings unless otherwise stated.

Me represents a methyl group, Et represents an ethyl group, Bu represents a butyl group, i-Pr represents an isopropyl group, and t-Bu represents a tert-butyl group.

A hydrogen atom may be a heavy hydrogen atom or a light hydrogen atom.

In a formula representing a metal complex (for example, in the formula (1) representing a phosphorescent compound), a solid line representing a bond to a central metal denotes a covalent bond or a coordinate bond.

“Polymer compound” denotes a polymer having molecular weight distribution and having a polystyrene-equivalent number average molecular weight of 1×10³ to 1×10⁸.

“Low molecular weight compound” denotes a compound having no molecular weight distribution and having a molecular weight of 1×10⁴ or less.

“Constitutional unit” denotes a unit structure found once or more in a polymer compound.

“Alkyl group” may be any of linear or branched. The number of carbon atoms of the linear alkyl group is, not including the number of carbon atoms of a substituent, usually 1 to 50, preferably 3 to 30, more preferably 4 to 20. The number of carbon atoms of the branched alkyl groups is, not including the number of carbon atoms of a substituent, usually 3 to 50, preferably 3 to 30, more preferably 4 to 20.

The alkyl group includes, for example, a methyl group, an ethyl group, a propyl group, an isopropyl group, a butyl group, an isobutyl group, a tert-butyl group, a pentyl group, an isoamyl group, a 2-ethylbutyl group, a hexyl group, a heptyl group, an octyl group, a 2-ethylhexyl group, a 3-propylheptyl group, a decyl group, a 3,7-dimethyloctyl group, a 2-ethyloctyl group, a 2-hexyldecyl group, a dodecyl group and the like. The alkyl group optionally has a substituent, and examples thereof may be groups obtained by substituting a part or all of hydrogen atoms in alkyl groups with a cycloalkyl group, an alkoxy group, a cycloalkoxy group, an aryl group, a fluorine atom or the like. The alkyl group having a substituent includes, for example, a trifluoromethyl group, a pentafluoroethyl group, a perfluorobutyl group, a perfluorohexyl group, a perfluorooctyl group, a 3-phenylpropyl group, a 3-(4-methylphenyl)propyl group, a 3-(3,5-di-hexylphenyl) propyl group and a 6-ethyloxyhexyl group.

The number of carbon atoms of “Cycloalkyl group” is, not including the number of carbon atoms of a substituent, usually 3 to 50, preferably 3 to 30, more preferably 4 to 20.

The cycloalkyl group includes, for example, a cyclohexyl group, a cyclopentyl group and the like. The cycloalkyl group optionally has a substituent, and examples thereof may be groups obtained by substituting a part or all of hydrogen atoms in cycloalkyl groups with an alkyl group, a cycloalkyl group, an alkoxy group, a cycloalkoxy group, an aryl group, a fluorine atom or the like. The cycloalkyl group having a substituent includes, for example, a cyclohexylmethyl group, a cyclohexylethyl group and the like.

“Aryl group” denotes an atomic group remaining after removing from an aromatic hydrocarbon one hydrogen atom linked directly to a carbon atom constituting the aromatic ring. The number of carbon atoms constituting the aromatic ring in the aryl group is usually 6 to 60, preferably 6 to 20, more preferably 6 to 10.

The aryl group includes, for example, a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, a 4-phenylphenyl group and the like. The aryl group optionally has a substituent, and examples thereof may be groups obtained by substituting a part or all of hydrogen atoms in aryl groups with an alkyl group, a cycloalkyl group, an alkoxy group, a cycloalkoxy group, an aryl group, a fluorine atom or the like.

“Alkoxy group” may be any of linear or branched. The number of carbon atoms of the linear alkoxy group is, not including the number of carbon atoms of a substituent, usually 1 to 40, preferably 4 to 10. The number of carbon atoms of the branched alkoxy group is, not including the number of carbon atoms of a substituent, usually 3 to 40, preferably 4 to 10.

The alkoxy group includes, for example, a methoxy group, an ethoxy group, a propyloxy group, an isopropyloxy group, a butyloxy group, an isobutyloxy group, a tert-butyloxy group, a pentyloxy group, a hexyloxy group, a heptyloxy group, an octyloxy group, a 2-ethylhexyloxy group, a nonyloxy group, a decyloxy group, a 3,7-dimethyloctyloxy group, a lauryloxy group and the like. The alkoxy group optionally has a substituent, and examples thereof may be groups obtained by substituting a part or all of hydrogen atoms in alkoxy groups with a cycloalkyl group, an alkoxy group, a cycloalkoxy group, an aryl group, a fluorine atom or the like.

The number of carbon atoms of “Cycloalkoxy group” is, not including the number of carbon atoms of a substituent, usually 3 to 40, preferably 4 to 10.

The cycloalkoxy group include a cyclohexyloxy group, a cyclopentyloxy group and the like. The cycloalkoxy group optionally has a substituent, and examples thereof may be groups obtained by substituting a part or all of hydrogen atoms in cycloalkoxy groups with an alkyl group, a cycloalkyl group, an alkoxy group, a cycloalkoxy group, an aryl group, a fluorine atom or the like.

“Aryloxy group” denotes an aromatic group in which an aryl group is linked to an oxygen atom. The number of carbon atoms constituting the aromatic ring in the aryloxy group is usually 6 to 60, preferably 6 to 20.

The aryloxy group includes, for example, a phenoxy group, a 1-naphthyloxy group, a 2-naphthyloxy group, a 1-anthracenyloxy group, a 9-anthracenyloxy group, a 1-pyrenyloxy group and the like.

The aryloxy group optionally has a substituent, and examples thereof may be groups obtained by substituting a part or all of hydrogen atoms in aryloxy groups with an alkyl group, a cycloalkyl group, an alkoxy group, a cycloalkoxy group, a fluorine atom or the like.

“p-Valent heterocyclic group” (p represents an integer of 1 or more) denotes an atomic group remaining after removing from a heterocyclic compound p hydrogen atoms among hydrogen atoms directly linked to a carbon atom or a hetero atom constituting the heterocyclic ring or the ring condensed to the heterocyclic ring. Of p-valent heterocyclic groups, “p-valent aromatic heterocyclic groups” as an atomic group remaining after removing from an aromatic heterocyclic compound p hydrogen atoms among hydrogen atoms directly linked to a carbon atom or a hetero atom constituting the heterocyclic ring or the ring condensed to the heterocyclic ring are preferable.

“Aromatic heterocyclic compound” denotes a compound in which the heterocyclic ring itself shows aromaticity such as oxadiazole, thiadiazole, thiazole, oxazole, thiophene, pyrrole, phosphole, furan, pyridine, pyrazine, pyrimidine, triazine, pyridazine, quinoline, isoquinoline, carbazole and dibenzophosphole, and a compound in which an aromatic ring is condensed to the heterocyclic ring even if the heterocyclic ring itself shows no aromaticity such as phenoxazine, phenothiazine, dibenzoborole, dibenzosilole and benzopyran.

The number of carbon atoms constituting the heterocyclic ring and the ring condensed to the heterocyclic ring in the monovalent heterocyclic group is usually 2 to 60, preferably 4 to 20.

The monovalent heterocyclic group includes a thienyl group, a pyrrolyl group, a furyl group, a pyridyl group, a piperidyl group, a quinolinyl group, an isoquinolinyl group, a pyrimidinyl group, a triazinyl group and the like. The monovalent heterocyclic group optionally has a substituent, and examples thereof may be groups obtained by substituting a part or all of hydrogen atoms in monovalent heterocyclic groups with an alkyl group, a cycloalkyl group, an alkoxy group, a cycloalkoxy group, a fluorine atom or the like.

“Halogen atom” denotes a fluorine atom, a chlorine atom, a bromine atom or an iodine atom.

“Amino group” optionally has a substituent, and a substituted amino group is preferable. The substituent which an amino group has is preferably an alkyl group, a cycloalkyl group, an aryl group or a monovalent heterocyclic group.

The substituted amino group includes, for example, a dialkylamino group, a dicycloalkylamino group and a diarylamino group. The amino group includes, for example, a dimethylamino group, a diethylamino group, a diphenylamino group, a bis(4-methylphenyl)amino group, a bis(4-tert-butylphenyl)amino group and a bis(3,5-di-tert-butylphenyl)amino group.

“Alkenyl group” may be any of linear or branched. The number of carbon atoms of the linear alkenyl group, not including the number of carbon atoms of the substituent, is usually 2 to 30, preferably 3 to 20. The number of carbon atoms of the branched alkenyl group, not including the number of carbon atoms of the substituent, is usually 3 to 30, preferably 4 to 20.

The number of carbon atoms of “Cycloalkenyl group”, not including the number of carbon atoms of the substituent, is usually 3 to 30, preferably 4 to 20.

The alkenyl group and cycloalkenyl group include, for example, a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, a 7-octenyl group and the like. The alkenyl group optionally has a substituent, and examples thereof may be groups obtained by substituting a part or all of hydrogen atoms in alkenyl groups with a cycloalkyl group, an alkoxy group, a cycloalkoxy group, an aryl group, a fluorine atom or the like. The cycloalkenyl group optionally has a substituent, and examples thereof may be groups obtained by substituting a part or all of hydrogen atoms in cycloalkenyl groups with an alkyl group, a cycloalkyl group, an alkoxy group, a cycloalkoxy group, an aryl group, a fluorine atom or the like.

“Alkynyl group” may be any of linear or branched. The number of carbon atoms of the alkynyl group, not including the number of carbon atoms of the substituent, is usually 2 to 20, preferably 3 to 20.

The number of carbon atoms of the branched alkynyl group, not including the number of carbon atoms of the substituent, is usually 4 to 30, preferably 4 to 20.

The number of carbon atoms of “Cycloalkynyl group”, not including the number of carbon atoms of the substituent, is usually 4 to 30, preferably 4 to 20.

The alkynyl group and cycloalkynyl group include, for example, an ethynyl group, a 1-propynyl group, a 2-propynyl group, a 2-butynyl group, a 3-butynyl group, a 3-pentynyl group, a 4-pentynyl group, a 1-hexynyl group, a 5-hexynyl group and the like. The alkynyl group optionally has a substituent, and examples thereof may be groups obtained by substituting a part or all of hydrogen atoms in alkynyl groups with a cycloalkyl group, an alkoxy group, a cycloalkoxy group, an aryl group, a fluorine atom or the like. The cycloalkynyl group optionally has a substituent, and examples thereof may be groups obtained by substituting a part or all of hydrogen atoms in cycloalkynyl groups with an alkyl group, a cycloalkyl group, an alkoxy group, a cycloalkoxy group, an aryl group, a fluorine atom or the like.

“Arylene group” denotes an atomic group remaining after removing from an aromatic hydrocarbon two hydrogen atoms linked directly to carbon atoms constituting the aromatic ring. The number of carbon atoms constituting the aromatic ring in the arylene group is usually 6 to 60, preferably 6 to 30, more preferably 6 to 18.

The arylene group includes, for example, a phenylene group, a naphthalenediyl group, an anthracenediyl group, a phenanthrenediyl group, a dihydrophenanthrenediyl group, a naphthacenediyl group, a fluorenediyl group, a pyrenediyl group, a perylenediyl group, a chrysenediyl group and the like. The arylene group optionally has a substituent, and examples thereof may be groups obtained by substituting a part or all of hydrogen atoms in arylene groups with an alkyl group, a cycloalkyl group, an alkoxy group, a cycloalkoxy group, an aryl group, a fluorine atom or the like.

The arylene group is preferably a group represented by the formula (A-1), (A-2), (A-3), (A-4), (A-5), (A-6), (A-7), (A-8), (A-9), (A-10), (A-11), (A-12), (A-13), (A-14), (A-15), (A-16), (A-17), (A-18), (A-19) or (A-20) (hereinafter, referred to as “groups represented by the formulae (A-1) to (A-20)” in some cases).

The arylene group includes groups obtained by linking a plurality of these groups.

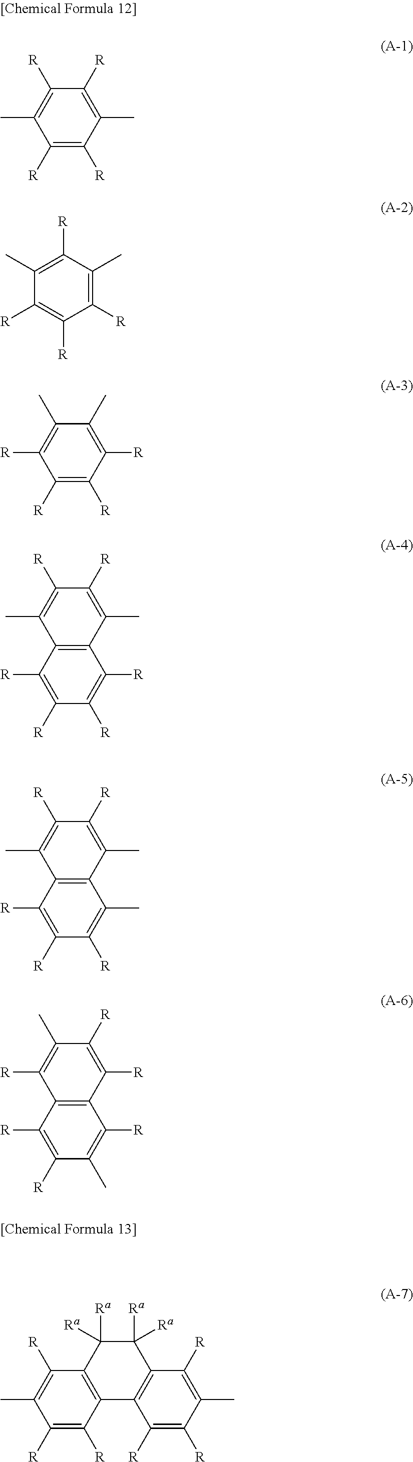

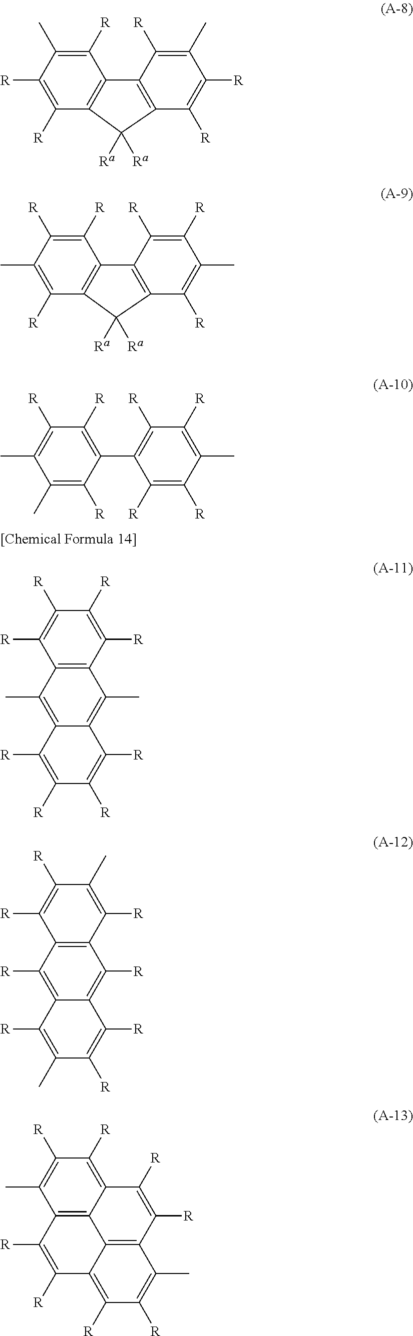

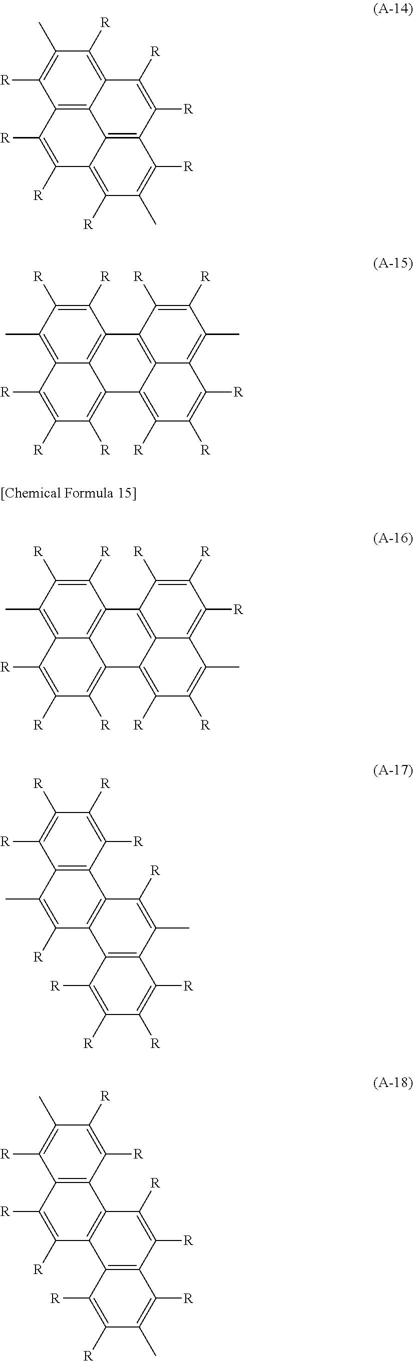

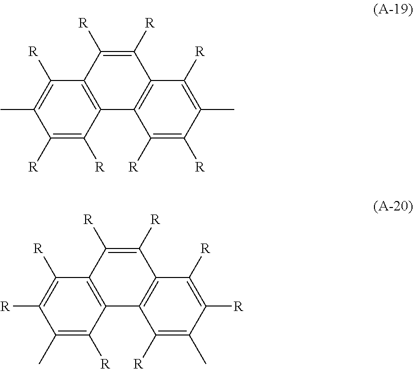

Wherein, R and R^{a} each independently represent a hydrogen atom, an alkyl group, a cycloalkyl group, an aryl group or a monovalent heterocyclic group. The plurality of R and R^{a} each may be the same or different, and groups R^{a} may be combined together to form a ring together with the atoms to which they are attached.

The number of carbon atoms constituting the heterocyclic ring and the ring condensed to the heterocyclic ring in the divalent heterocyclic group is usually 2 to 60, preferably 3 to 20, more preferably 4 to 15.

The divalent heterocyclic group includes, for example, divalent groups obtained by removing from heterocyclic compounds such as pyridine, diazabenzene, triazine, azanaphthalene, diazanaphthalene, carbazole, dibenzofuran, dibenzothiophene, dibenzosilole, phenoxazine, phenothiazine, acridine, dihydroacridine, furan, thiophene, azole, diazole and triazole two hydrogen atoms among hydrogen atoms linking directly to a carbon atom or a hetero atom constituting the heterocyclic ring or the ring condensed to the heterocyclic ring.

The divalent heterocyclic group is preferably a group represented by the formula (AA-1), (AA-2), (AA-3), (AA-4), (AA-5), (AA-6), (AA-7), (AA-8), (AA-9), (AA-10), (AA-11), (AA-12), (AA-13), (AA-14), (AA-15), (AA-16), (AA-17), (AA-18), (AA-19), (AA-20), (AA-21), (AA-22), (AA-23), (AA-24), (AA-25), (AA-26), (AA-27), (AA-28), (AA-29), (AA-30), (AA-31), (AA-32), (AA-33) or (AA-34) (hereinafter, referred to as “groups represented by the formulae (AA-1) to (AA-34)” in some cases). The divalent heterocyclic group includes groups obtained by linking a plurality of these groups.

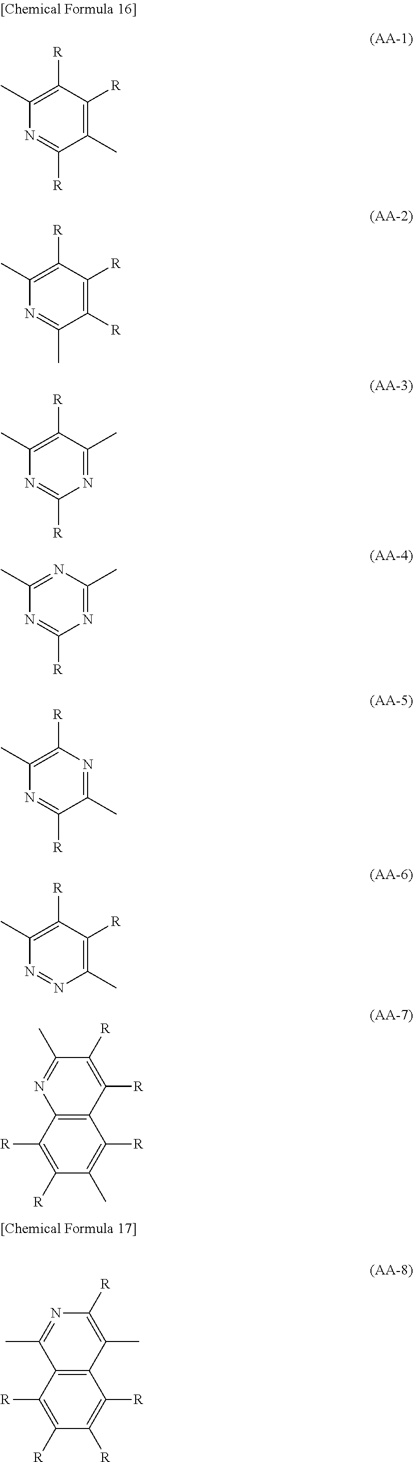

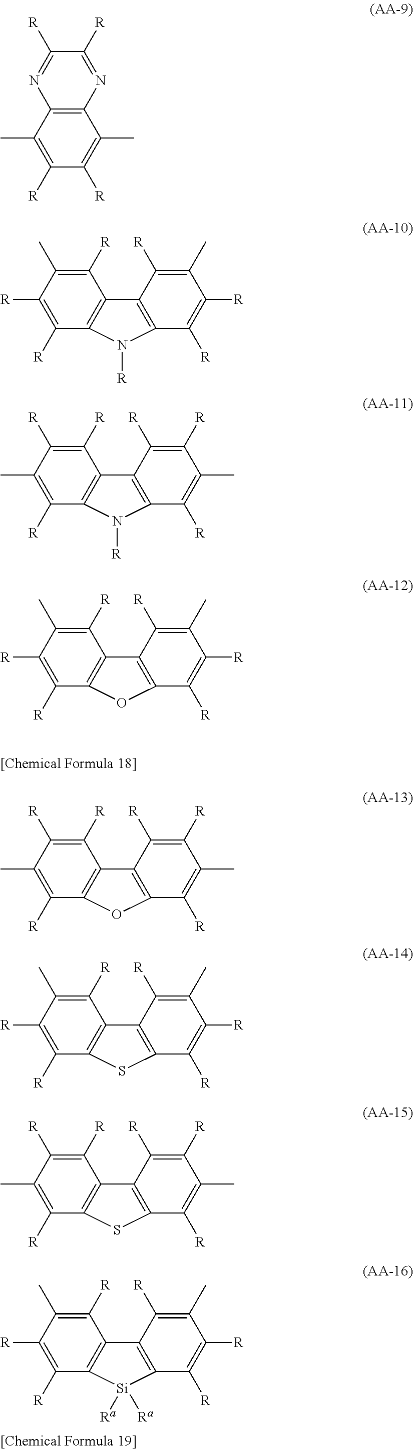

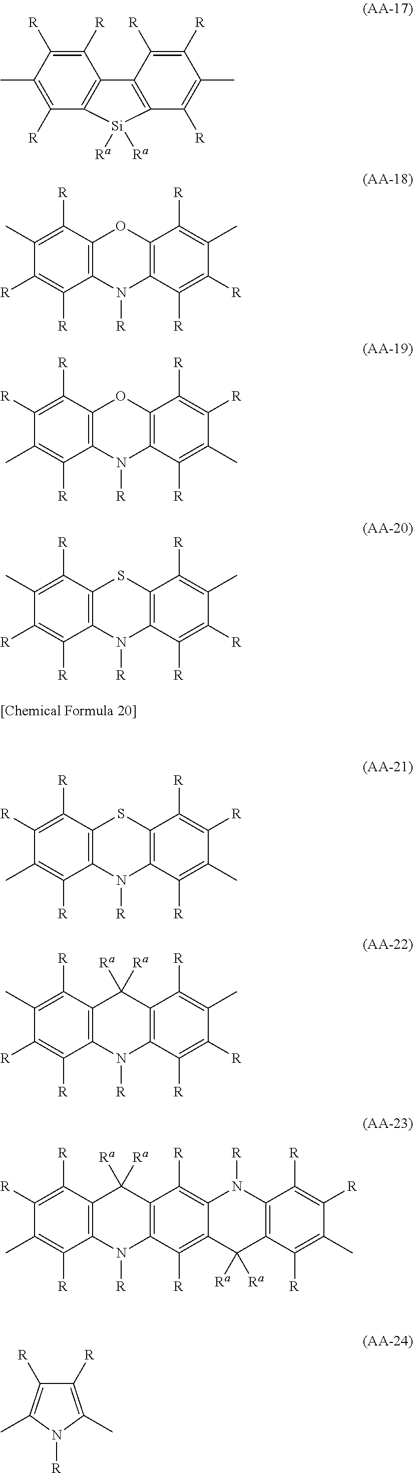

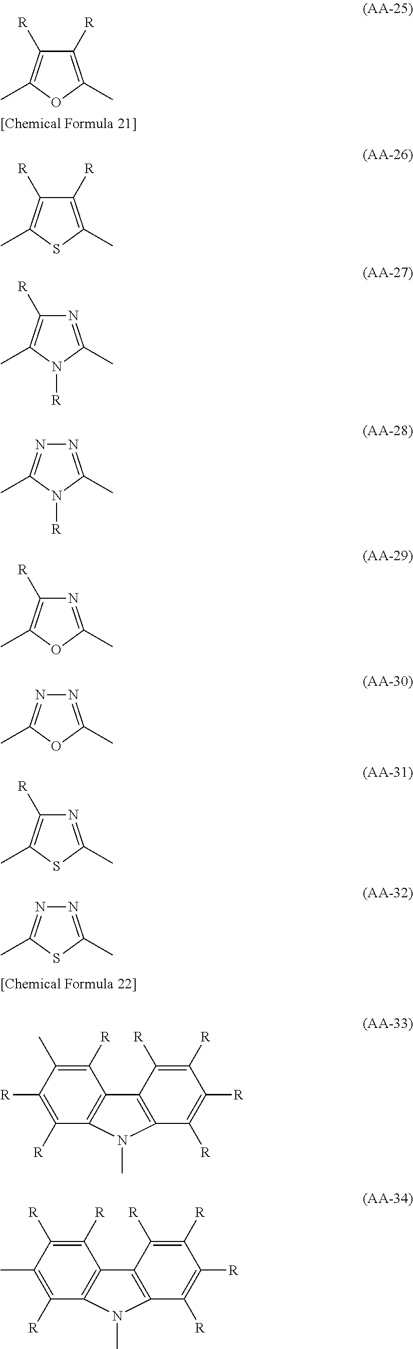

Wherein, R and R^{a} represent the same meaning as described above.

“Crosslinkable group” is a group capable of forming a new bond by being subjected to a heating treatment, an ultraviolet irradiation treatment, a radical reaction and the like, and is preferably a crosslinkable group represented by the formula (XL-1), (XL-2), (XL-3), (XL-4), (XL-5), (XL-6), (XL-7), (XL-8), (XL-9), (XL-10), (XL-11), (XL-12), (XL-13), (XL-14), (XL-15), (XL-16) or (XL-17) in the above-described Group A of crosslinkable group (hereinafter, referred to as “groups represented by the formulae (XL-1) to (XL-17)” in some cases).

“Substituent” represents a halogen atom, a cyano group, an alkyl group, a cycloalkyl group, an aryl group, a monovalent heterocyclic group, an alkoxy group, a cycloalkoxy group, an aryloxy group, an amino group, a substituted amino group, an alkenyl group, a cycloalkenyl group, an alkynyl group or a cycloalkynyl group. The substituent may be a crosslinkable group.

<Light-Emitting Device>

Then, a light-emitting device according to one embodiment of the present invention will be described.

A light-emitting device according to the present embodiment comprises an anode, a cathode, a first organic layer disposed between the anode and the cathode, and a second organic layer disposed between the anode and the first organic layer and adjacent to the first organic layer. The first organic layer is a layer formed by using a phosphorescent compound represented by the formula (1), and the second organic layer is a layer formed by using a polymer composition in which one or two or more polymer compounds including a crosslinkable polymer compound having a crosslinkable group compounded. Further for the one or two or more polymer compounds compounded in the polymer composition, with respect to each monomer unit constituting the polymer compounds, the value x obtained by multiplying the molar ratio C of the each monomer unit to the total mol of all the monomer units by the molecular weight M of the each monomer unit, and the value y obtained by multiplying the molar ratio C by the number n of the crosslinkable groups in the each monomer unit are determined, the value of (Y₁×1000)/X₁ calculated from the total X₁ of the values x and the total Y₁ of the values y being 0.5 or more

“Being formed by using” mentioned for the relation, between the first organic layer and the phosphorescent compound represented by the formula (1) means that the first organic layer is formed by using the phosphorescent compound represented by the formula (1). The phosphorescent compound represented by the formula (1) as it is may be contained in the first organic layer, or the phosphorescent compound represented by the formula (1) may be contained in the state of being intramolecularly, intermolecularly or in both manners crosslinked in the first organic layer. That is, the first organic layer may comprise the phosphorescent compound represented by the formula (1) and/or a crosslinked form of the phosphorescent compound.

“Being formed by using” mentioned for the relation between the second organic layer and the polymer composition means that the second organic layer is formed by using the polymer composition. The polymer composition as it is may be contained in the second organic layer, or the crosslinkable polymer compound contained in the polymer composition may be contained in the state of being intramolecularly, intermolecularly or in both manners crosslinked in the second organic layer. That is, the second organic layer may comprise the polymer composition and/or a cured polymer product produced by curing the polymer composition.

Examples of the methods for forming the first organic layer and the second organic layer include a vacuum vapor deposition method, and coating methods typified by a spin coat method and an inkjet printing method.

When the first organic layer is formed by a coating method, it is preferable to use an ink for the first organic layer described later. After the first organic layer is formed, the phosphorescent compound can be crosslinked by heating it or irradiating it with light. When the phosphorescent compound is contained in the state of being crosslinked in the first organic layer, the first organic layer is substantially insolubilized to solvents. Hence, the first organic layer can suitably be used for lamination of the light-emitting device.

When the second organic layer is formed by a coating method, it is preferable to use an ink for the second organic layer described later. After the second organic layer is formed, a crosslinkable polymer compound contained in the polymer composition can be crosslinked by heating it or irradiating it with light. When the polymer compound is contained in the state of being crosslinked in the second organic layer, the second organic layer is substantially insolubilized to solvents. Hence, the second organic layer can suitably be used for lamination of the light-emitting device.

In the light-emitting device according to the present embodiment, it is preferable that the crosslinkable polymer compound contained in the polymer composition is contained in the state of being crosslinked in the second organic layer.

The heating temperature for the crosslinking is usually 25 to 300° C., preferably 50 to 250° C., and more preferably 150 to 200° C.

The kind of light to be used for light irradiation for the crosslinking is, for example, ultraviolet light, near-ultraviolet light or visible light.

<First Organic Layer>

The first organic layer is a layer formed by using a phosphorescent compound represented by the formula (1).

[Phosphorescent Compound Represented by the Formula (1)]

The phosphorescent compound represented by the formula (1) is constituted of M being the central metal, a ligand(s) the number of which is specified by a subscript n¹, and a ligand(s) the number of which is specified by a subscript n².

M is preferably an iridium atom or a platinum atom, and more preferably an iridium atom, because the external quantum efficiency of the light-emitting device according to the present embodiment is excellent.

When M is a ruthenium atom, a rhodium atom or an iridium atom, it is preferable that n¹ is 2 or 3; and it is more preferable to be 3.

When M is a palladium atom or a platinum atom, it is preferable that n¹ is 2.

It is preferable that E¹ is a carbon atom.

The ring L^{1A} is an imidazole ring in which E^{11A} is a nitrogen atom or E^{12A} is a nitrogen atom, and the imidazole ring in which E^{11A} is a nitrogen atom is preferable.

When E^{11A} is a nitrogen atom, R^{11A} is preferably an alkyl group, a cycloalkyl group, an aryl group, a monovalent heterocyclic group or a substituted amino group; more preferably an alkyl group, a cycloalkyl group or an aryl group; and further preferably an aryl group; and these groups each optionally have a substituent.

When E^{11A} is a carbon atom, R^{11A} is preferably an alkyl group, a cycloalkyl group, an aryl group, a monovalent heterocyclic group or a substituted amino group; more preferably a hydrogen atom, an alkyl group, a cycloalkyl group or an aryl group; further preferably a hydrogen atom, an alkyl group or a cycloalkyl group; and it is especially preferably a hydrogen atom; and these groups each optionally have a substituent.

When E^{12A} is a nitrogen atom, R^{12A} is preferably an alkyl group, a cycloalkyl group, an aryl group, a monovalent heterocyclic group or a substituted amino group; more preferably an alkyl group, a cycloalkyl group or an aryl group; and it is further preferably an aryl group; and these groups each optionally have a substituent.

When E^{12A} is a carbon atom, R^{12A} is preferably an alkyl group, a cycloalkyl group, an aryl group, a monovalent heterocyclic group or a substituted amino group; more preferably a hydrogen atom, an alkyl group, a cycloalkyl group or an aryl group; further preferably a hydrogen atom, an alkyl group or a cycloalkyl group; and especially preferably a hydrogen atom; and these groups each optionally have a substituent.

R^{13A} is preferably an alkyl group, a cycloalkyl group, an aryl group, a monovalent heterocyclic group or a substituted amino group; more preferably a hydrogen atom, an alkyl group, a cycloalkyl group or an aryl group; further preferably a hydrogen atom, an alkyl group or a cycloalkyl group; and especially preferably a hydrogen atom; and these groups each optionally have a substituent.

When the ring L^{2A} is a pyridine ring, the pyridine ring in which E^{21A} is a nitrogen atom, the pyridine ring in which E^{22A} is a nitrogen atom, or the pyridine ring in which E^{23A} is a nitrogen atom is preferable; and the pyridine ring in which E^{22A} is a nitrogen atom is more preferable.

When the ring L^{2A} is a pyrimidine ring, the pyrimidine ring in which E^{21A} and E^{23A} are nitrogen atoms, or the pyrimidine ring in which E^{22A} and E^{24A} are nitrogen atoms is preferable; and the pyrimidine ring in which E^{22A} and E^{24A} are nitrogen atoms is more preferable.

It is preferable that the ring L^{2A} is a benzene ring.

R^{21A}, R^{22A}, R^{23A} and R^{24A} each preferably independently represent an alkyl group, a cycloalkyl group, an aryl group, a monovalent heterocyclic group or a substituted amino group; are more preferably a hydrogen atom, an alkyl group, a cycloalkyl group or an aryl group; and further preferably a hydrogen atom, an alkyl group or an aryl group; and these groups each optionally have a substituent.

It is preferable that a substituent which R^{11A}, R^{12A}, R^{13A}, R^{21A}, R^{22A}, R^{23A} and R^{24A} optionally have is an alkyl group, a cycloalkyl group, an aryl group, a monovalent heterocyclic group or a substituted amino group; and these groups each optionally further have a substituent.

When R^{11A}, R^{12A}, R^{13A}, R^{21A}, R^{22A}, R^{23A} and R^{24A} are an aryl group, a monovalent heterocyclic group or a substituted amino group, it is preferable to be a dendron because the external quantum efficiency of the light-emitting device is excellent.

“Dendron” denotes a group having a regular dendritic branched structure having a branching point at an atom or ring (that is, a dendrimer structure). A compound having a dendron (hereinafter, referred to as “dendrimer”) includes, for example, structures described in literatures such as International Publication WO02/067343, JP-A No. 2003-231692, International Publication WO02003/079736, International Publication WO2006/097717 and the like.

The dendron is preferably a group represented by the above-described formula (D-A) or the above-described (D-B).

G^{DA} is preferably a group represented by the formula (GDA-11), (GDA-12), (GDA-13), (GDA-14) or (GDA-15) (hereinafter, referred to as “groups represented by the formulae (GDA-11) to (GDA-15)” in some cases), and these groups each optionally have a substituent.

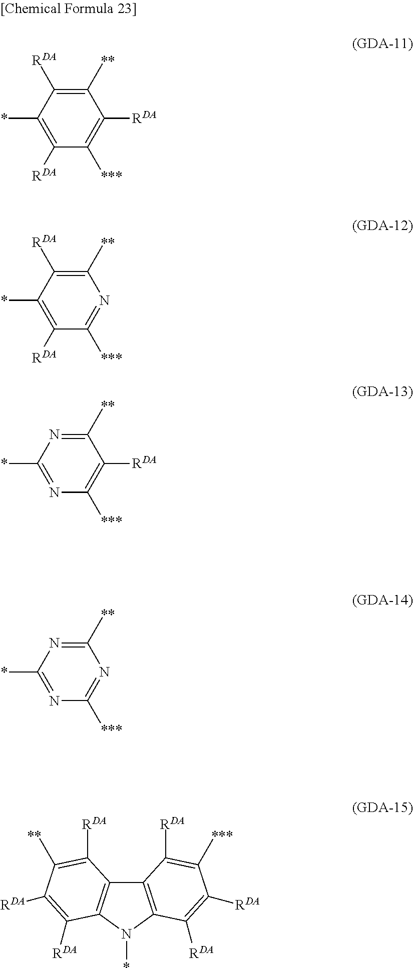

Wherein,

* represents a bond to Ar^{DA1} in the formula (D-A), Ar^{DA1} in the formula (D-B), Ar^{DA2} in the formula (D-B) or Ar^{DA3} in the formula (D-B).

** represents a bond to Ar^{DA2} in the formula (D-A), Ar^{DA2} in the formula (D-B), Ar^{DA4} in the formula (D-B) or Ar^{DA6} in the formula (D-B).

*** represents a bond to Ar^{DA3} in the formula (D-A), Ar^{DA3} in the formula (D-B), Ar^{DA5} in the formula (D-B) or Ar^{DA7} in the formula (D-B).

R^{DA} represents a hydrogen atom, an alkyl group, a cycloalkyl group, an alkoxy group, a cycloalkoxy group, an aryl group or a monovalent heterocyclic group, and these groups each optionally have a substituent. When a plurality of R^{DA} are present, they may be the same or different.

R^{DA} is preferably a hydrogen atom, an alkyl group, a cycloalkyl group, an alkoxy group or a cycloalkoxy group, more preferably a hydrogen atom, an alkyl group or cycloalkyl group, and these groups each optionally have a substituent.

It is preferable that Ar^{DA1}, Ar^{DA2}, Ar^{DA3}, Ar^{DA4}, Ar^{DA5}, Ar^{DA6} and Ar^{DA7} are groups represented by the formula (ArDA-1), (ArDA-2) or (ArDA-3) (hereinafter, referred to as “groups represented by the formulae (ArDA-1) to (ArDA-3)” in some cases).

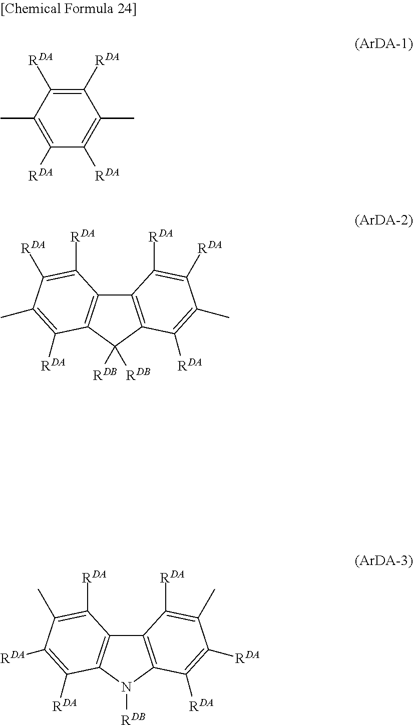

Wherein,

R^{DA} represents the same meaning as described above.

R^{DB} represents a hydrogen atom, an alkyl group, a cycloalkyl group, an aryl group or a monovalent heterocyclic group, and these groups each optionally have a substituent. When a plurality of R^{DB} are present, they may be the same or different.

R^{DB} is preferably an alkyl group, a cycloalkyl group, an aryl group or a monovalent heterocyclic group, more preferably an aryl group or a monovalent heterocyclic group, further preferably an aryl group, and these groups each optionally have a substituent.

T^{DA} is preferably groups represented by the formula (TDA-1), (TDA-2) or (TDA-3) (hereinafter, referred to as “groups represented by the formulae (TDA-1) to (TDA-3)” in some cases).

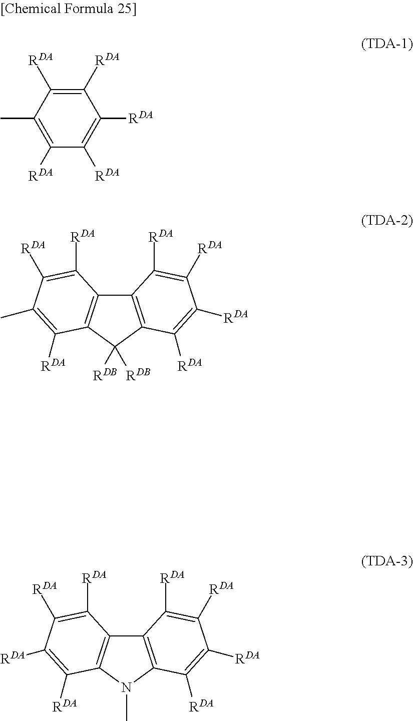

Wherein, R^{DA} and R^{DB} represent the same meaning described above.

The group represented by the formula (D-A) is preferably a group represented by the formula (D-A1), (D-A2) or (D-A3) (hereinafter, referred to as “groups represented by the formulae (D-A1) to (D-A3)” in some cases).

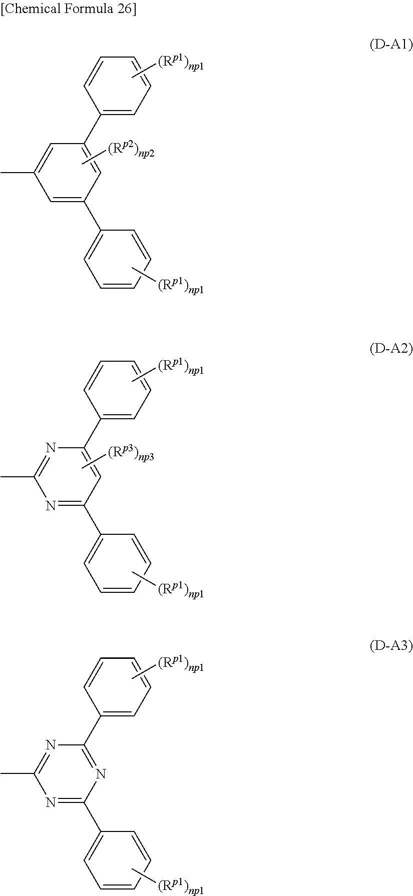

Wherein,

R^{p1}, R^{p2} and R^{p3} each independently represent an alkyl group, a cycloalkyl group, an alkoxy group, a cycloalkoxy group or a halogen atom. When a plurality of R^{p1} and R^{p2} are present, they may be the same or different at each occurrence.

np1 represents an integer of 0 to 5, np2 represents an integer of 0 to 3, and np3 represents 0 or 1. The plurality of np1 may be the same or different.

The group represented by the formula (D-B) is preferably a group represented by the formula (D-B1), (D-B2) or (D-B3) (hereinafter, referred to as “groups represented by the formulae (D-B1) to (D-B3)” in some cases).

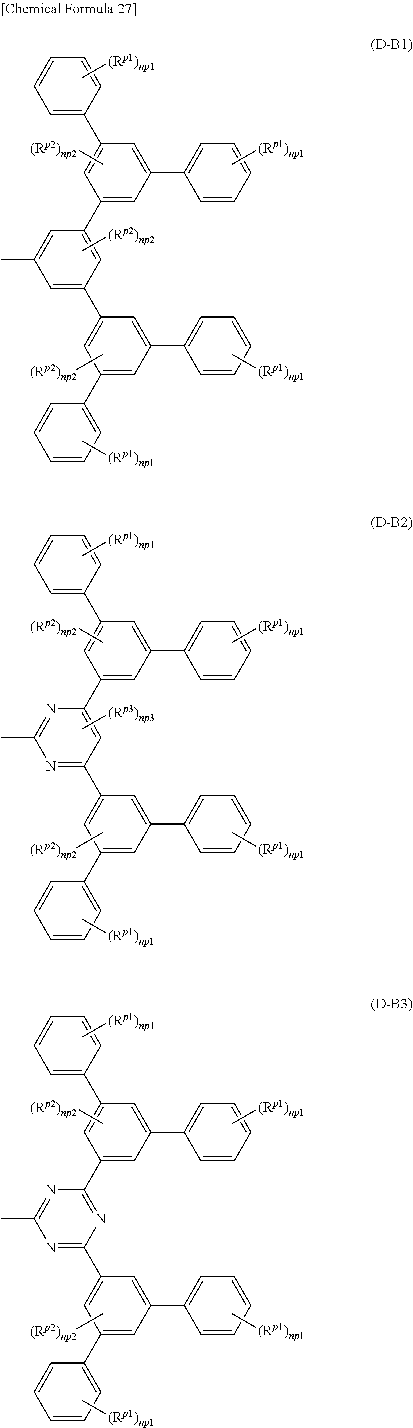

Wherein,

R^{p1}, R^{p2} and R^{p3} each independently represent an alkyl group, a cycloalkyl group, an alkoxy group, a cycloalkoxy group or a halogen atom. When a plurality of R^{p1} and R^{p2} are present, they may be the same or different at each occurrence.

np1 represents an integer of 0 to 5, np2 represents an integer of 0 to 3, and np3 represents 0 or 1. When a plurality of np1 and np2 are present, they may be the same or different at each occurrence.

np1 is preferably 0 or 1, more preferably 1. np2 is preferably 0 or 1, more preferably 0. np3 is preferably 0.

R^{p1}, R^{p2} and R^{p3} are preferably an alkyl group or a cycloalkyl group.

Examples of an anionic bidentate ligand represented by A¹-G¹-A² include ligands represented by the following.

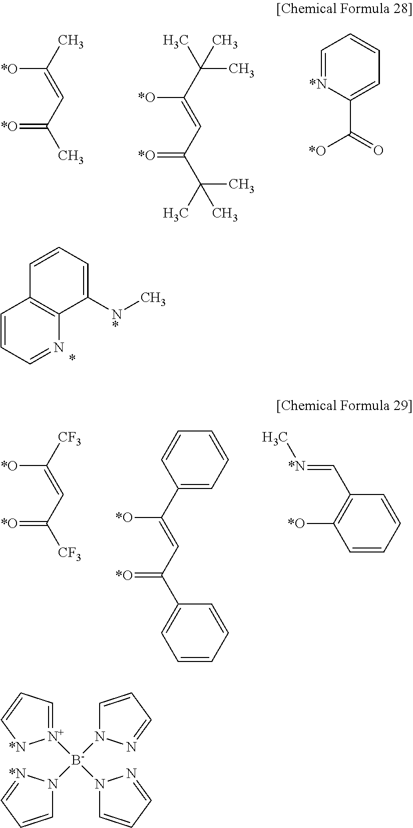

Wherein, * indicates bonding portions to M.

The anionic bidentate ligand represented by A¹-G¹-A² may be ligands represented by the following. Here, the anionic bidentate ligand represented by A¹-G¹-A² is different from the ligand the number of which is defined by the subscript n¹.

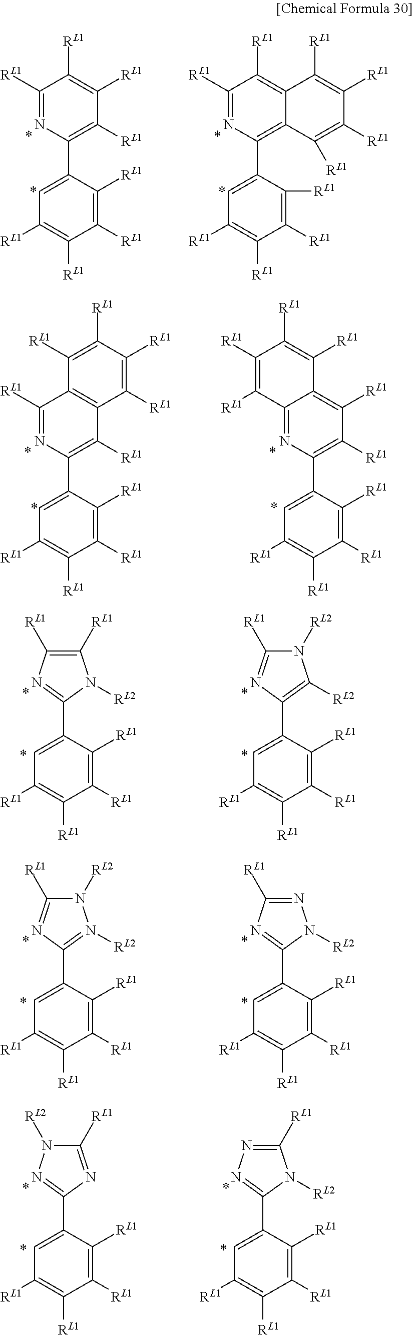

Wherein, * indicates bonding portions to M.

R^{L1} represents a hydrogen atom, an alkyl group, a cycloalkyl group or a halogen atom, and these groups each optionally have a substituent. The plurality of R^{L1} may be the same or different.

R^{L2} represents an alkyl group, a cycloalkyl group or a halogen atom, and these groups each optionally have a substituent.

The phosphorescent compound represented by the formula (1) is preferably a phosphorescent compound represented by the above formula (1-1) or a phosphorescent compound represented by the formula (1-2); and more preferably a phosphorescent compound represented by the above formula (1-1).

Examples of the phosphorescent compound represented by the formula (1) include phosphorescent compounds represented by the following formulae.

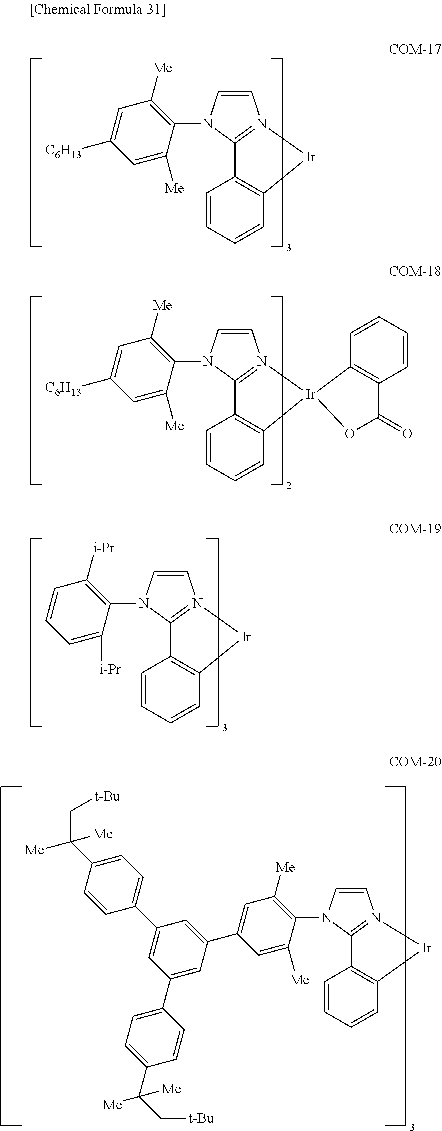

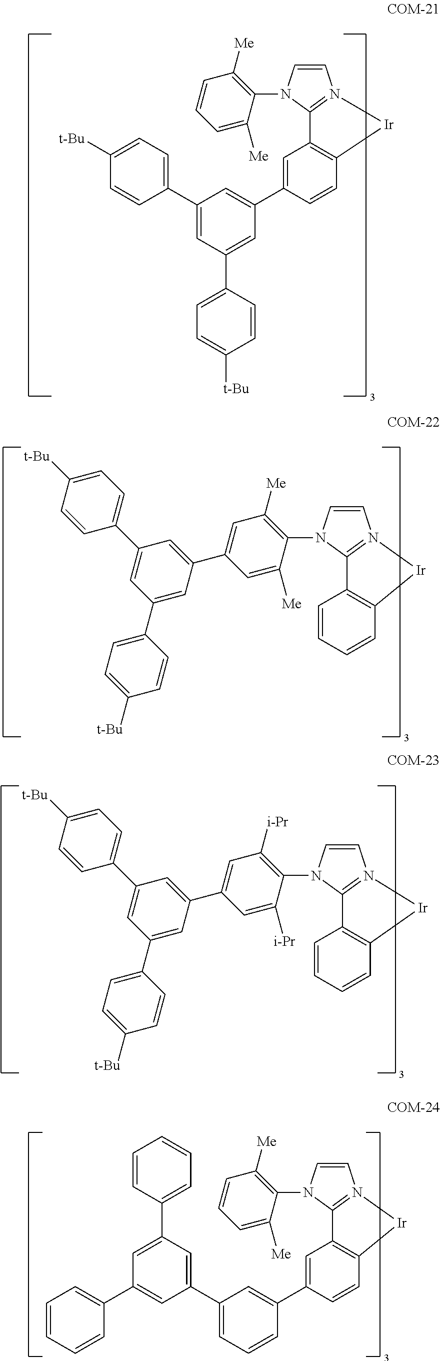

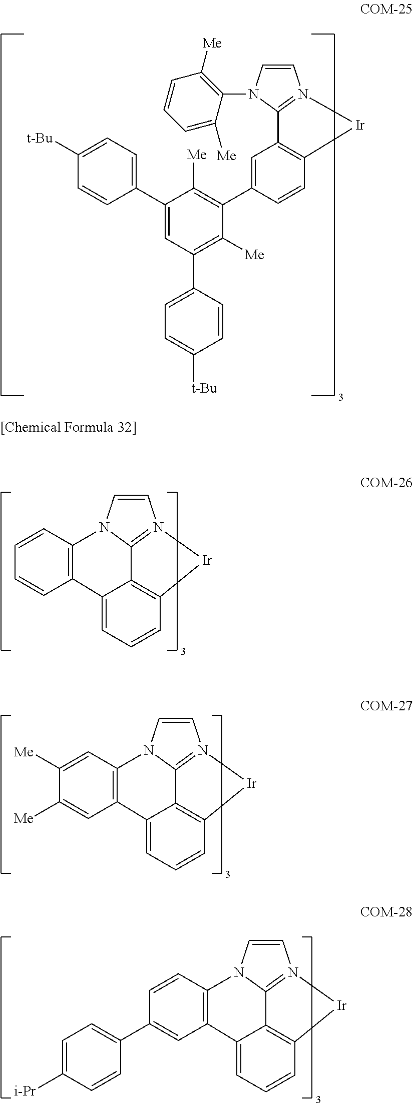

As described above, although the first organic layer is formed by using at least the phosphorescent compound represented by the formula (1), the first organic layer may be a layer formed by using the phosphorescent compound represented by the formula (1) and other phosphorescent compounds in combination. That is, the first organic layer may further comprise the other phosphorescent compounds other than the phosphorescent compound represented by the formula (1). Examples of the other phosphorescent compounds include phosphorescent compounds represented by the following formulae.

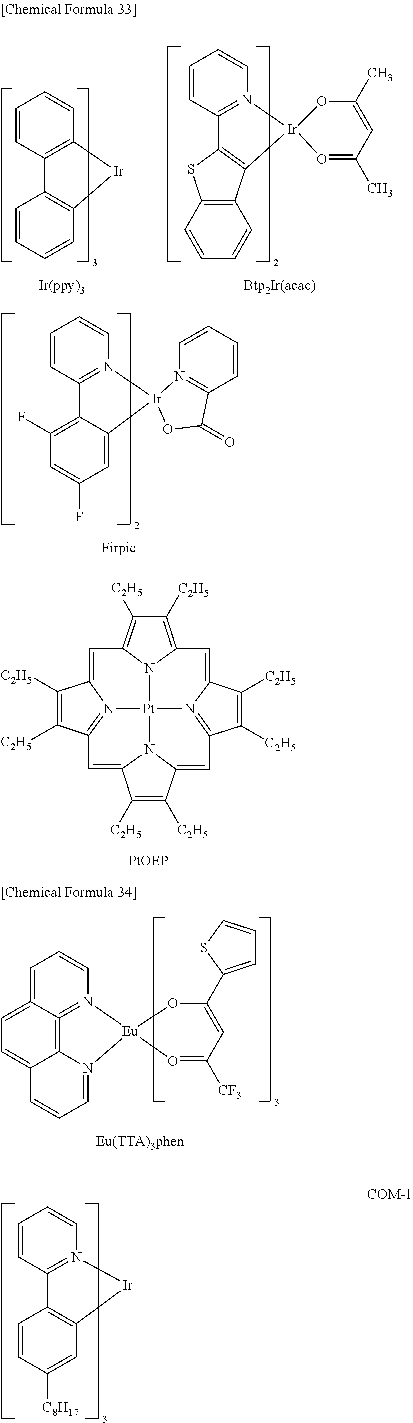

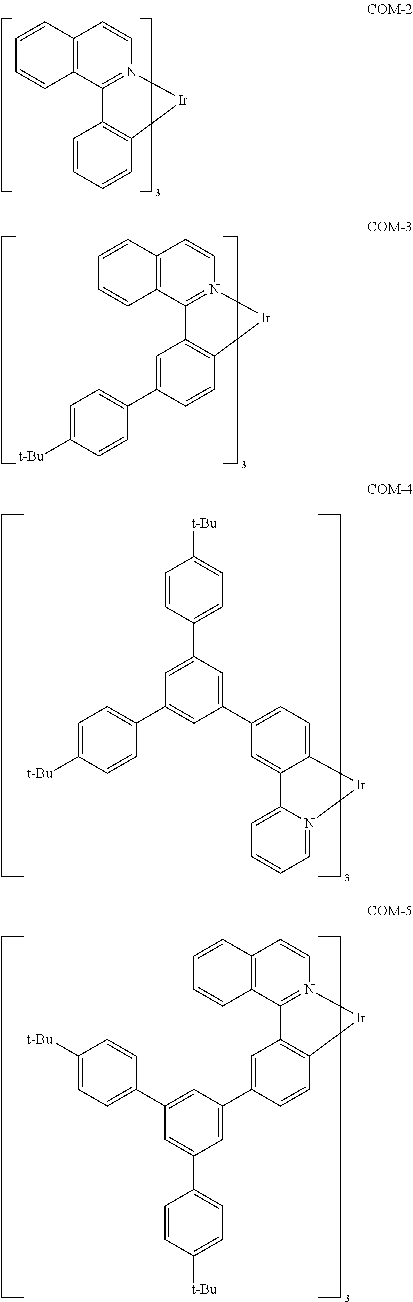

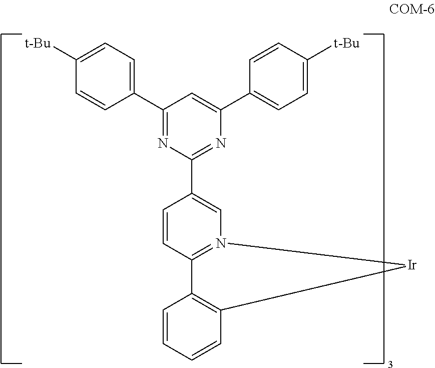

The phosphorescent compound used for formation of the first organic layer can be synthesized according to methods described, for example, in Japanese Patent Application National Publication No. 2004-530254, JP-A No. 2008-179617, JP-A No. 2011-105701, Japanese Patent Application National Publication No. 2007-504272, JP-A No. 2013-147449 and JP-A No. 2013-147450.

[Host Material]

Because the external quantum efficiency of the light-emitting device according to the present embodiment is excellent, it is preferable that the first organic layer of the light-emitting device according to the present embodiment is a layer formed by using a composition comprising one or more phosphorescent compounds represented by the formula (1), and a host material having at least one function selected from the group consisting of the hole injectability, the hole transportability, the electron injectability and the electron transportability. In the composition, the host material may be contained singly or two or more materials may be contained.

That is, the first organic layer may be a layer further comprising a host material having at least one function selected from the group consisting of the hole injectability, the hole transportability, the electron injectability and the electron transportability. Further the first organic layer may be a layer constituted of a composition comprising one or more phosphorescent compounds represented by the formula (1), and a host material having at least one function selected from the group consisting of the hole injectability, the hole transportability, the electron injectability and the electron transportability.

In the composition comprising the phosphorescent compounds represented by the formula (1) and the host material, the content of the phosphorescent compounds represented by the formula (1) is, when the total of the phosphorescent compounds represented by the formula (1) and the host material is taken to be 100 parts by mass, usually 0.1 to 50 parts by mass, preferably 1 to 45 parts by mass, and more preferably 5 to 40 parts by mass.

It is preferable that the lowest excited triplet state (T₁) the host material has is at the same energy level as that of T₁ the phosphorescent compound represented by the formula (1) to be used for formation of the first organic layer has, or at a higher energy level than that, because the external quantum efficiency of the light-emitting device according to the present embodiment is excellent.

It is preferable that the host material is soluble in a solvent capable of dissolving the phosphorescent compound represented by the formula (1), because the light-emitting device according to the present embodiment can be fabricated by a solution coating process.

The host material is classified into low molecular weight compounds and polymer compounds.

[Low Molecular Weight Host]

The low molecular weight compound which is preferable as a host compound (hereinafter, referred to as “low molecular weight host”) will be explained below. The low molecular weight host is a compound having no molecular weight distribution and having a molecular weight of 1×10⁴ or less among host materials described above.

The low molecular weight host is preferably a compound represented by the formula (H-1).

Ar^{H1} and Ar^{H2} are preferably a phenyl group, a fluorenyl group, a spirobifluorenyl group, a pyridyl group, a pyrimidinyl group, a triazinyl group, a quinolinyl group, an isoquinolinyl group, a thienyl group, a benzothienyl group, a dibenzothienyl group, a furyl group, a benzofuryl group, a dibenzofuryl group, a pyrrolyl group, an indolyl group, an azaindolyl group, a carbazolyl group, an azacarbazolyl group, a diazacarbazolyl group, a phenoxazinyl group or a phenothiazinyl group, more preferably a phenyl group, a spirobifluorenyl group, a pyridyl group, a pyrimidinyl group, a triazinyl group, a dibenzothienyl group, a dibenzofuryl group, a carbazolyl group or an azacarbazolyl group, further preferably a phenyl group, a pyridyl group, a carbazolyl group or an azacarbazolyl group, particularly preferably a group represented by formula (TDA-1) or (TDA-3) described above, especially preferably a group represented by the formula (TDA-3) described above, and these groups each optionally have a substituent.

The substituent which Ar^{H1} and Ar^{H2} optionally have is preferably a halogen atom, an alkyl group, a cycloalkyl group, an alkoxy group, a cycloalkoxy group, an aryl group or a monovalent heterocyclic group, more preferably an alkyl group, a cycloalkoxy group, an alkoxy group or cycloalkoxy group, further preferably an alkyl group or cycloalkoxy group, and these groups each optionally further have a substituent.

n^{H1} is preferably 1. n^{H2} is preferably 0.

n^{H3} is usually an integer of 0 to 10, preferably an integer of 0 to 5, further preferably an integer of 1 to 3, particularly preferably 1.

n^{H11} is preferably an integer of 1 to 5, more preferably an integer of 1 to 3, further preferably 1.

R^{H11} is preferably a hydrogen atom, an alkyl group, a cycloalkyl group, an aryl group or a monovalent heterocyclic group, more preferably a hydrogen atom, an alkyl group or a cycloalkyl group, further preferably a hydrogen atom or an alkyl group, and these groups each optionally have a substituent.

L^{H1} is preferably an arylene group or a divalent heterocyclic group, and these groups optionally have a substituent.

L^{H1} is preferably a group represented by the formula (A-1) to (A-3), the formula (A-8) to (A-10), the formula (AA-1) to (AA-6), the formula (AA-10) to (AA-21) or the formula (AA-24) to (AA-34), more preferably a group represented by the formula (A-1), the formula (A-2), the formula (A-8), the formula (A-9), the formula (AA-1) to (AA-4), the formula (AA-10) to (AA-15) or the formula (AA-29) to (AA-34), further preferably a group represented by the formula (A-1), the formula (A-2), the formula (A-8), the formula (A-9), the formula (AA-2), the formula (AA-4) or the formula (AA-10) to (AA-15), particularly preferably a group represented by the formula (A-1), the formula (A-2), the formula (A-8), the formula (AA-2), the formula (AA-4), the formula (AA-10), the formula (AA-12) or the formula (AA-14), especially preferably a group represented by the formula (A-1), the formula (A-2), the formula (AA-2), the formula (AA-4) or the formula (AA-14).

The substituent which L^{H1} optionally has is preferably a halogen atom, an alkyl group, a cycloalkyl group, an alkoxy group, a cycloalkoxy group, an aryl group or a monovalent heterocyclic group, more preferably an alkyl group, an alkoxy group, an aryl group or a monovalent heterocyclic group, further preferably an alkyl group, an aryl group or a monovalent heterocyclic group, and these groups each optionally further have a substituent.

L^{H21} is preferably a single bond or an arylene group, more preferably a single bond, and this arylene group optionally has a substituent.

The definition and examples of the arylene group or the divalent heterocyclic group represented by L^{H21} are the same as the definition and examples of the arylene group or the divalent heterocyclic group represented by L^{H1}.

R^{H21} is preferably an aryl group or a monovalent heterocyclic group, and these groups each optionally have a substituent.

The definition and examples of the aryl group and the monovalent heterocyclic group represented by R^{H21} are the same as the definition and examples of the aryl group and the monovalent heterocyclic group represented by Ar^{H1} and Ar^{H2}.

The definition and examples of the substituent which R^{H21} may optionally has are the same as the definition and examples of the substituent which Ar^{H1} and Ar^{H2} optionally have.

The compound represented by the formula (H-1) is preferably a compound represented by the formula (H-2).

[Chemical Formula 37]

Ar^{H1}L^{H1}ₙ_{^{H3}}ArH² (H-2)

Wherein, Ar^{H1}, Ar^{H2}, n^{H3} and L^{H1} represent the same meaning as described above.

As the compound represented by the formula (H-1), compounds represented by the following formula (H-101), (H-102), (H-103), (H-104), (H-105), (H-106), (H-107), (H-108), (H-109), (H-110), (H-111), (H-112), (H-113), (H-114), (H-115), (H-116), (H-117) or (H-118) (hereinafter, referred to as “compounds represented by the formulae (H-101) to (118)” in some cases) are exemplified.

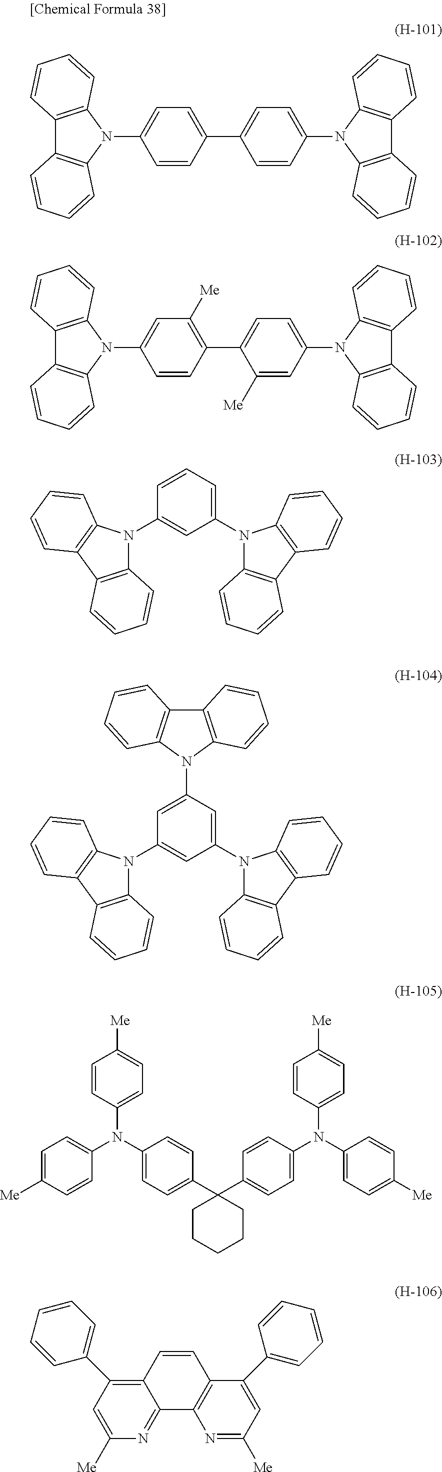 [SMILES: c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; Cc1ccc(N(c2ccc(C)cc2)c2ccc(C3(c4ccc(N(c5ccc(C)cc5)c5ccc(C)cc5)cc4)CCCCC3)cc2)cc1 ; Cc1cc(-c2ccccc2)c2ccc3c(-c4ccccc4)cc(C)nc3c2n1]

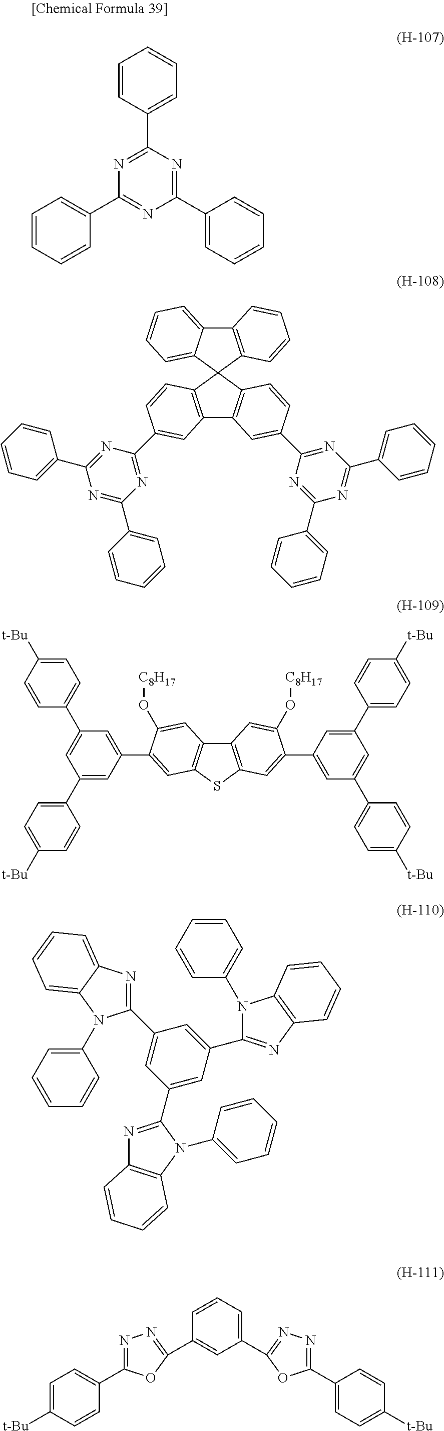

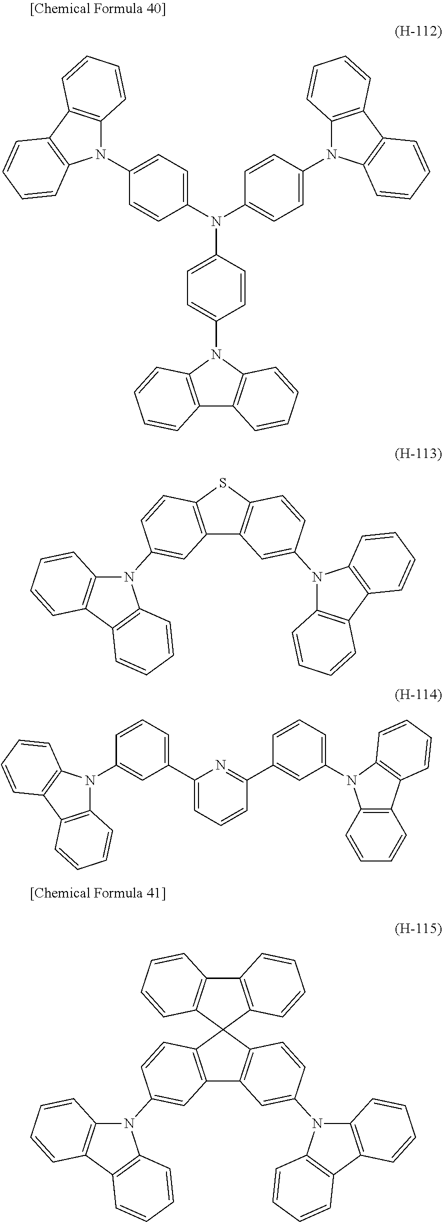

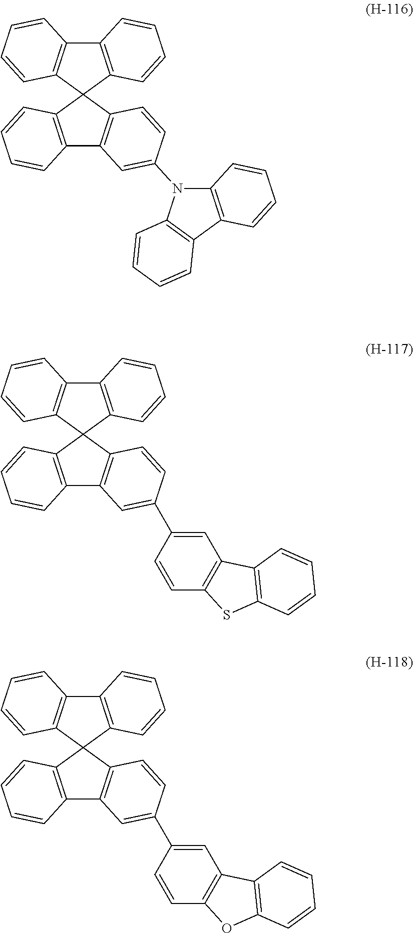 [SMILES: c1ccc2c(c1)-c1ccccc1C21c2ccccc2-c2cc(-n3c4ccccc4c4ccccc43)ccc21 ; c1ccc2c(c1)-c1ccccc1C21c2ccccc2-c2cc(-c3ccc4sc5ccccc5c4c3)ccc21 ; c1ccc2c(c1)-c1ccccc1C21c2ccccc2-c2cc(-c3ccc4oc5ccccc5c4c3)ccc21]

[Polymer Host]

The polymer compound which is preferable as a host compound (hereinafter, referred to as “polymer host”) will be explained below.

The polymer host is a polymer having molecular weight distribution and having a polystyrene-equivalent number average molecular weight of 1×10³ to 1×10⁸ among host materials described above.

The polymer host includes, for example, polymer compounds as a hole transporting material described later and polymer compounds as an electron transporting material described later.

The polymer host is preferably a polymer compound comprising a constitutional unit represented by the formula (Y) described above.

The arylene group represented by Ar^{Y1} is more preferably a group represented by the formula (A-1), the formula (A-2), the formula (A-6) to (A-10), the formula (A-19) or the formula (A-20), further preferably a group represented by the formula (A-1), the formula (A-2), the formula (A-7), the formula (A-9) or the formula (A-19), and these groups each optionally have a substituent.

The divalent heterocyclic group represented by Ar^{Y1} is more preferably a group represented by the formula (AA-1) to (AA-4), the formula (AA-10) to (AA-15), the formula (AA-18) to (AA-21), the formula (AA-33) or the formula (AA-34), further preferably a group represented by the formula (AA-4), the formula (AA-10), the formula (AA-12), the formula (AA-14) or the formula (AA-33), and these groups each optionally have a substituent.

The more preferable range and the further preferable range of the arylene group and the divalent heterocyclic group in the divalent group in which at least one arylene group and at least one divalent heterocyclic group are bonded directly to each other represented by Ar^{Y1} are the same as the more preferable range and the further preferable range of the arylene group and the divalent heterocyclic group represented by Ar^{Y1} described above, respectively.

“The divalent group in which at least one arylene group and at least one divalent heterocyclic group are bonded directly to each other” includes, for example, groups represented by the following formulae, and each of them optionally has a substituent.

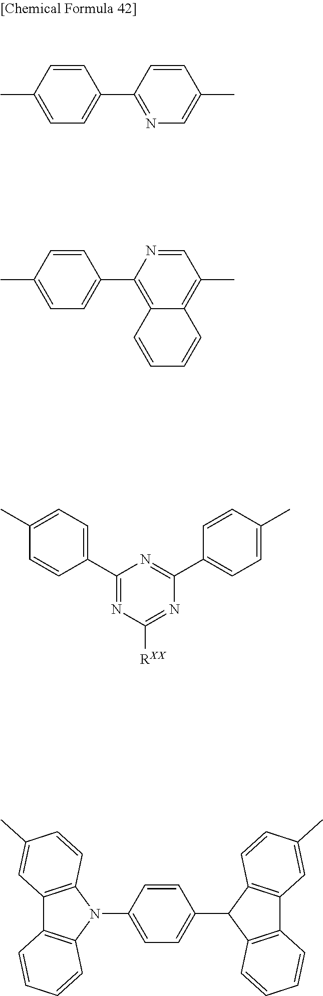

Wherein, R^{XX} represents a hydrogen atom, an alkyl group, a cycloalkyl group, an aryl group or a monovalent heterocyclic group and these groups each optionally have a substituent.

R^{XX} is preferably an alkyl group, a cycloalkyl group or an aryl group, and these groups each optionally have a substituent.

The substituent which the group represented by Ar^{Y1} optionally has is preferably an alkyl group, a cycloalkyl group or an aryl group, and these groups each optionally further have a substituent.

The constitutional unit represented by the formula (Y) includes, for example, constitutional units represented by the formula (Y-1), (Y-2), (Y-3), (Y-4), (Y-5), (Y-6), (Y-7), (Y-8), (Y-9) or (Y-10) (hereinafter, referred to as “constitutional units represented by the formulae (Y-1) to (Y-9)” in some cases), and from the standpoint of the luminance life of the light-emitting device of the present embodiment preferable are constitutional units represented by the formulae (Y-1) to (Y-3), from the standpoint of electron transportability of the light-emitting device of the present embodiment preferable are constitutional units represented by the formulae (Y-4) to (Y-7), and from the standpoint of hole transportability of the light-emitting device of the present embodiment preferable are constitutional units represented by the formulae (Y-8) to (Y-10).

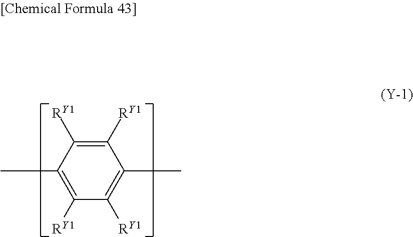

Wherein, R^{Y1} represents a hydrogen atom, an alkyl group, a cycloalkyl group, an alkoxy group, a cycloalkoxy group, an aryl group or a monovalent heterocyclic group, and these groups each optionally have a substituent. The plurality of R^{Y1} may be the same or different, and adjacent R^{Y1}s may be combined together to form a ring together with the carbon atoms to which they are attached.

R^{Y1} is preferably a hydrogen atom, an alkyl group, a cycloalkyl group or an aryl group, and these groups each optionally have a substituent.

It is preferable that the constitutional unit represented by the formula (Y-1) is a constitutional unit represented by the formula (Y-1′).

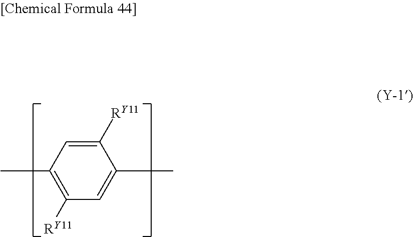

Wherein, R^{Y11} represents an alkyl group, a cycloalkyl group, an alkoxy group, a cycloalkoxy group, an aryl group or a monovalent heterocyclic group, and these groups each optionally have a substituent. The plurality of R^{Y11} may be the same or different.

R^{Y11} is preferably an alkyl group, a cycloalkyl group or an aryl group, more preferably an alkyl group or a cycloalkyl group, and these groups each optionally have a substituent.

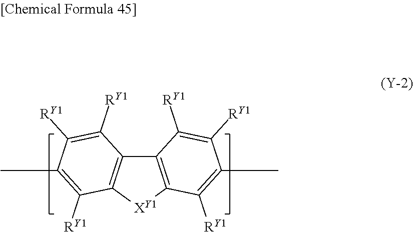

Wherein, R^{Y1} represents the same meaning as described above.

X^{Y1} represents a group represented by —C(R^{Y2})₂—, —C(R^{Y2})═C(R^{Y2})— or —C(R^{Y2})₂-C(R^{Y2})₂—. R^{Y2} represents a hydrogen atom, an alkyl group, a cycloalkyl group, an alkoxy group, a cycloalkoxy group, an aryl group or a monovalent heterocyclic group and these groups each optionally have a substituent. The plurality of R^{Y2} may be the same or different, and groups R^{Y2} may be combined together to form a ring together with the carbon atoms to which they are attached.

R^{Y2} is preferably an alkyl group, a cycloalkyl group, an aryl group or a monovalent heterocyclic group, more preferably an alkyl group a cycloalkyl group or an aryl group, and these groups each optionally have a substituent.

Regarding the combination of two R^{Y2}s in the group represented by —C(R^{Y2})₂— in X^{Y1}, it is preferable that the both are an alkyl group or a cycloalkyl group, the both are an aryl group, the both are a monovalent heterocyclic group, or one is an alkyl group or a cycloalkyl group and the other is an aryl group or a monovalent heterocyclic group, it is more preferable that one is an alkyl group or cycloalkyl group and the other is an aryl group, and these groups each optionally have a substituent. The two groups R^{Y2} may be combined together to form a ring together with the atoms to which they are attached, and when the groups R^{Y2} form a ring, the group represented by —C(R^{Y2})₂— is preferably a group represented by the formula (Y-A1), (Y-A2), (Y-A3), (Y-A4) or (Y-A5), more preferably a group represented by the formula (Y-A4), and these groups each optionally have a substituent.

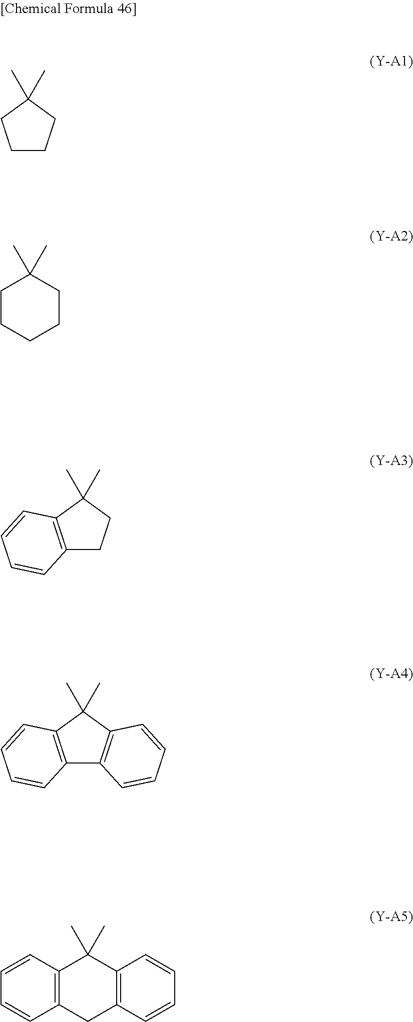

Regarding the combination of two R² s in the group represented by —C(R^{Y2})═C(R^{Y2})— in X^{Y1}, it is preferable that the both are an alkyl group or cycloalkyl group, or one is an alkyl group or a cycloalkyl group and the other is an aryl group, and these groups each optionally have a substituent.

Four R^{Y2}s in the group represented by —C(R²)₂—C(R^{Y2})₂— in X^{Y1} are preferably an alkyl group or a cycloalkyl group each optionally having a substituent. The plurality of R^{Y2} may be combined together to form a ring together with the atoms to which they are attached, and when the groups R^{Y2} form a ring, the group represented by —C(R^{Y2})₂—C(R^{Y2})₂— is preferably a group represented by the formula (Y-B1), (Y-B2), (Y-B3), (Y-B4) or (Y-B5), more preferably a group represented by the formula (Y-B3), and these groups each optionally have a substituent.

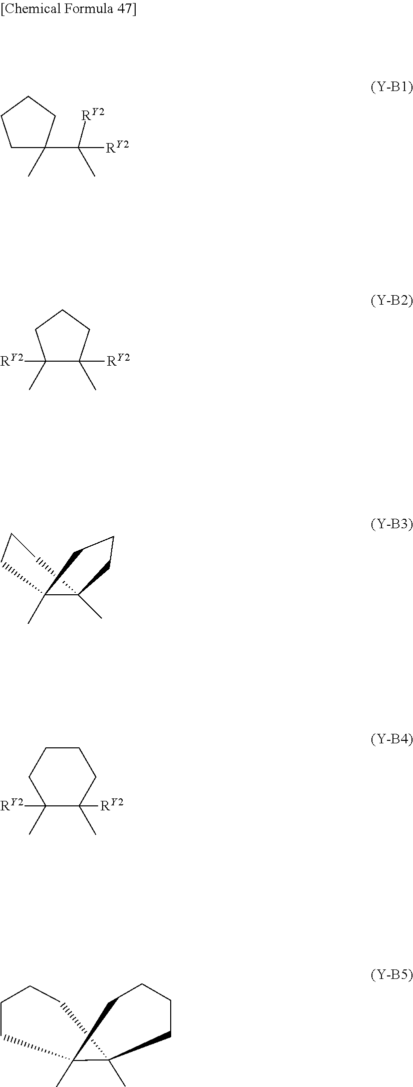

Wherein, R^{Y2} represents the same meaning as described above.

It is preferable that the constitutional unit represented by the formula (Y-2) is a constitutional unit represented by the formula (Y-2′).

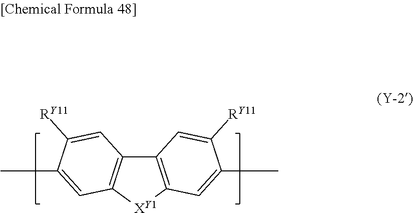

Wherein, R^{Y1} and X^{Y1} represent the same meaning as described above.

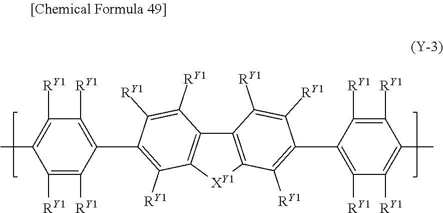

Wherein, R^{Y1} and X^{Y1} represent the same meaning as described above.

It is preferable that the constitutional unit represented by the formula (Y-3) is a constitutional unit represented by the formula (Y-3′).

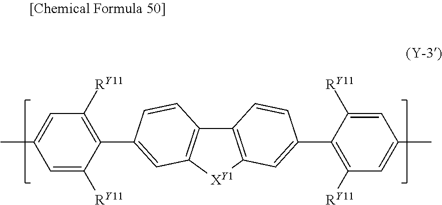

Wherein, R^{Y11} and X^{Y1} represent the same meaning as described above.

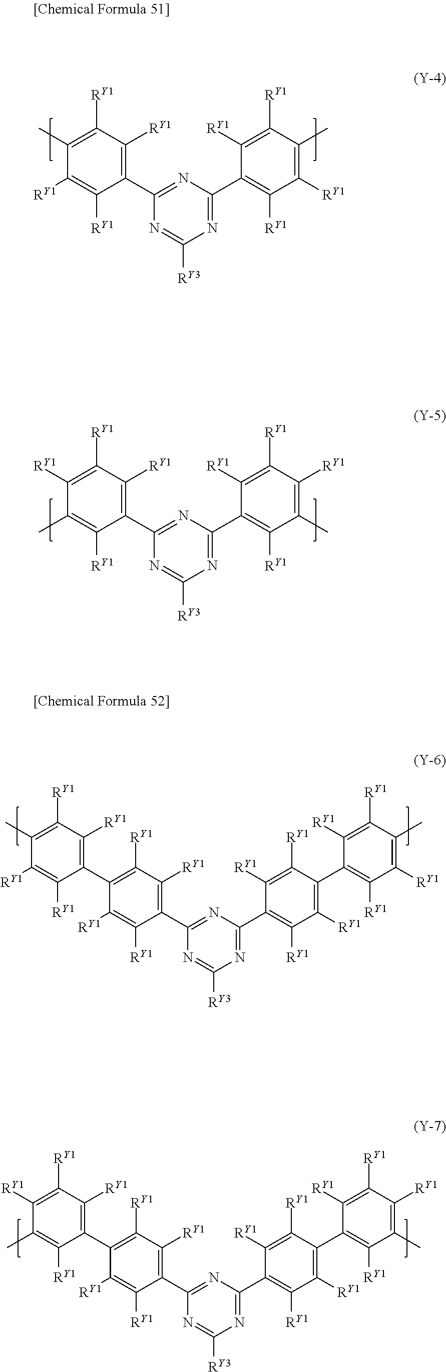

Wherein, R^{Y1} represents the same meaning as described above. R^{Y3} represents a hydrogen atom, an alkyl group, a cycloalkyl group, an alkoxy group, a cycloalkoxy group, an aryl group or a monovalent heterocyclic group and these groups each optionally have a substituent.

R^{Y3} is preferably an alkyl group, a cycloalkyl group, an alkoxy group, a cycloalkoxy group, an aryl group or a monovalent heterocyclic group, more preferably an aryl group, and these groups each optionally have a substituent.

It is preferable that the constitutional unit represented by the formula (Y-4) is a constitutional unit represented by the formula (Y-4′), and it is preferable that the constitutional unit represented by the formula (Y-6) is a constitutional unit represented by the formula (Y-6′).

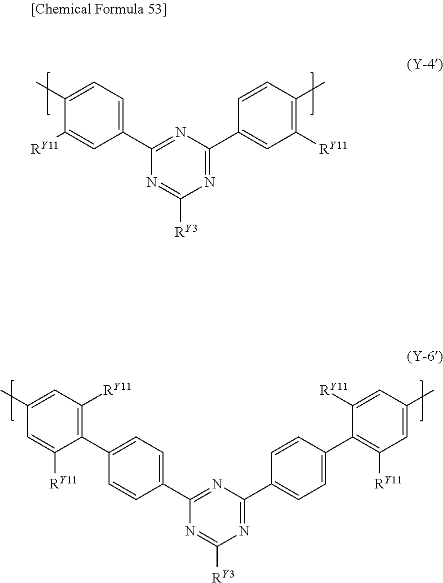

Wherein, R^{Y11} and R^{Y3} represent the same meaning as described above.

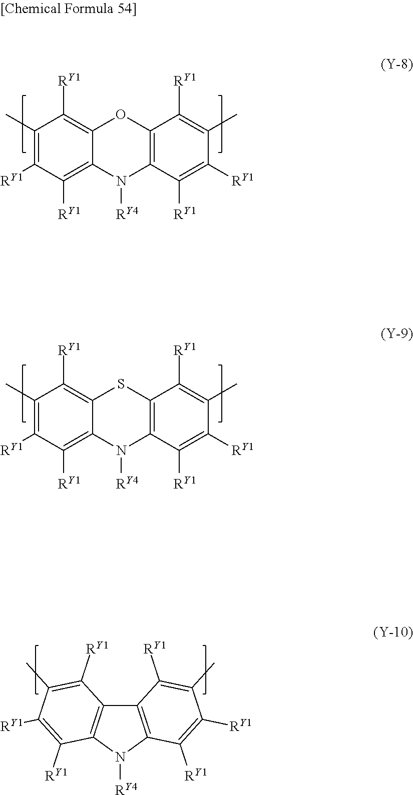

Wherein, R^{Y1} represents the same meaning as described above. R^{Y4} represents a hydrogen atom, an alkyl group, a cycloalkyl group, an alkoxy group, a cycloalkoxy group, an aryl group or a monovalent heterocyclic group, and these groups each optionally have a substituent.

R^{Y4} is preferably an alkyl group, a cycloalkyl group, an alkoxy group, a cycloalkoxy group, an aryl group or a monovalent heterocyclic group, more preferably an aryl group, and these groups each optionally have a substituent.

The constitutional unit represented by the formula (Y) includes, for example, a constitutional unit composed of an arylene group represented by the formula (Y-101), (Y-102), (Y-103), (Y-104), (Y-105), (Y-106), (Y-107), (Y-108), (Y-109), (Y-110), (Y-111), (Y-112), (Y-113), (Y-114), (Y-115), (Y-116), (Y-117), (Y-118), (Y-119), (Y-20) or (Y-121) (hereinafter, referred to as “arylene groups represented by the formulae (Y-101) to (Y-121)” in some cases), a constitutional unit composed of a divalent heterocyclic group represented by the formula (Y-201), (Y-202), (Y-203), (Y-204), (Y-205) or (Y-206) (hereinafter, referred to as “divalent heterocyclic groups represented by the formulae (Y-201) to (Y-206)” in some cases), and a constitutional unit composed of a divalent group in which at least one arylene group and at least one divalent heterocyclic group are bonded directly to each other represented by the formula (Y-301), (Y-302), (Y-303) or (Y-304) (hereinafter, referred to as “the formulae (Y-301) to (Y-304)” in some cases).

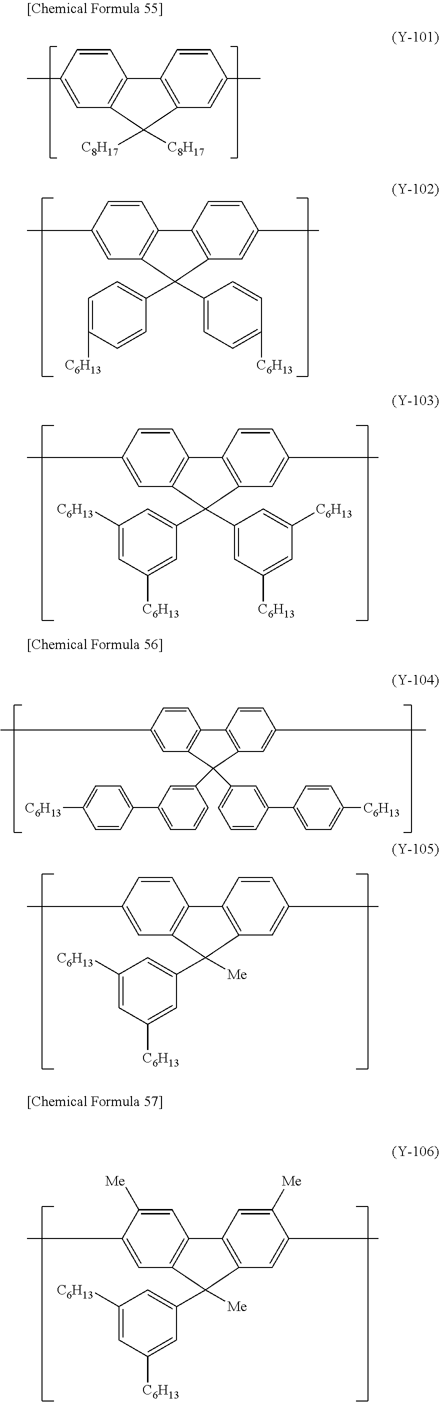

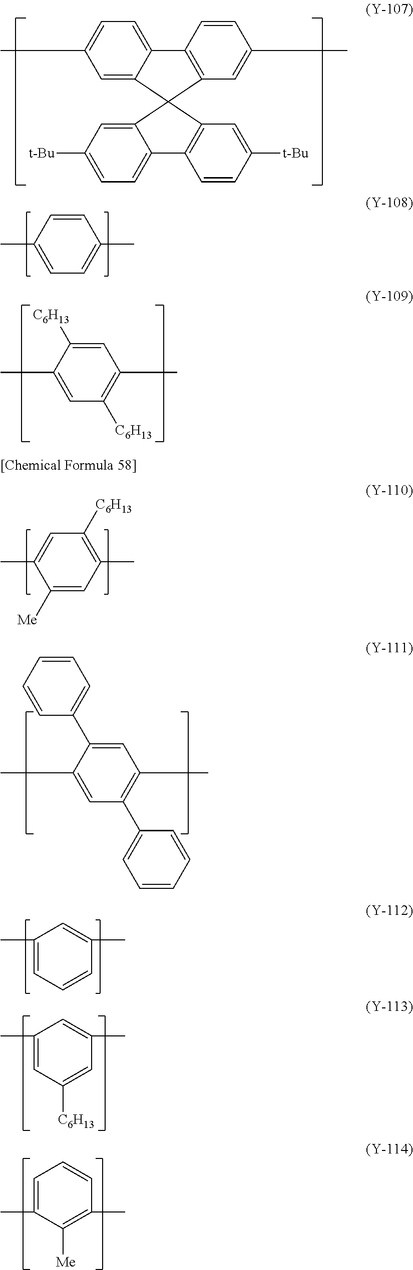

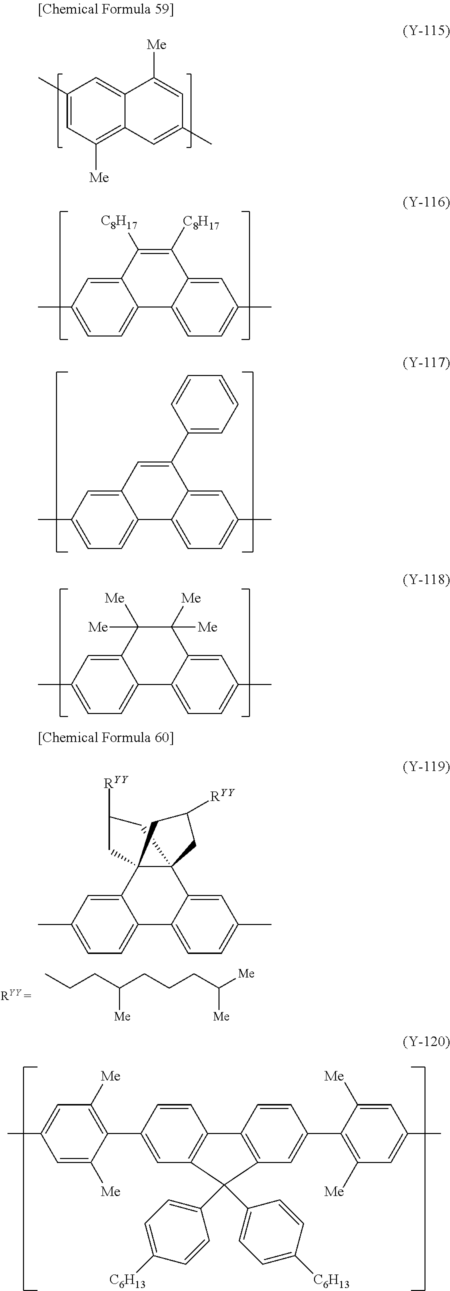

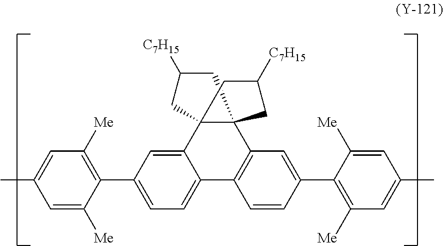

When the constitutional unit represented by the formula (Y) in which Ar^{Y1} is an arylene group is contained in a predetermined amount, the luminance life of the light-emitting device is likely to be better.

Hence, it is preferable that the polymer compound is one obtained by polymerizing a monomer to make the above constitutional unit in a proportion of 0.5 to 80% by mol (preferably 30 to 60% by mol) to the total amount of the monomers to form the polymer compound.

When the constitutional unit represented by the formula (Y) in which Ar^{Y1} is a divalent heterocyclic group or a divalent group in which at least one arylene group and at least one divalent heterocyclic group are bonded directly to each other is contained in a predetermined amount, the charge transportability of the light-emitting device is likely to be better. Hence, it is preferable that the polymer compound is one obtained by polymerizing a monomer to make the above constitutional unit in a proportion of 0.5 to 30% by mol (preferably 3 to 20% by mol) to the total amount of the monomers to form the polymer compound.

The constitutional unit represented by the formula (Y) may be contained only singly or two or more units thereof may be contained in the polymer host.

It is preferable that the polymer host further comprises a constitutional unit represented by the following formula (X), because hole transportability is excellent.

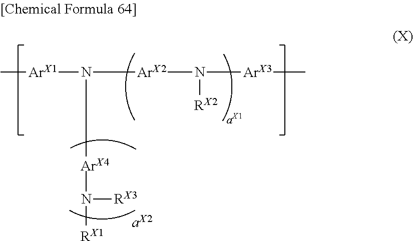

Wherein,

a^{X1} and a^{X2} each independently represent an integer of 0 or more.

Ar^{X1} and Ar^{X3} each independently represent an arylene group or a divalent heterocyclic group, and these groups each optionally have a substituent.

Ar^{X2} and Ar^{X4} each independently represent an arylene group, a divalent heterocyclic group or a divalent group in which at least one arylene group and at least one divalent heterocyclic group are bonded directly to each other, and these groups each optionally have a substituent. When a plurality of Ar^{X2} and Ar^{X4} are present, they may be the same or different at each occurrence.

R^{X1}, R^{X2} and R^{X3} each independently represent a hydrogen atom, an alkyl group, a cycloalkyl group, an aryl group or a monovalent heterocyclic group, and these groups each optionally have a substituent.

When a plurality of R^{X2} and R^{X3} are present, they may be the same or different at each occurrence.

a^{X1} is preferably 2 or less, more preferably 1, because the luminance life of the light-emitting device of the present embodiment is excellent.

a^{X2} is preferably 2 or less, more preferably 0, because the luminance life of the light-emitting device of the present embodiment is excellent.

R^{X1}, R^{X2} and R^{X3} are preferably an alkyl group, a cycloalkyl group, an aryl group or a monovalent heterocyclic group, more preferably an aryl group, and these groups each optionally have a substituent.

The arylene group represented by Ar^{X1} and Ar^{X3} is more preferably a group represented by the formula (A-1) or the formula (A-9), further preferably a group represented by the formula (A-1), and these groups each optionally have a substituent.

The divalent heterocyclic group represented by Ar^{X1} and Ar^{X3} is more preferably a group represented by the formula (AA-1), the formula (AA-2) or the formula (AA-7) to (AA-26), and these groups each optionally have a substituent.

Ar^{X1} and Ar^{X3} are preferably an arylene group optionally having a substituent.

The arylene group represented by Ar^{X2} and Ar^{X4} is more preferably a group represented by the formula (A-1), the formula (A-6), the formula (A-7), the formula (A-9) to (A-11) or the formula (A-19), and these groups each optionally have a substituent.

The more preferable range of the divalent heterocyclic group represented by Ar^{X2} and Ar^{X4} is the same as the more preferable range of the divalent heterocyclic group represented by Ar^{X2} and Ar^{X3}.

The more preferable range and the further preferable range of the arylene group and the divalent heterocyclic group in the divalent group in which at least one arylene group and at least one divalent heterocyclic group are bonded directly to each other represented by Ar^{X2} and Ar^{X4} are the same as the more preferable range and the further preferable range of the arylene group and the divalent heterocyclic group represented by Ar^{X1} and Ar^{X3}, respectively.

The divalent group in which at least one arylene group and at least one divalent heterocyclic group are bonded directly to each other represented by Ar^{X2} and Ar^{X4} includes the same groups as the divalent group in which at least one arylene group and at least one divalent heterocyclic group are bonded directly to each other represented by Ar^{Y1} in the formula (Y).

Ar^{X2} and Ar^{X4} are preferably an arylene group optionally having a substituent.

The substituent which the group represented by Ar^{X1} to Ar^{X4} and R^{X1} to R^{X3} optionally has is preferably an alkyl group, a cycloalkyl group or an aryl group, and these groups each optionally further have a substituent.

The constitutional unit represented by the formula (X) is preferably a constitutional unit represented by the formula (X-1), (X-2), (X-3), (X-4), (X-5), (X-6) or (X-7) (hereinafter, referred to as “constitutional units represented by the formulae (Y-1) to (Y-7)” in some cases), more preferably a constitutional unit represented by the formula (X-1) to (X-6), further preferably a constitutional unit represented by the formula (X-3) to (X-6).

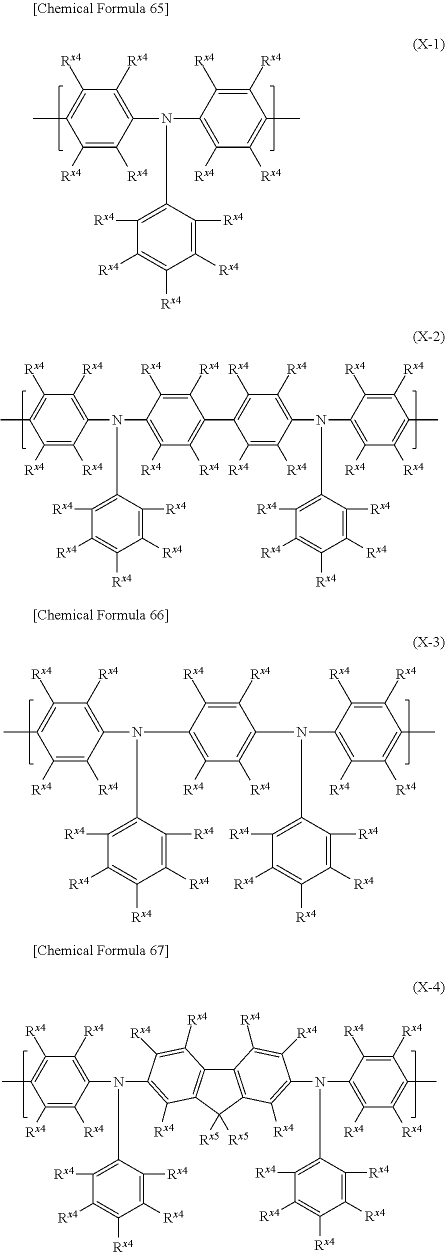

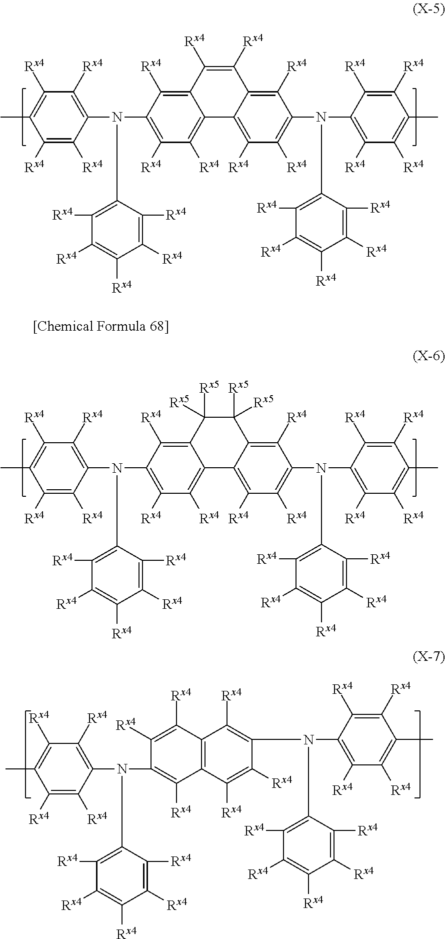

Wherein, R^{X4} and R^{X5} each independently represent a hydrogen atom, an alkyl group, a cycloalkyl group, an alkoxy group, a cycloalkoxy group, an aryl group, an aryloxy group, a halogen atom, a monovalent heterocyclic group or a cyano group, and these groups each optionally have a substituent. The plurality of R^{X4} may be the same or different. The plurality of R^{X5} may be the same or different, and adjacent groups R^{X5} may be combined together to form a ring together with the carbon atoms to which they are attached.

It is preferable that the constitutional unit represented by the formula (X) is contained in a predetermined amount in the polymer host, because the hole transportability is excellent. That is, it is preferable that the polymer host is one obtained by polymerizing a monomer to form the constitutional unit represented by the formula (X) in a proportion of preferably 0.1 to 50% by mol (more preferably 1 to 40% by mass, further preferably 5 to 30% by mass) to the total amount of the monomers to form the polymer host.

The constitutional unit represented by the formula (X) includes, for example, constitutional units represented by the formula (X1-1), (X1-2), (X1-3), (X1-4), (X1-5), (X1-6), (X1-7), (X1-8), (X1-9), (X1-10) or (X1-11) (hereinafter, referred to as “constitutional units represented by the formulae (X1-1) to (X1-11)” in some cases), preferably constitutional units represented by the formulae (X1-3) to (X1-10).

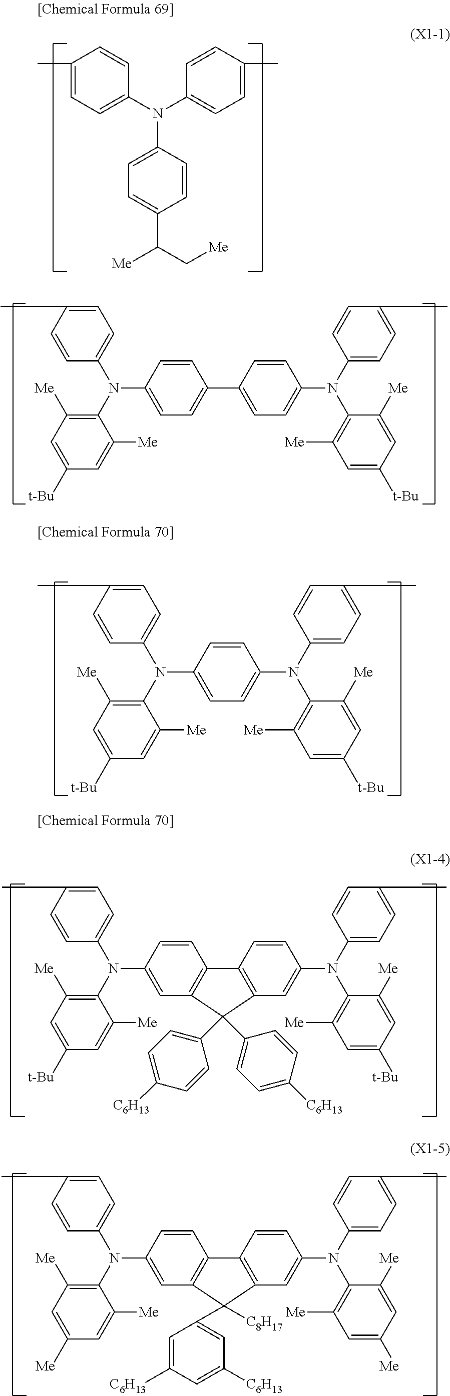

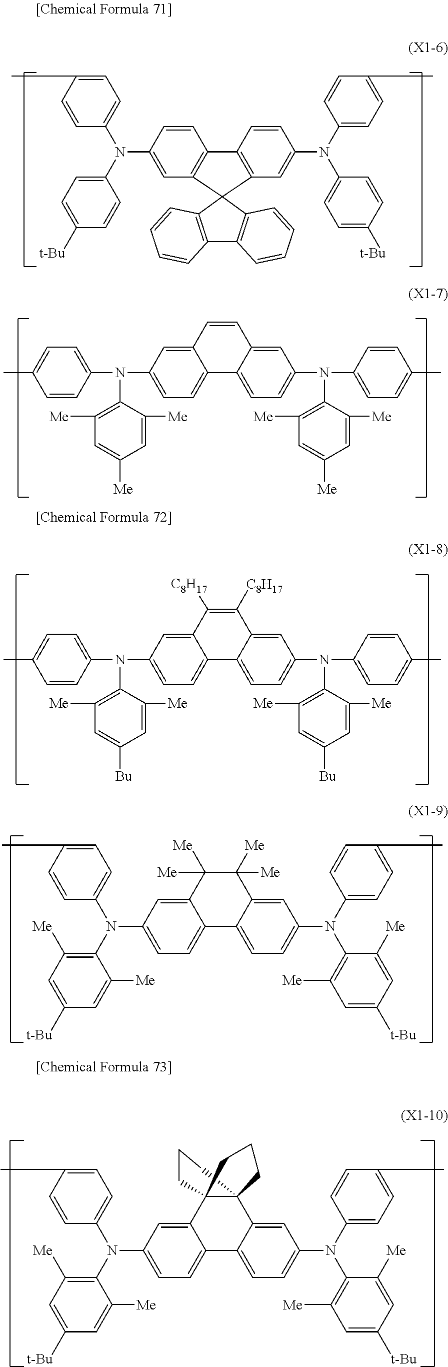

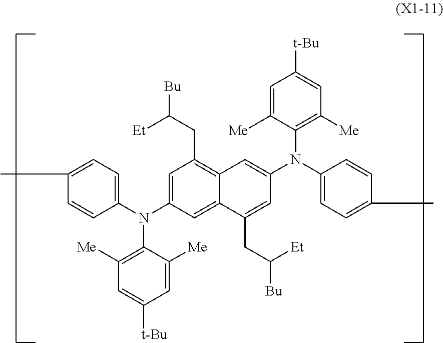

The constitutional unit represented by the formula (X) may be contained only singly or two or more units thereof may be contained in the polymer host.

The polymer host include, for example, polymer compounds (P-1), (P-2), (P-3), (P-4), (P-5) and (P-6) in the Table 1.

TABLE 1

| | constitutional unit and mole fraction thereof | | | | |
|---|---|---|---|---|---|
| | | | | formula | |
| | formula (Y) | | | (X) | |
| | | formulae | formulae | formulae | |
| | formulae | (Y-4) to | (Y-8) to | (X-1) to | |
| polymer | (Y-1) to (Y-3) | (Y-7) | (Y-10) | (X-7) | other |
| compound | p | q | r | s | t |
| (P-1) | 0.1 to 99.9 | 0.1 to 99.9 | 0 | 0 | 0 to 30 |
| (P-2) | 0.1 to 99.9 | 0 | 0.1 to 99.9 | 0 | 0 to 30 |
| (P-3) | 0.1 to 99.8 | 0.1 to 99.8 | 0 | 0.1 to 99.8 | 0 to 30 |
| (P-4) | 0.1 to 99.8 | 0.1 to 99.8 | 0.1 to 99.8 | 0 | 0 to 30 |
| (P-5) | 0.1 to 99.8 | 0 | 0.1 to 99.8 | 0.1 to 99.8 | 0 to 30 |
| (P-6) | 0.1 to 99.7 | 0.1 to 99.7 | 0.1 to 99.7 | 0.1 to 99.7 | 0 to 30 |

In the table 1, p, q, r, s and t represent the mole fraction of each constitutional unit. p+q+r+s+t=100, and 100≧p+q+r+s≧70. “Other” denotes a constitutional unit other than the constitutional unit represented by the formula (Y) and the constitutional unit represented by the formula (X).

The polymer host may be any of a block copolymer, a random copolymer, an alternating copolymer or a graft copolymer, and may also be another embodiment, and is preferably a copolymer produced by copolymerizing a plurality of raw material monomers.

<Production Method of Polymer Host>

The polymer host can be produced by using a known polymerization method described in Chem. Rev., vol. 109, pp. 897-1091 (2009) and the like, exemplified are methods of causing polymerization by a coupling reaction using a transition metal catalyst such as the Suzuki reaction, the Yamamoto reaction, the Buchwald reaction, the Stille reaction, the Negishi reaction and the Kumada reaction.

In the polymerization method described above, the method of charging monomers includes, for example, a method in which the total amount of monomers is charged in a lump into the reaction system, a method in which monomers are partially charged and reacted, then, the remaining monomers are charged in a lump, continuously or in divided doses, and a method in which monomers are charged continuously or in divided doses.

The transition metal catalyst includes a palladium catalyst, a nicked catalyst and the like.

For the post treatment of the polymerization reaction, known methods, for example, a method of removing water-soluble impurities by liquid-separation, a method in which the reaction solution after the polymerization reaction is added to a lower alcohol such as methanol to cause deposition of a precipitate which is then filtrated before drying, and other methods, are used each singly or combined. When the purity of the polymer host is low, the polymer host can be purified by usual methods such as, for example, recrystallization, reprecipitation, continuous extraction with a Soxhlet extractor and column chromatography.

[Composition of the First Organic Layer]

The first organic layer may be a layer formed by using a composition (hereinafter, referred to also as “composition of the first organic layer”) comprising one or more phosphorescent compounds represented by the formula (1), and at least one material selected from the group consisting of the host material described above, a hole transporting material, a hole injection material, an electron transporting material, an electron injection material, a light emitting material, an antioxidant and a solvent. Further the first organic layer may be a layer comprising the composition of the first organic layer.

[Hole Transporting Material]

The hole transporting material is classified into low molecular weight compounds and polymer compounds, and polymer compounds are preferable. The hole transporting material optionally has a crosslinkable group.

The polymer compound includes, for example, polyvinylcarbazole and derivatives thereof; polyarylene having an aromatic amine structure in the side chain or main chain and derivatives thereof. The polymer compound may also be a compound in which an electron accepting portion is linked. The electron accepting portion includes, for example, fullerene, tetrafluorotetracyanoquinodimethane, tetracyanoethylene, trinitrofluorenone and the like, preferably fullerene.

In the composition of the first organic layer, the compounding amount of the hole transporting material is usually 1 to 400 parts by weight, preferably 5 to 150 parts by weight when the content of the phosphorescent compound represented by the formula (1) is 100 parts by weight.

The hole transporting material may be used singly, or two or more hole transporting materials may be used in combination.

[Electron Transporting Material]

The electron transporting material is classified into low molecular weight compounds and polymer compounds. The electron transporting material optionally has a crosslinkable group.

The low molecular weight compound includes, for example, a metal complex having 8-hydroxyquinoline as a ligand, oxadiazole, anthraquinodimethane, benzoquinone, naphthoquinone, anthraquinone, tetracyanoanthraquinodimethane, fluorenone, diphenyldicyanoethylene, diphenoquinone and derivatives thereof.

The polymer compound includes, for example, polyphenylene, polyfluorene and derivatives thereof. These polymer compounds may be doped with a metal.

In the composition of the first organic layer, the compounding amount of the electron transporting material is usually 1 to 400 parts by weight, preferably 5 to 150 parts by weight when the content of the phosphorescent compound represented by the formula (1) is 100 parts by weight.

The electron transporting material may be used singly, or two or more electron transporting materials may be used in combination.

[Hole Injection Material and Electron Injection Material]

The hole injection material and the electron injection material are each classified into low molecular weight compounds and polymer compounds. The hole injection material and the electron injection material each optionally have a crosslinkable group.

The low molecular weight compound includes, for example, metal phthalocyanines such as copper phthalocyanine; carbon; oxides of metals such as molybdenum and tungsten; metal fluorides such as lithium, fluoride, sodium fluoride, cesium fluoride and potassium fluoride.

The polymer compound includes, for example, polyaniline, polythiophene, polypyrrole, polyphenylenevinylene, polythienylenevinylene, polyquinoline and polyquinoxaline, and derivatives thereof; electrically conductive polymers such as a polymer comprising an aromatic amine structure in the main chain or side chain.

In the composition of the first organic layer, the compounding amounts of the hole injection material and the electron injection material are each usually 1 to 400 parts by weight, preferably 5 to 150 parts by weight when the content of the phosphorescent compound represented by the formula (1) is 100 parts by weight.

The hole injection material and the electron injection material may each be used singly, or two or more of them may be used in combination.

[Ion Dope]

When the hole injection material or the electron injection material comprises an electrically conductive polymer, the electric conductivity of the electrically conductive polymer is preferably 1×10⁻⁵ S/cm to 1×10³ S/cm. For adjusting the electric conductivity of the electrically conductive polymer within such a range, the electrically conductive polymer can be doped with a suitable amount of ions.

The kind of the ion to be doped is an anion for a hole injection material and a cation for an electron injection material. The anion includes, for example, a polystyrenesulfonate ion, an alkylbenzenesulfonate ion and a camphorsulfonate ion. The cation includes, for example, a lithium ion, a sodium ion, a potassium ion and a tetrabutylammonium ion.

The ion to be doped may be used singly, or two or more ions to be doped may be used.

[Light Emitting Material]

The light emitting material (different from the phosphorescent compound represented by the formula (1)) is classified into low molecular weight compounds and polymer compounds. The light emitting material optionally has a crosslinkable group.

The low molecular weight compound includes, for example, naphthalene and derivatives thereof, anthracene and derivatives thereof, and perylene and derivatives thereof.

The polymer compound includes, for example, polymer compounds comprising a phenylene group, a naphthalenediyl group, an anthracenediyl group, a fluorenediyl group, a phenanthrenediyl group, dihydrophenanthrenediyl group, a group represented by the formula (X), a carbazolediyl group, a phenoxazinediyl group, a phenothiazinediyl group, a pyrenediyl group and the like.

In the composition of the first organic layer, the compounding amount of the light emitting material is usually 1 to 400 parts by weight, preferably 5 to 150 parts by weight when the content of the phosphorescent compound represented by the formula (1) is 100 parts by weight.

The light emitting material may be used singly, or two or more light emitting materials may be used in combination.

[Antioxidant]

The antioxidant may advantageously be one which is soluble in the same solvent as for a phosphorescent compound and does not disturb light emission and charge transportation, and the examples thereof include phenol-based antioxidants and phosphorus-based antioxidants.

In the composition of the first organic layer, the compounding amount of the antioxidant is usually 0.001 to 10 parts by weight when the content of the phosphorescent compound represented by the formula (1) is 100 parts by weight.

The antioxidant may be used singly, or two or more antioxidants may be used in combination.

[Ink of First Organic Layer]

The composition of the first organic layer comprising a solvent (hereinafter, referred to also as “ink of first organic layer”.) can be suitably used in application methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a capillary coat method and a nozzle coat method.

The viscosity of the ink of the first organic layer may be adjusted depending on the kind of the application method, and when a solution goes through a discharge apparatus such as in an inkjet printing method, the viscosity is preferably in the range of 1 to 20 mPa·s at 25° C. because curved aviation and clogging in discharging are unlikely.

As the solvent contained in the ink of the first organic layer, those capable of dissolving or uniformly dispersing solid components in the ink are preferable. The solvent includes, for example, chlorine-based solvents such as 1,2-dichloroethane, 1,1,2-trichloroethane, chlorobenzene and o-dichlorobenzene; ether solvents such as THF (tetrahydrofuran), dioxane, anisole and 4-methylanisole; aromatic hydrocarbon solvents such as toluene, xylene, mesitylene, ethylbenzene, n-hexylbenzene and cyclohexylbenzene; aliphatic hydrocarbon solvents such as cyclohexane, methylcyclohexane, n-pentane, n-hexane, n-heptane, n-octane, n-nonane, n-decane, n-dodecane and bicyclohexyl; ketone solvents such as acetone, methylethylketone, cyclohexanone and acetophenone; ester solvents such as ethyl acetate, butyl acetate, ethylcellosolve acetate, methyl benzoate and phenyl acetate; poly-hydric alcohol solvents such as ethylene glycol, glycerin and 1,2-hexanediol and derivatives thereof; alcohol solvents such as isopropylalcohol and cyclohexanol; sulfoxide solvents such as dimethyl sulfoxide; and amide solvents such as N-methyl-2-pyrrolidone and N,N-dimethylformamide.

These solvents may be used singly, or two or more of them may be used in combination.

In the ink of the first organic layer, the compounding amount of the solvent is usually 1000 to 1.00000 parts by weight, preferably 2000 to 20000 parts by weight when the content of the phosphorescent compound represented by the formula (1) is 100 parts by weight.

<Second Organic Layer>

The second organic layer is a layer formed by using a polymer composition in. which one or two or more polymer compounds including a crosslinkable polymer compound having a crosslinkable group are compounded. The second organic layer preferably comprises a cured polymer product formed from the polymer composition.

In one suitable aspect, with respect to each monomer unit constituting the polymer compounds (one or two or more polymer compounds including a crosslinkable polymer compound), the value×obtained by multiplying the molar ratio C of the each monomer unit to the total mol of all the monomer units by the molecular weight M of the each monomer unit, and the value y obtained by multiplying the molar ratio C by the number n of the crosslinkable groups in the each monomer unit are determined, the value of (Y₁×1000)/X₁ calculated from the total. X₁ of the values x and the total Y₁ of the values y being 0.5 or more.

In the case where the second organic layer is a layer formed by using one polymer compound (crosslinkable polymer compound having a crosslinkable group), with respect to each monomer unit constituting the one polymer compound, the value x obtained by multiplying the molar ratio C of the each monomer unit to the total mol of all the monomer units by the molecular weight M of the each monomer unit, and the value y obtained by multiplying the molar ratio C by the number n of the crosslinkable groups in the each monomer unit are determined, the value of (Y₁×1000)/X₁ calculated from the total X₁ of the values x and the total Y₁ of the values y being 0.5 or more.

In the case where the second organic layer is a layer formed by using a polymer composition in which two or more polymer compounds including a crosslinkable polymer compound having a crosslinkable group are compounded, the weighted average (an average value from the compounding amount ratios of the two or more polymer compounds) of the values of (Y₁×1000)/X₁ determined for the each polymer compound is 0.5 or more.

In the case where the second organic layer is a layer formed by using a polymer composition in which a crosslinkable polymer compound having a crosslinkable group and a polymer compound having no crosslinkable group are compounded, examples of the polymer compound having no crosslinkable group include polymer compounds comprising at least one constitutional unit selected from the group consisting of the constitutional unit represented by the formula (Y) and the constitutional unit represented by the formula (X).

[Crosslinkable Polymer Compound]

It is preferable that the crosslinkable polymer compound is a polymer compound having at least one crosslinkable group selected from the Group A of crosslinkable groups, because the external quantum efficiency of the light-emitting device according to the present embodiment is excellent.

The crosslinkable group selected from the Group A of crosslinkable groups is, because the luminance life of the light-emitting device according to the present embodiment is better, preferably a crosslinkable group represented by the formula (XL-1), (XL-3), (XL-9), (XL-16) or (XL-17), more preferably crosslinkable group represented by the formula (XL-1), (XL-16) or (XL-17), and further preferably a crosslinkable group represented by the formula (XL-1) or (XL-17).

The crosslinkable polymer compound comprises a constitutional unit (hereinafter, referred to also as “crosslinkable constitutional unit”) having a crosslinkable group. Although it is preferable that the crosslinkable constitutional unit is a constitutional unit represented by the above formula (2) or the above formula (3), the crosslinkable constitutional unit may be a constitutional unit represented by the following formula.

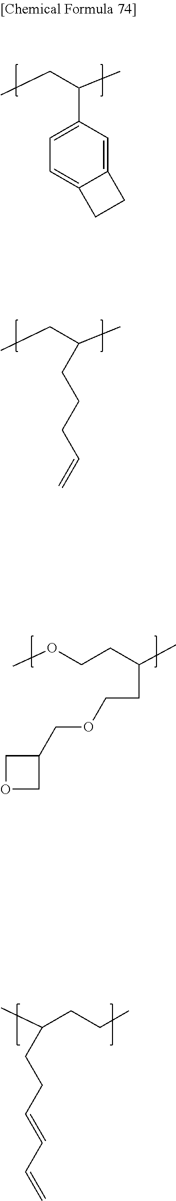

It is preferable that the crosslinkable polymer compound comprises a crosslinkable constitutional unit having at least one crosslinkable group selected from the Group A of crosslinkable groups, and it is preferable that the crosslinkable constitutional unit is a constitutional unit represented by the above formula (2) or the above formula (3).

nA is preferably an integer of 0 to 2, more preferably 0 or 1, further preferably 0, because the light-emitting device of the present embodiment is excellent in external quantum efficiency.

n is preferably 2, because the light-emitting device of the present embodiment is excellent in external quantum efficiency.

Ar¹ is preferably an aromatic hydrocarbon group optionally having a substituent, because the light-emitting device of the present embodiment is excellent in external quantum efficiency.

The number of carbon atoms constituting the aromatic ring in the aromatic hydrocarbon group represented by Ar¹ is usually 6 to 60, preferably 6 to 30, more preferably 6 to 18.

The arylene group portion obtained by removing n substituents of the aromatic hydrocarbon group represented by Ar¹ is preferably a group represented by the formula (A-1) to the formula (A-20), more preferably a group represented by the formula (A-1), the formula (A-2), the formula (A-6) to the formula (A-10), the formula (A-19) or the formula (A-20), further preferably a group represented by the formula (A-1), the formula (A-2), the formula (A-7), the formula (A-9) or the formula (A-19), and these groups each optionally have a substituent.

The number of carbon atoms constituting the heterocyclic ring and the ring condensed to the heterocyclic ring in the divalent heterocyclic group in the heterocyclic group represented by Ar¹ is usually 2 to 60, preferably 3 to 20, more preferably 4 to 15.

The divalent heterocyclic group portion obtained by removing n substituents of the heterocyclic group represented by Ar¹ is preferably a group represented by the formula (AA-1) to the formula (AA-34).

The aromatic hydrocarbon group and the heterocyclic group represented by Ar¹ each optionally have a substituent, and the substituent which the aromatic hydrocarbon group and the heterocyclic group optionally have includes, for example, an alkyl group, a cycloalkyl group, an alkoxy group, a cycloalkoxy group, an aryl group, an aryloxy group, a halogen atom, a monovalent heterocyclic group and a cyano group.

The number of carbon atoms of the alkylene group represented by L^{A}, not including the number of carbon atoms of a substituent, is usually 1 to 10, preferably 1 to 5, more preferably 1 to 3. The number of carbon atoms of the cycloalkylene group represented by L^{A}, not including the number of carbon atoms of a substituent, is usually 3 to 10.

The alkylene group represented by L^{A} includes, for example, a methylene group, an ethylene group, a propylene group, a butylene group, a hexylene group and an octylene group. The alkylene group represented by L^{A} optionally has a substituent, and the substituent includes, for example, a cycloalkyl group, an alkoxy group, a cycloalkoxy group, a halogen atom and a cyano group.

The cycloalkylene group represented by L^{A} includes, for example, a cyclohexylene group and a cyclopentylene group. The cycloalkylene group represented by L^{A} optionally has a substituent, and the substituent includes, for example, an alkyl group, a cycloalkyl group, an alkoxy group, a cycloalkoxy group, a halogen atom and a cyano group.

The alkylene group and the cycloalkylene group represented by L^{A} each optionally have a substituent. The substituent which the alkylene group and the cycloalkylene group optionally have includes, for example, an alkyl group, a cycloalkyl group, an alkoxy group, a cycloalkoxy group, a halogen atom and a cyano group.

L^{A} is preferably a phenylene group or a methylene group, because production of the crosslinkable polymer compound is easy, and these groups each optionally have a substituent.

The preferable range, the more preferable range and the further preferable range of the crosslinkable group represented by X are the same as the preferable range, the more preferable range and the further preferable range of the crosslinkable group selected from the above-described Group A of crosslinkable group.

The constitutional unit represented by the formula (2) may be contained singly or two or more of the constitutional units may be contained in the crosslinkable polymer compound.

mA is preferably 0 or 1, more preferably 0, because the light-emitting device of the present embodiment is excellent in external quantum efficiency.

m is preferably 2, because the light-emitting device of the present embodiment is excellent in external quantum efficiency.

c is preferably 0, because production of the crosslinkable polymer compound is easy and because the light-emitting device of the present embodiment is excellent in external quantum efficiency.

Ar³ is preferably an aromatic hydrocarbon group optionally having a substituent, because the light-emitting device of the present embodiment is excellent in external quantum efficiency.

The definition and examples of the arylene group portion obtained by removing m substituents of the aromatic hydrocarbon group represented by Ar³ are the same as the definition and examples of the arylene group represented by Ar^{X2} in the formula (X) described above.

The definition and examples of the divalent heterocyclic group portion obtained by removing m substituents of the heterocyclic group represented by Ar³ are the same as the definition and examples of the divalent heterocyclic group portion represented by Ar^{X2} in the formula (X) described above.

The definition and examples of the divalent group obtained by removing m substituents of the group in which at least one aromatic hydrocarbon ring and at least one heterocyclic ring are bonded directly to each other represented by Ar³ are the same as the definition and examples of the divalent group in which at least one arylene group and at least one divalent heterocyclic group are bonded directly to each other represented by Ar^{X2} in the formula (X) described above.

Ar² and Ar⁴ are preferably an arylene group optionally having a substituent, because the light-emitting device of the present embodiment is more excellent in luminance life.

The definition and examples of the arylene group represented by Ar² and Ar⁴ are the same as the definition and examples of the arylene group represented by Ar^{X1} and Ar^{Y3} in the formula (X) described above.

The definition and examples of the divalent heterocyclic group represented by Ar² and Ar⁴ are the same as the definition and examples of the divalent heterocyclic group represented by Ar^{X1} and Ar^{X3} in the formula (X) described above.

The group represented by Ar², Ar³ and Ar⁴ optionally has a substituent, and the substituent includes an alkyl group, a cycloalkyl group, an alkoxy group, a cycloalkoxy group, an aryl group, an aryloxy group, a halogen atom, a monovalent heterocyclic group and a cyano group.

The definitions and examples of the alkylene group, the cycloalkylene group, the arylene group and the divalent heterocyclic group represented by K^{A} are the same as the definitions and examples of the alkylene group, the cycloalkylene group, the arylene group and the divalent heterocyclic group represented by L^{A}, respectively.

K^{A} is preferably a phenylene group or a methylene group, because production of the crosslinkable polymer compound is easy, and these groups each optionally have a substituent.

The preferable range, the more preferable range and the further preferable range of the crosslinkable group represented by X′ are the same as the preferable range, the more preferable range and the further preferable range of the crosslinkable group selected from the above-described Group A of crosslinkable group.

The constitutional unit represented by the formula (3) may be contained singly or two or more of the constitutional units may be contained in the crosslinkable polymer compound.

The constitutional unit represented by the formula (2) includes, for example, constitutional units represented by the formula (2-1), (2-2), (2-3), (2-4), (2-5), (2-6), (2-7), (2-8), (2-9), (2-10), (2-11), (2-12), (2-13), (2-14), (2-15), (2-16), (2-17), (2-18), (2-19), (2-20), (2-21), (2-22), (2-23), (2-24), (2-25), (2-26), (2-27), (2-28), (2-29) or (2-30) (hereinafter, referred to as “constitutional units represented by the formulae (2-1) to (2-30)” in some cases).

The constitutional unit represented by the formula (3) includes, for example, constitutional units represented. by the formula (3-1), (3-2), (3-3), (3-4), (3-5), (3-6), (3-7), (3-8) or (3-9) (hereinafter, referred to as “constitutional units represented by the formulae (3-1) to (3-9)” in some cases).

Of them, preferable are constitutional units represented by the formula (2-1) to the formula (2-30), more preferable are constitutional units represented by the formula (2-1) to the formula (2-15), the formula (2-19), the formula (2-20), the formula (2-23), the formula (2-25), the formula (2-27) or the formula (2-30), further preferable are constitutional units represented by the formula (2-1) to the formula (2-13), the formula (2-20), the formula (2-27) or the formula (2-30), particularly preferable are constitutional units represented by the formula (2-1) to the formula (2-9), the formula (2-20), the formula (2-27) or the formula (2-30), because the crosslinkable polymer compound is excellent in crosslinkability.

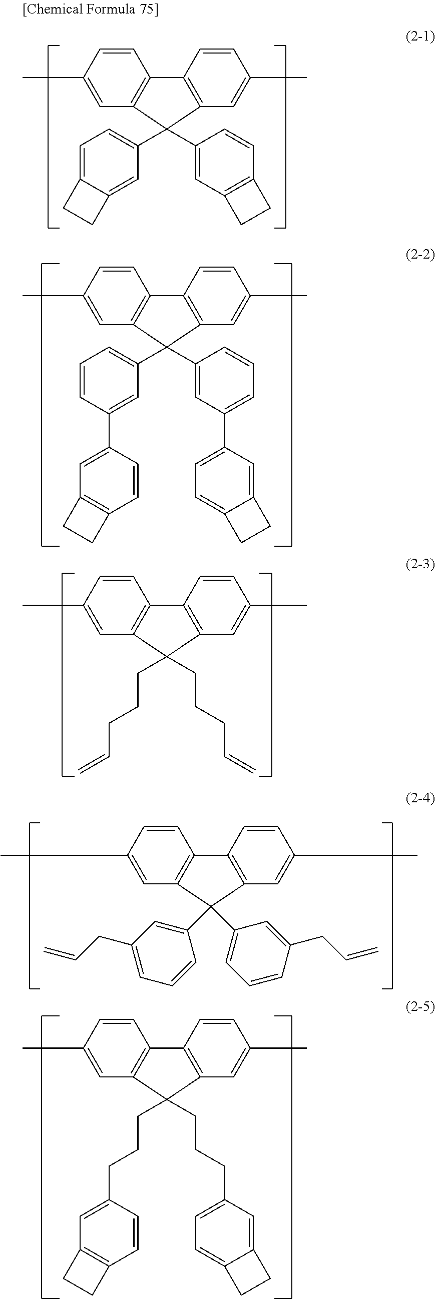

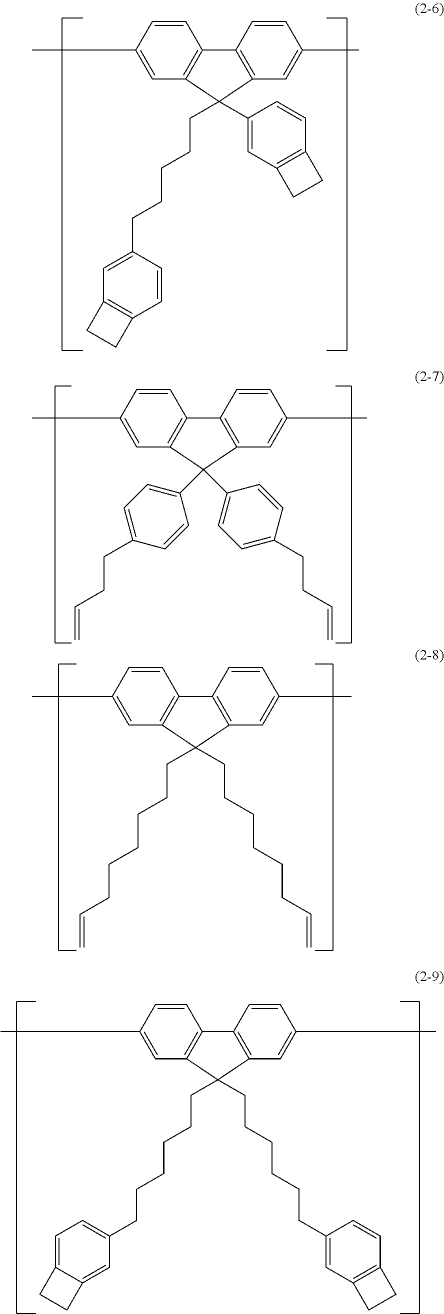

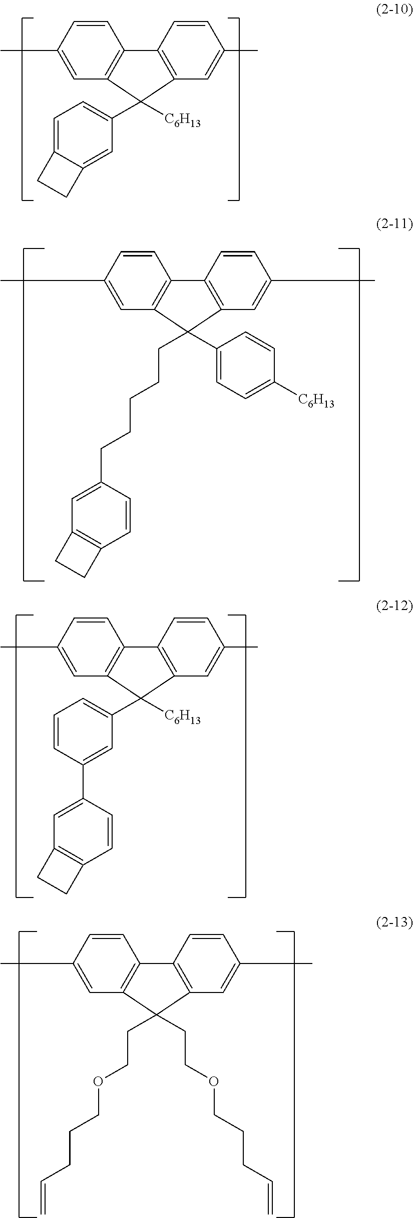

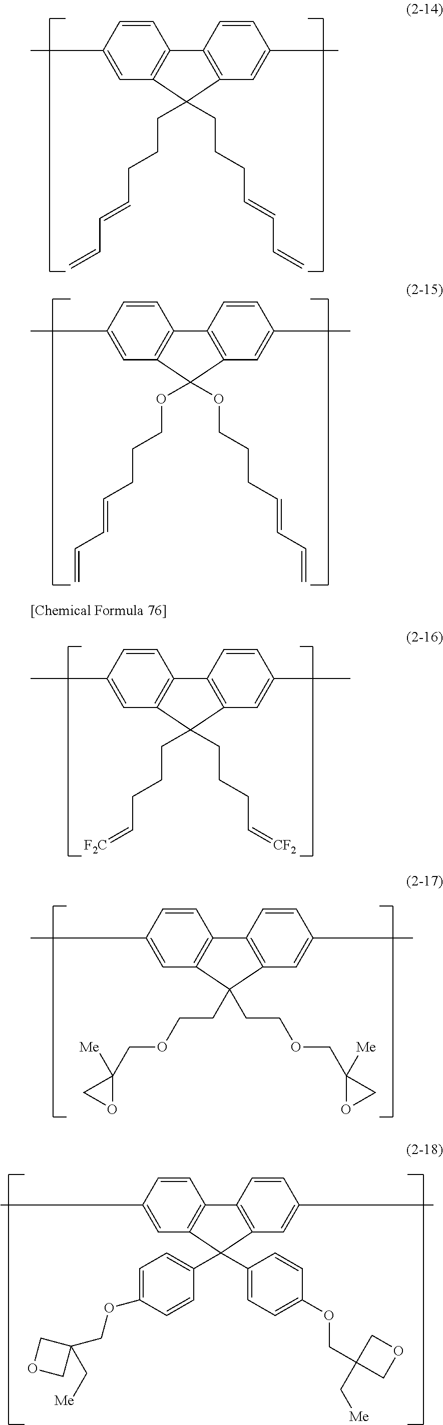

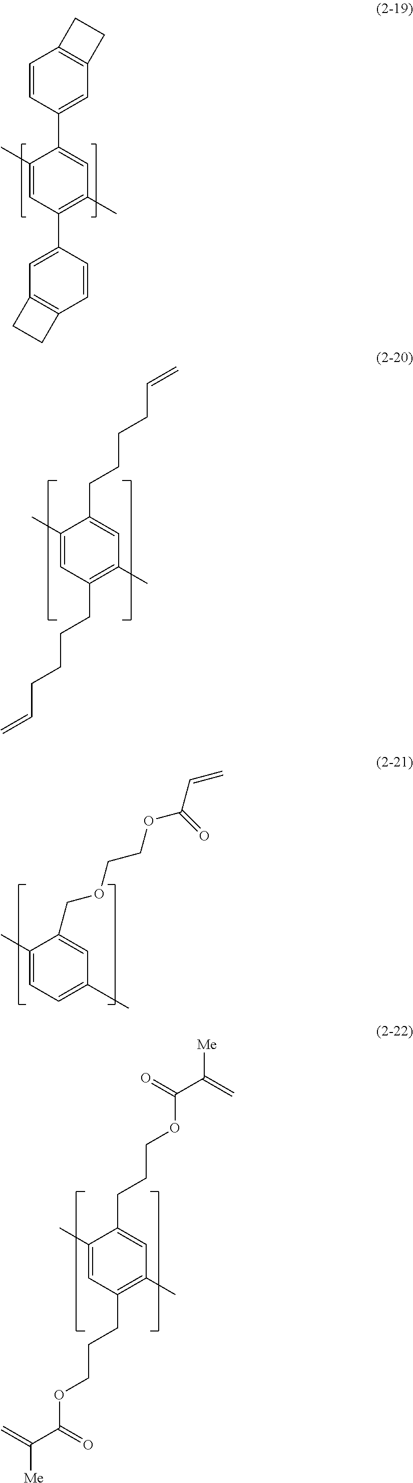

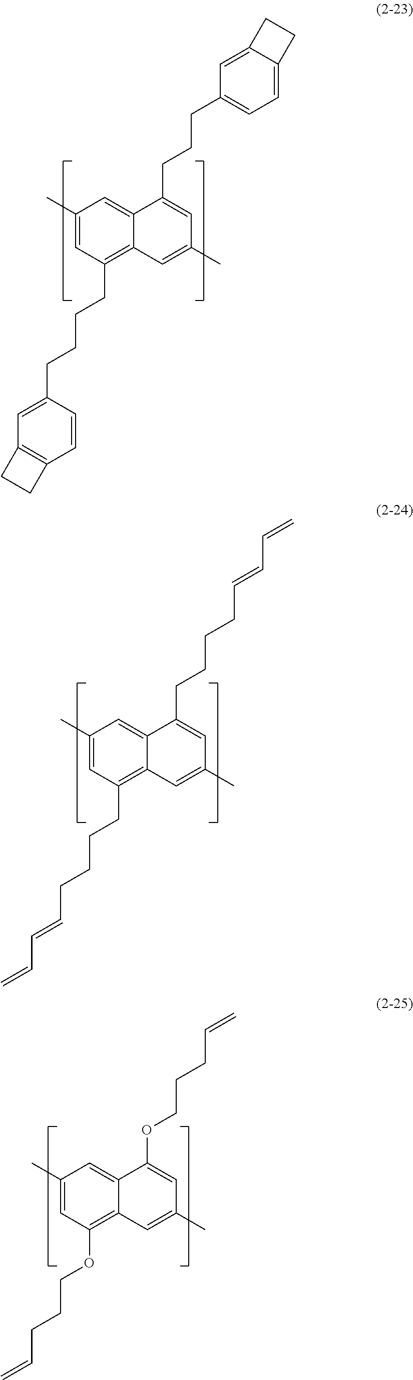

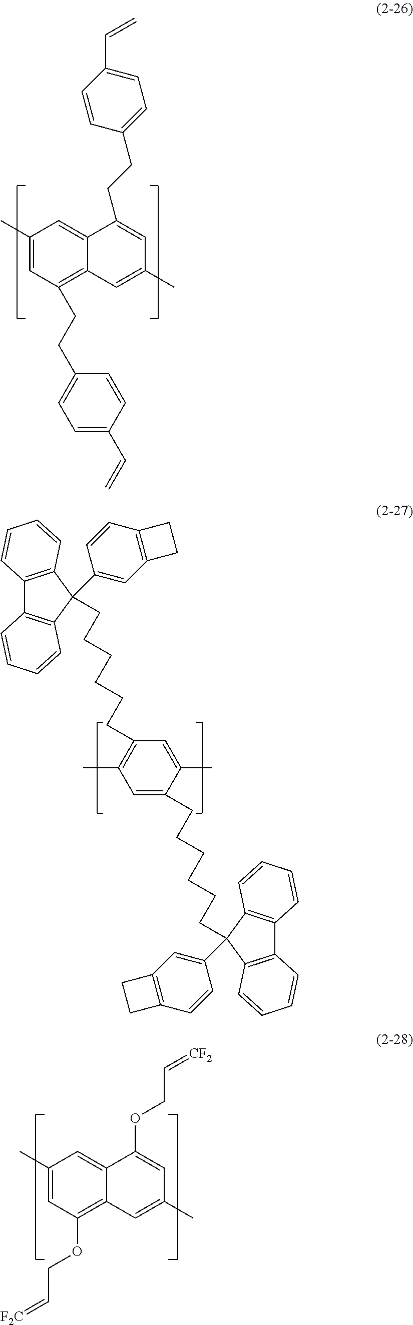

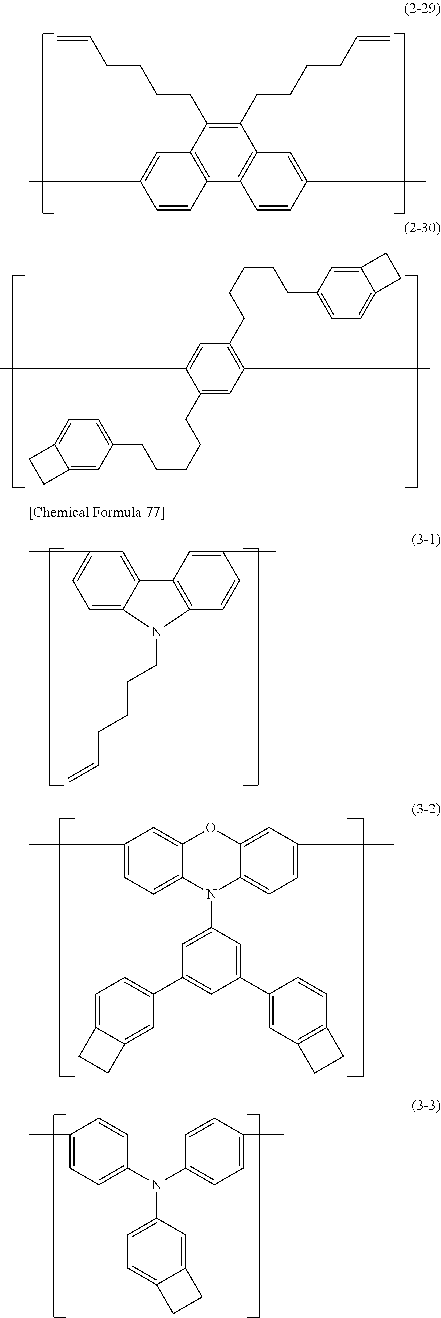

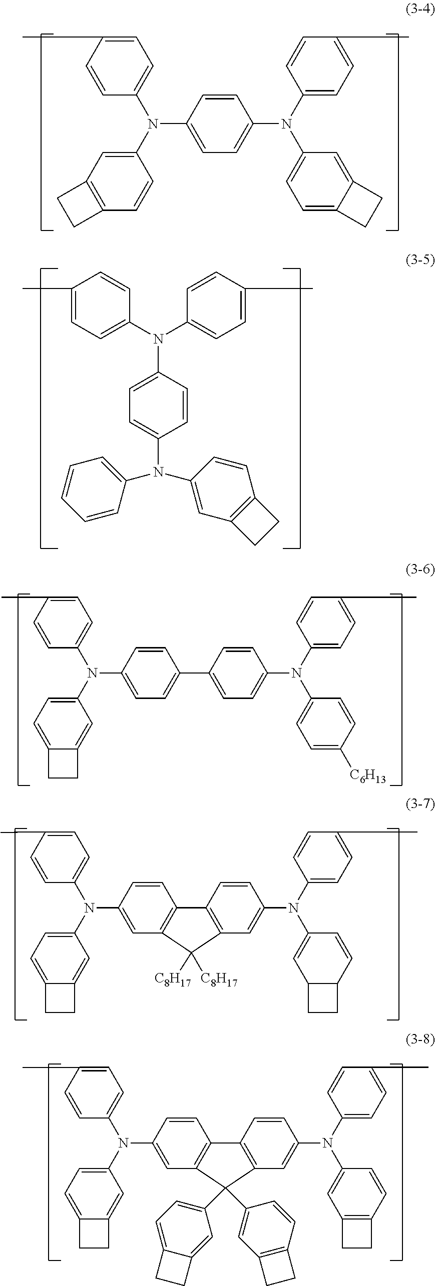

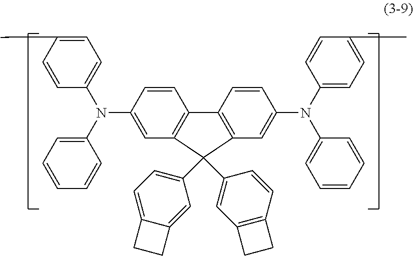

It is preferable that the crosslinkable polymer compound further comprises a constitutional unit represented by the formula (X), because the hole transportability is excellent.

The definition and examples of the constitutional unit represented by the formula (X) which the crosslinkable polymer compound may comprise are the same as the definition and examples of the constitutional unit represented by the formula (X) which the polymer host described above may comprise.

The constitutional unit represented by the formula (X) may be contained singly, or two or more units thereof may be contained in the crosslinkable polymer compound.

It is preferable that the crosslinkable polymer compound further comprises at least one constitutional unit selected from the group consisting of constitutional units represented by the formula (Y11) and constitutional units represented by the formula (Y12), because the external quantum efficiency of the light-emitting device according to the present embodiment is excellent.

When the crosslinkable polymer compound comprises at least one constitutional unit selected from the group consisting of constitutional units represented by the formula (Y11) and constitutional units represented by the formula (Y12), and a constitutional unit represented by the formula (2), it is preferable that with respect to each monomer unit constituting the crosslinkable polymer compound, the value x obtained by multiplying the molar ratio C of the each monomer unit to the total mol of all the monomer units by the molecular weight M of the each monomer unit, and the value y obtained by multiplying the molar ratio C by the number n of the crosslinkable groups in the each monomer unit are determined, the value of (Y₁×1000)/X₁ calculated from the total X₁ of the values x and the total Y₁ of the values y being 0.5 or more, because the external quantum efficiency of the light-emitting device according to the present embodiment is excellent.

When the crosslinkable polymer compound comprises at least one constitutional unit selected from the group consisting of constitutional units represented by the formula (Y11) and constitutional units represented by the formula (Y12), and a constitutional unit represented by the formula (3), it is preferable that with respect to each monomer unit constituting the crosslinkable polymer compound, the value x obtained by multiplying the molar ratio C of the each monomer unit to the total mol of all the monomer units by the molecular weight M of the each monomer unit, and the value y obtained by multiplying the molar ratio C by the number n of the crosslinkable groups in the each monomer unit are determined, the value of (Y₁×1000)/X₁ calculated from the total X₁ of the values x and the total Y₁ of the values y being 1.10 or more, because the external quantum efficiency of the light-emitting device according to the present embodiment is excellent.

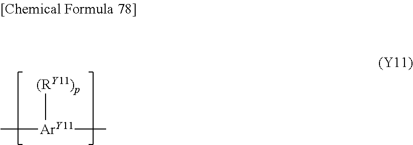

Wherein,

Ar^{Y11} represents an aromatic hydrocarbon group, and the group optionally has a substituent other than R^{Y11};

p represents an integer of 1 or more; and

R^{Y11} represents an alkyl group, an alkoxy group, an aryl group or a monovalent heterocyclic group, and these groups each optionally have a substituent; and when a plurality of R^{Y11} are present, they may be the same or different; provided that at least one of R^{Y11} links to a carbon atom adjacent to a carbon atom forming a bond with another constitutional unit.

[Chemical Formula 79]

+Ar^{Y12}X^{Y12}_{q}Ar^{Y12} (Y12)

Wherein,

Ar^{Y12} represents an arylene group or a divalent heterocyclic group, and these groups each optionally have a substituent; and the plurality of Ar^{Y12} may be the same or different;

q represents an integer of 1 to 5; and

X^{Y12} represents an alkyl group, a cycloalkylene group, an oxygen atom or a sulfur atom, and these groups each optionally have a substituent; and when a plurality of X^{Y12} are present, they may be the same or different.

The aromatic hydrocarbon group of Ar^{Y11} in the formula (Y11) denotes a group obtained by removing from an aromatic hydrocarbon one or more hydrogen atoms directly linked to carbon atoms constituting the aromatic ring. The aromatic hydrocarbon preferably includes benzene, fluorene, naphthalene, anthracene, pyrene, chrysene and fluoranthene; benzene, fluorene, naphthalene and chrysene are preferable; more preferable are benzene, fluorene and naphthalene; and especially preferable are benzene and fluorene.

Preferable as Ar^{Y11} is a constitutional unit represented by the above formula (Y-1′), (Y-2′) or (Y-3′).

The preferable range of R^{Y11} in the formula (Y11) is the same as described above.

The definition, examples and the preferable range of Ar^{Y12} in the formula (Y12) are the same as those of Ar^{Y1}.

q in the formula (Y1.2) represents an integer of 1 to 5, and is preferably an integer of 1 to 3, more preferably an integer of 1 or 2, and further preferably 1.

q in the formula (Y12) represents an integer of 1 to 5, and is preferably an integer of 1 to 3, more preferably an integer of 1 or 2, and further preferably 1.

X^{Y12} in the formula (Y12) represents an alkylene group, a cycloalkylene group, an oxygen atom or a sulfur atom, and these groups each optionally have a substituent; and preferable as X^{Y12} are an alkylene group and a cycloalkylene group; and when a plurality of X^{Y12} are present, they may be the same or different.

The number of carbon atoms of the alkylene group is, not including the number of carbon atoms of substituents, usually 1 to 10, preferably 1 to 5, and more preferably 1 to 3. The number of carbon atoms of the cycloalkylene group is, not including the number of carbon atoms of substituents, usually 3 to 10.

Examples of the alkylene group include a methylene group, an ethylene group, a propylene group, a butylene group, a hexylene group and an octylene group. The alkylene group optionally has a substituent, and examples of the substituent include cycloalkyl groups, alkoxy groups, cycloalkoxy groups, halogen atoms and a cyano group.

Examples of the cycloalkylene group include a cyclohexylene group and a cyclopentylene group. The cycloalkylene group optionally has a substituent, and examples of the substituent include alkyl groups, cycloalkyl groups, alkoxy groups, cycloalkoxy groups, halogen atoms and a cyano group.

Examples of the constitutional unit represented by the formula (Y12) include the following.

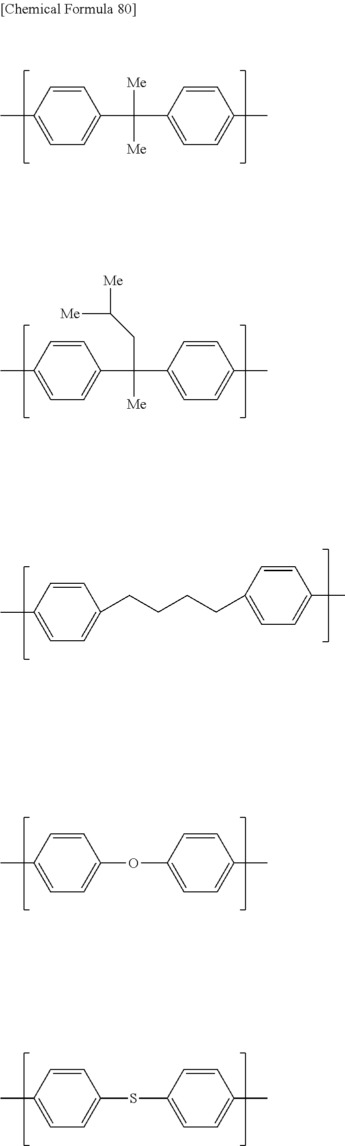

The constitutional unit represented by the formula (Y11) or (Y12) may be contained singly, or two or more units thereof may be contained in the crosslinkable polymer compound.

It is preferable that the crosslinkable polymer compound further comprises both of the constitutional unit represented by the formula (X) and the constitutional unit represented by the formula (Y11) or (Y12), because the external quantum efficiency of the light-emitting device according to the present embodiment is excellent.

Examples of the crosslinkable polymer compound include polymer compounds (P-11), (P-12), (P-13), (P-14), (P-15), (P-16), (P-17), (P-18), (P-19), (P-20), (P-21), (P-22) and (P-23), in Table 2.

TABLE 2

| | Constitutional unit and mole fraction thereof | | | | | |
|---|---|---|---|---|---|---|
| | | | Formulae | | | |
| | Formula | Formula | (X-1) to | Formula | Formula | |
| Polymer | (2) | (3) | (X-7) | (Y11) | (Y12) | Others |
| compound | p′ | q′ | r′ | s′ | t′ | u′ |
| P-11 | 0.1 to | 0 | 0.1 to | 0 | 0 | 0 to 30 |
| | 99.9 | | 99.9 | | | |
| P-12 | 0 | 0.1 to | 0.1 to | 0 | 0 | 0 to 30 |
| | | 99.9 | 99.9 | | | |
| P-13 | 0.1 to | 0 | 0 | 0.1 to | 0 | 0 to 30 |
| | 99.9 | | | 99.9 | | |
| P-14 | 0 | 0.1 to | 0 | 0.1 to | 0 | 0 to 30 |
| | | 99.9 | | 99.9 | | |
| P-15 | 0.1 to | 0 | 0.1 to | 0.1 to | 0 | 0 to 30 |
| | 99.8 | | 99.8 | 99.8 | | |
| P-16 | 0 | 0.1 to | 0.1 to | 0.1 to | 0 | 0 to 30 |
| | | 99.8 | 99.8 | 99.8 | | |
| P-17 | 0.1 to | 0.1 to | 0.1 to | 0 | 0 | 0 to 30 |
| | 99.8 | 99.8 | 99.8 | | | |
| P-18 | 0.1 to | 0 | 0.1 to | 0 | 0.1 to | 0 to 30 |
| | 99.8 | | 99.8 | | 99.8 | |
| P-19 | 0 | 0.1 to | 0.1 to | 0 | 0.1 to | 0 to 30 |
| | | 99.8 | 99.8 | | 99.8 | |
| P-20 | 0.1 to | 0.1 to | 0.1 to | 0.1 to | 0 | 0 to 30 |
| | 99.7 | 99.7 | 99.7 | 99.7 | | |
| P-21 | 0.1 to | 0.1 to | 0 | 0.1 to | 0.1 to | 0 to 30 |
| | 99.7 | 99.7 | | 99.7 | 99.7 | |
| P-22 | 0.1 to | 0.1 to | 0.1 to | 0 | 0.1 to | 0 to 30 |
| | 99.7 | 99.7 | 99.7 | | 99.7 | |
| P-23 | 0.1 to | 0.1 to | 0.1 to | 0.1 to | 0.1 to | 0 to 30 |
| | 99.6 | 99.6 | 99.6 | 99.6 | 99.6 | |

In Table 2, p′, q′, r′, s′, t′ and u′ represent the molar ratios of each constitutional unit. p′+q′+r′+s′+t′+u′=100, and 70≦p′+q′+r′+s′+t′≦100. “Others” denote a constitutional unit other than the constitutional unit represented by the formula (2), the constitutional unit represented by the formula (3), the constitutional unit represented by the formula (X) and the constitutional unit represented by the formula (Y11) or (Y12).

The crosslinkable polymer compound may be any of a block copolymer, a random copolymer, an alternating copolymer or a graft copolymer, and may also be another aspect; but it is preferable that the crosslinkable polymer compound is a copolymer produced by copolymerizing a plurality of raw material monomers.

[Production Method of the Crosslinkable Polymer Compound]

The crosslinkable polymer compound can be produced by the same production method as the method of production of the polymer host described above.

[Average Number of the Crosslinkable Groups]

In the present embodiment, the second organic layer is formed by using a polymer composition in which one or two or more polymer compounds including a crosslinkable polymer compound having a crosslinkable group are compounded. Here, the index to indicate the average number of the crosslinkable groups in the polymer compounds can be determined by the following method.

First, with respect to each monomer unit constituting the polymer compound, the value x obtained by multiplying the molar ratio C of the each monomer unit to the total mol of all the monomer units by the molecular weight M of the each monomer unit, and the value y obtained by multiplying the molar ratio C by the number n of the crosslinkable groups in the each monomer unit are determined. Then, the total of the values x determined for the each monomer unit is taken to be X₁, and the total of the values y determined for the each monomer unit is taken to be Y₁.

At this time, the value of (Y₁×1000)/X₁ becomes a value nearly equal to the average number of the crosslinkable groups per 1000 in molecular weight of the polymer compound, and can effectively be used as an index indicating the average number of the crosslinkable groups in the polymer compound. Hereinafter, the value of (Y₁×1000)/X₁ is referred to as “average number of the crosslinkable groups per 1000 in molecular weight” in some cases.

A specific calculation method of the average number of the crosslinkable groups will be described in detail by way of a polymer compound P1 used in Example 1 described below.

The polymer compound P1 has monomer units formed from a compound MM1, a compound MM2 and a compound MM3, which are monomers. The ratio to the total mol of all the monomer units is 0.45 for the monomer unit formed from the compound MM1, 0.05 for the monomer unit formed from the compound MM2, and 0.50 for the monomer unit formed from the compound MM3. Further the molecular weight of the monomer unit formed from the compound MM1 is 776.45; the molecular weight of the monomer unit formed from the compound MM2 is 240.20; and the molecular weight of the monomer unit formed from the compound MM3 is 750.51. Further the number of the crosslinkable groups the monomer unit formed from the compound MM1 has is 2; the number of the crosslinkable groups the monomer unit formed from the compound MM2 has is 2; and the number of the crosslinkable groups the monomer unit formed from the compound MM3 has is 0.

Therefore, X₁ can be determined as follows.

(0.45×776.45)+(0.05×240.20)+(0.50×750.51)=736.67

Further, Y₁ can be determined as follows.

(0.45×2)+(0.05×2)+(0.50×0)=1.00

Therefore, the average number of the crosslinkable groups per 1000 in molecular weight can be determined as follows.

(1.00×1000)/736.67=1.36

when the polymer composition comprises two or more polymer compounds as the polymer compound, the value of (Y₁×1000)/X₁ can be determined based on the monomer units constituting the each polymer compound. Further the value of (Y₁×1000)/X₁ is determined for the each polymer compound, and the value of (Y₁×1000)/X₁ of the whole polymer compounds is determined from the compounding amount ratios of the each polymer compound.

A specific calculation method will be described for the case where a polymer compound P4 and a polymer compound P5 of Comparative Example 4 described below are compounded in a ratio of 50:50.

The polymer compound P4 has monomer units formed from the compound MM1, the compound MM2, a compound MM4 and the compound MM3, which are monomers. In the polymer compound P4, the ratio to the total mol of all the monomer units is 0.05 for the monomer unit formed from the compound MM1, 0.05 for the monomer unit formed from compound MM2, 0.40 for the monomer unit formed from compound MM4, and 0.05 for the monomer unit formed from compound MM3. Further the molecular weight of the monomer unit formed from the compound MM1 is 776.45; the molecular weight of the monomer unit formed from the compound MM2 is 240.20; the molecular weight of the monomer unit formed from the compound MM4 is 244.23; and the molecular weight of the monomer unit formed from the compound MM3 is 750.51. Further the number of the crosslinkable groups the monomer unit formed from the compound MM1 has is 2; the number of the crosslinkable groups the monomer unit formed from the compound MM2 has is 2; the number of the crosslinkable groups the monomer unit formed from the compound MM4 has is 0; and the number of the crosslinkable groups the monomer unit formed from the compound MM3 has is 0. Therefore, for the polymer compound P4, the average number of the crosslinkable groups per 1000 in molecular weight as calculated by the method described above is 0.38.

The polymer compound P5 has monomers units formed from the compound MM4 and the compound MM3, which are monomers. In the polymer compound P5, the ratio to the total mol of all the monomer units is 0.50 for the monomer unit formed from the compound MM3, and 0.50 for the monomer unit from compound MM4. Further the molecular weight of the monomer unit formed from the compound MM4 is 244.23; and the molecular weight of the monomer unit formed from the compound MM3 is 750.51. Further the number of the crosslinkable groups the monomer unit formed from the compound MM4 has is 0; and the number of the crosslinkable groups the monomer unit formed from the compound MM3 has is 0. Therefore, for the polymer compound P5, the average number of the crosslinkable groups per 1000 in molecular weight as calculated by the method described above is 0.

In Comparative Example 4, the polymer compound P4 and the polymer compound P5 are compounded in a ratio of 50:50.

Therefore, in Comparative Example 4, the average number of the crosslinkable groups per 1000 in molecular weight of the polymer compound can be determined to be 0.19 by the following formula.

0.38×0.5+0×0.5=0.19

In the present embodiment, the average number of the crosslinkable groups per 1000 in molecular weight is preferably 0.50 or more, more preferably 0.60 or more, further preferably 0.65 or more, still further preferably 0.90 or more, and especially preferably 1.10 or more. It is conceivable that when the average number of the crosslinkable groups increase, a more compact film is formed from the crosslinkable polymer compound, and the charge transportability of the second organic layer and/or the charge injection from the second organic layer to the first organic layer is improved.

Further in the present embodiment, the average number of the crosslinkable groups per 1000 in molecular weight may be, for example, 10 or less, or may be 3 or less. By making the average number of the crosslinkable groups in this range, the effect that the luminance life of the light-emitting device is more improved is attained.

[Composition of the Second Organic Layer]

The second organic layer may be a layer formed by using a composition (hereinafter, referred to also as “composition of the second organic layer”) comprising the crosslinkable polymer compound, the phosphorescent compound, and at least one material selected from the group consisting of a hole transporting material, a hole injection material, an electron transporting material, an electron injection material, a light emitting material, an antioxidant and a solvent.

The second organic layer may be, for example, a layer comprising a crosslinked body formed from the crosslinkable polymer compound, the phosphorescent compound, and at least one material selected from the group consisting of a hole transporting material, a hole injection material, an electron transporting material, an electron injection material, a light emitting material, an antioxidant and a solvent.

Examples and the preferable ranges of the hole transporting material, the electron transporting material, the hole injection material, the electron injection material and the light emitting material contained in the composition of the second organic layer are the same as the examples and the preferable ranges of the hole transporting material, the electron transporting material., the hole injection material, the electron injection material. and the light emitting material contained in the composition of the first organic layer.

In the composition of the second organic layer, the compounding amounts of the hole transporting material, the electron transporting material, the hole injection material, the electron injection material and the light emitting material are each, when the crosslinkable polymer compound is taken to be 100 parts by mass, usually 1 to 400 parts by mass, and preferably 5 to 1.50 parts by mass.

Examples and the preferable ranges of the antioxidant contained in the composition of the second organic layer are the same as the examples and the preferable ranges of the antioxidant contained in the composition of the first organic layer.

In the composition of the second organic layer, the compounding amount of the antioxidant is, when the crosslinkable polymer compound is taken to be 100 parts by mass, usually 0.001 to 10 parts by mass.

[Ink for the Second Organic Layer]

The composition (hereinafter, referred to also as “ink for the second organic layer”) of the second organic layer comprising a solvent can suitably be used, similarly to the ink for the first organic layer, in applying methods such as a spin coat method and an inkjet printing method.

The preferable range of the viscosity of the ink for the second organic layer is the same as the preferable range of the viscosity of the ink for the first organic layer.

The solvent contained in the ink for the second organic layer is preferably a solvent capable of dissolving or uniformly dispersing solid components in the ink. Examples and the preferable ranges of the solvent are the same as the examples and the preferable ranges of the solvent contained in the first organic layer.

In the ink for the second organic layer, the compounding amount of the solvent is, when the crosslinkable polymer compound is taken to be 100 parts by mass, usually 1000 to 100000 parts by mass, and preferably 2000 to 20000 parts by mass.

<Layer Constitution of Light-Emitting Device>

The light-emitting device of the present embodiment comprises an anode, a cathode, a first organic layer disposed between the anode and the cathode and a second organic layer disposed between the anode and the first organic layer. The light-emitting device of the present embodiment may comprise layers other than the anode, the cathode, the first organic layer and the second organic layer.

In the light-emitting device of the present embodiment, the first organic layer is usually a light emitting layer.

In the light-emitting device of the present embodiment, it is preferable that the first organic layer and the second organic layer are adjacent, because the light-emitting device of the present embodiment is more excellent in external quantum efficiency.

It is preferable for the light-emitting device of the present embodiment to further comprise at least one layer selected from the group consisting of a hole transporting layer and a hole injection layer between the anode and the second organic layer, because the light-emitting device of the present embodiment is more excellent in power efficiency. Further, it is preferable for the light-emitting device of the present embodiment to further comprise at least one layer selected from the group consisting of an electron transporting layer and an electron injection layer between the cathode and the first organic layer, because the light-emitting device of the present embodiment is excellent in power efficiency.

The specific layer constitution of the light-emitting device of the present embodiment includes layer constitutions represented by (D1), (D2), (D3), (D4), (D5), (D6), (D7), (D8), (D9), (D10), (D11), (D12), (D13), (D14), (D15) or (D16) described below (hereinafter, referred to as “layer constitution represented by (D1) to (D16)” in some cases). The light-emitting device of the present embodiment usually comprises a substrate, and the anode may be first laminated on the substrate or the cathode may be first laminated on the substrate.

(D1) anode/second organic layer/first organic layer/cathode
(D2) anode/second organic layer/first organic layer/electron transporting layer/cathode
(D3) anode/second organic layer/first organic layer/electron injection layer/cathode
(D4) anode/second organic layer/first organic layer/electron transporting layer/electron injection layer/cathode
(D5) anode/hole injection layer/second organic layer/first organic layer/cathode
(D6) anode/hole injection layer/second organic layer/first organic layer/electron transporting layer/cathode
(D7) anode/hole injection layer/second organic layer/first organic layer/electron injection layer/cathode
(D8) anode/hole injection, layer/second organic layer/first organic layer/electron transporting layer/electron injection layer/cathode
(D9) anode/hole transporting layer/second organic layer/first organic layer/cathode
(D10) anode/hole transporting layer/second organic layer/first organic layer/electron transporting layer/cathode
(D11) anode/hole transporting layer/second organic layer/first organic layer/electron injection layer/cathode
(D12) anode/hole transporting layer/second organic layer/first organic layer/electron transporting layer/electron injection layer/cathode
(D13) anode/hole injection layer/hole transporting layer/second organic layer/first organic layer/cathode
(D14) anode/hole injection layer/hole transporting layer/second organic layer/first organic layer/electron transporting layer/cathode
(D15) anode/hole injection layer/hole transporting layer/second organic layer/first organic layer/electron injection layer/cathode
(D16) anode/hole injection layer/hole transporting layer/second organic layer/first organic layer/electron transporting layer/electron injection layer/cathode

In (D1) to (D16) described above, “/” denotes adjacent lamination of anterior and posterior layers. Specifically, “second organic layer/first organic layer” means that the second organic layer and the first organic layer are laminated adjacently.

In the light-emitting device of the present embodiment, if necessary, two or more of each of a hole injection layer, a hole transporting layer, an electron transporting layer and an electron injection layer may be provided.

The thickness of an anode, a cathode, a first organic layer, a second organic layer, a hole injection layer, a hole transporting layer, an electron injection layer and an electron transporting layer is usually 1 nm to 1 μm, preferably 2 nm to 500 nm, further preferably 5 nm to 150 nm.

In the light-emitting device of the present embodiment, the order, the number and the thickness of layers to be laminated may be advantageously adjusted in views of external quantum efficiency and device lifetime of the light-emitting device.

[Hole Transporting Layer]

The hole transporting layer is usually a layer formed by using a hole transporting material. The hole transporting material used for formation of the hole transporting layer includes, for example, hole transporting materials which the above-described composition of the first organic layer may comprise.

The hole transporting material may be used singly, or two or more hole transporting materials may be used in combination.

[Electron Transporting Layer]

The electron transporting layer is usually a layer formed by using an electron transporting material. The electron transporting material used for formation of the electron transporting layer includes, for example, electron transporting materials which the above-described composition of the first organic layer may comprise and a polymer compound comprising at least one constitutional unit selected from the group consisting of a constitutional unit represented by the formula (ET-1) and a constitutional unit represented by the formula (ET-2), preferably, a polymer compound comprising at least one constitutional unit selected from the group consisting of a constitutional unit represented by the formula (ET-1) and a constitutional unit represented by the formula (ET-2). The electron transporting material may be used singly, or two or more electron transporting materials may be used in combination.

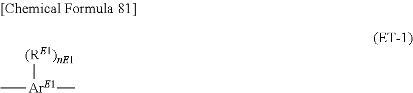

Wherein,

nE1 represents an integer of 1 or more.

Ar^{E1} represents an aromatic hydrocarbon group or a heterocyclic group, and these groups each optionally have a substituent other than R^{E1}.

R^{E1} represents a group represented by the formula (ES-1). When a plurality of R^{E1} are present, they may be the same or different.

—(R^{E3})_{cE1}-(Q^{E1})_{nE4}-Y^{E1}(M^{E2})_{aE1}(Z^{E1})_{bE1} (ES-1)

[wherein,

cE1 represents 0 or 1, nE4 represents an integer of 0 or more, aE1 represents an integer of 1 or more, and bE1 represents an integer of 0 or more.

R^{E3} represents an arylene group or a divalent heterocyclic group, and these groups each optionally have a substituent.

Q^{E1} represents an alkylene group, an arylene group, an oxygen atom or a sulfur atom, and these groups each optionally have a substituent. When a plurality of Q^{E1} are present, they may be the same or different.

Y^{E1} represents —CO₂⁻, —SO₃⁻, —SO₂⁻ or PO₃²⁻.

M^{E2} represents a metal cation or an ammonium cation, and this ammonium cation optionally has a substituent. When a plurality of M^{E2} are present, they may be the same or different.

Z^{E1} represents F⁻, CY⁻, Br⁻, I⁻, O⁻, R^{E4}SO₃⁻, R^{E4}COO⁻, CIO⁻, ClO₂⁻, ClO₃⁻, ClO₄⁻, SCN⁻, CN⁻, NO₃⁻, SO₄²⁻, HSO₄⁻, PO₄³⁻, HPO₄²⁻, H₂PO₄⁻, BF₄⁻ or PF₆⁻. R^{E4} represents an alkyl group, a cycloalkyl group or an aryl group, and these groups each optionally have a substituent. When a plurality of Z^{E1} are present, they may be the same or different.

aE1 and bE1 are selected so that the charge of the group represented by the formula (ES-1) is 0.]

nE1 is preferably an integer of 1 to 4, more preferably 1 or 2.

The aromatic hydrocarbon group or the heterocyclic group represented by Ar^{E1} is preferably an atomic group remaining after removing from a 1,4-phenylene group, a 1,3-phenylene group, a 1,2-phenylene group, a 2,6-naphthalenediyl group, a 1,4-naphthalenediyl group, a 2,7-fluorenediyl group, a 3,6-fluorenediyl group, a 2,7-phenanthrenediyl group or a 2,7-carbazoledilyl group nE1 hydrogen atoms bonding directly to atoms constituting the ring, and optionally has a substituent other than R^{E1}.

The substituent other than RE 1 which Ar^{E1} optionally has includes a halogen atom, a cyano group, an alkyl group, a cycloalkyl group, an aryl group, a monovalent heterocyclic group, an alkoxy group, a cycloalkoxy group, an aryloxy group, an amino group, a substituted amino group, an alkenyl group, a cycloalkenyl group, an alkynyl group, a cycloalkynyl group, a carboxyl group, and a group represented by the formula (ES-3).

—O(C_{n′}H_{2n′}O)ₙₓC_{m′}H_{2m′+1} (ES-3)

[wherein, n′, m′ and nx represent an integer of 1 or more.]

cE1 is preferably 0 or 1, and nE4 is preferably an, integer of 0 to 6.

R^{E3} is preferably an arylene group.

Q^{E1} is preferably an alkylene group, an arylene group or an oxygen atom.

Y^{E1} is preferably —CO₂— or SO₃.

M^{E2} is preferably Li⁺, Na⁺, K⁺, Cs⁺, N(CH₃)₄⁺, NH(CH₃)₃⁺, NH₂ (CH₃)₂⁺ or N(C₂H₅)₄⁺.

Z^{E1} is preferably F⁻, Cl⁻, Br⁻, I⁻, OH⁻, R^{E4}SO₃⁻ or R^{E4}COO⁻.

The group represented by the formula (ES-1) includes, for example, groups represented by the following formulae.

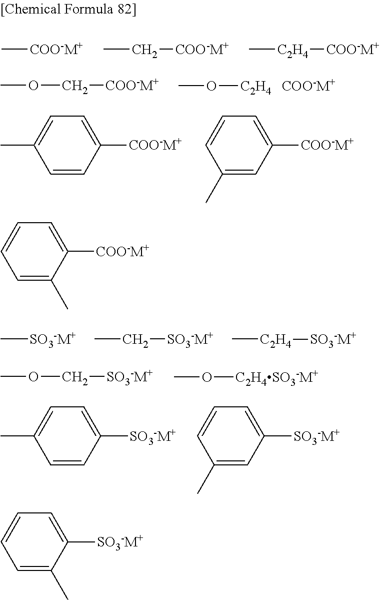

Wherein, M⁺ represents Li⁺, Na⁺, K⁺, Cs⁺, N(CH₃)₄⁺, NH(CH₃)₃⁺, NH₂(H₃)₂⁺ or N(C₂H₅)₄⁺.

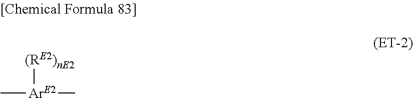

Wherein,

nE2 represents an integer of 1 or more.

Ar^{E2} represents an aromatic hydrocarbon group or a heterocyclic group, and these groups each optionally have a substituent other than R^{E2}.

R^{E2} represents a group represented by the formula (ES-2).

When a plurality of R^{E2} are present, they may be the same or different.

—(R^{E6})_{cE2}-(Q^{E2})_{nE6}-Y^{E2}(M^{E3})_{bE2}(Z^{E2})_{aE2} (ES-2)

[wherein,

cE2 represents 0 or 1, nE6 represents an integer of 0 or more, bE2 represents an integer of 1 or more, and aE2 represents an integer of 0 or more.

R^{E6} represents an arylene group or a divalent heterocyclic group, and these groups each optionally have a substituent.

Q^{E2} represents an alkylene group, an arylene group, an oxygen atom or a sulfur atom, and these groups each optionally have a substituent. When a plurality of Q^{E2} are present, they may be the same or different.

Y^{E2} represents a carbocation, an ammonium cation, a phosphonyl cation or a sulfonyl cation.

M^{E3} represents F⁻, Cl⁻, Br⁻, I⁻, OH⁻, R^{E7}SO₃⁻, R^{E7}COO⁻, ClO⁻, ClO₂⁻, ClO₃⁻, ClO₄⁻, SCN⁻, CN⁻, NO₃⁻, SO₄²⁻, HSO₄⁻, PO₄³⁻, HPO₄²⁻, H₂PO₄⁻, tetraphenyl borate, BF₄⁻ or PF₆⁻. R^{E7} represents an alkyl group, a perfluoroalkyl group or an aryl group, and these groups each optionally have a substituent. When a plurality of M^{E3} are present, they may be the same or different.

Z^{E2} represents a metal ion or an ammonium ion, and this ammonium ion optionally has a substituent. When a plurality of Z^{E2} are present, they may be the same or different.

aE2 and bE2 are selected so that the charge of the group represented by the formula (ES-2) is 0.]

nE2 is preferably an integer of 1 to 4, more preferably 1 or 2.

The aromatic hydrocarbon group or the heterocyclic group represented by Ar^{E2} is preferably an atomic group remaining after removing from a 1,4-phenylene group, a 1,3-phenylene group, a 1,2-phenylene group, a 2,6-naphthalenediyl group, a 1,4-naphthalenediyl group, a 2,7-fluorenediyl group, a 3,6-fluorenediyl group, a 2,7-phenanthrenediyl group or a 2,7-carbazoledilyl group nE2 hydrogen atoms bonding directly to atoms constituting the ring, and optionally has a substituent other than R^{E2}.

The substituent other than R^{E2} which Ar^{E2} optionally has is the same as the substituent other than R^{E1} which Ar^{E1} optionally has.

cE2 is preferably 0 or 1, and nE6 is preferably an integer of 0 to 6.

R^{E6} is preferably an arylene group.

Q^{E2} is preferably an alkylene group, an arylene group or an oxygen atom.

Y^{E2} is preferably a carbocation or an ammonium cation.

M^{E3} is preferably F⁻, Cl⁻, Br⁻, I⁻, tetraphenyl borate, CF₃SO₃⁻ or CH₃COO⁻.

Z^{E2} is preferably Li⁺, Na⁺, K⁺, Cs⁺, N(CH₃)₄⁺, NH(CH₃)₃⁺, NH₂ (CH₃)₂⁺ or N(C₂H₅)₄⁺.

The group represented by the formula (ES-2) includes, for example, groups represented by the following formulae.

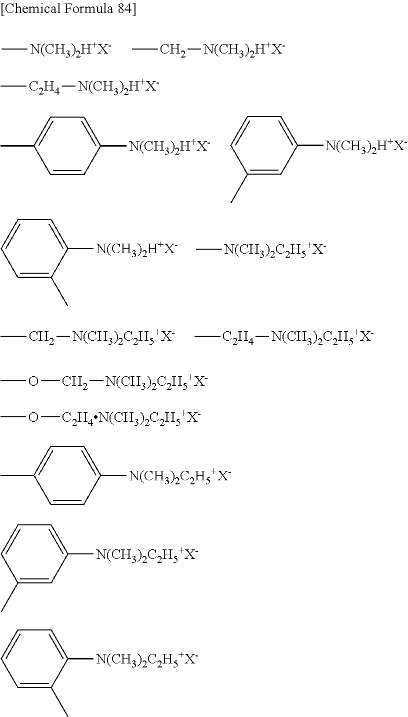

Wherein, X⁻ represents F⁻, Cl⁻, Br⁻, I⁻, tetraphenyl borate, CF₃ SO₃⁻ or CH₃ COO⁻.

The constitutional unit represented by the formula (ET-1) and the formula (ET-2) includes, for example, constitutional units represented by the formula (ET-31), (ET-32), (ET-33) or (ET-34) described below.

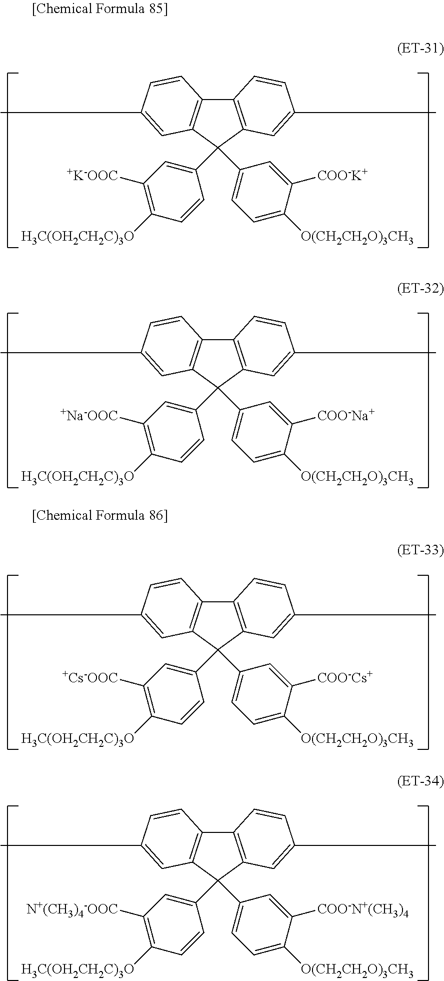

When a material used for formation of the hole injection layer described later, a material used for formation of the hole transporting layer, a material used for formation of the second organic layer, a material used for formation of the first organic layer, a material used for formation of the electron transporting layer, and a material used for formation of the electron injection layer described later are each soluble in a solvent used in forming a layer adjacent to the hole injection layer, the hole transporting layer, the second organic layer, the first organic layer, the electron transporting layer and the electron injection layer in fabrication of a light-emitting device, it is preferable that dissolution of the material in the solvent is avoided. As the method for avoiding dissolution of the material, i) a method of using a material having a crosslinkable group or ii) a method of providing a difference of solubility between adjacent layers is preferable. In the above-described method i), a layer is formed using a material having a crosslinkable group, then, the crosslinkable group is crosslinked, thus, the layer can be insolubilized.

For example, when an electron transporting layer is laminated on the first organic layer by utilizing a difference of solubility, the electron transporting layer can be laminated by using a solution manifesting low solubility for the first organic layer.

As the solvent used in laminating an electron transporting layer on the first organic layer by utilizing a difference of solubility, preferable are water, alcohols, ethers, esters, nitrile compounds, nitro compounds, fluorinated alcohols, thiols, sulfides, sulfoxides, thioketones, amides, carboxylic acids and the like. Specific examples of the solvent include methanol, ethanol, 2-propanol, 1-butanol, tert-butyl alcohol, acetonitrile, 1,2-ethanediol, N,N-dimethylformamide, dimethyl sulfoxide, acetic acid, nitromethane, propylene carbonate, pyridine, carbon disulfide and a mixed solvent of these solvents. When the mixed solvent is used, mixed solvents composed of one or more solvents selected from water, alcohols, ethers, esters, nitrile compounds, nitro compounds, fluorinated alcohols, thiols, sulfides, sulfoxides, thioketones, amides, carboxylic acids and the like and one or more solvents selected from chlorine-based solvents, aromatic hydrocarbon solvents, aliphatic hydrocarbon solvents and ketone solvents may be permissible.

[Hole Injection Layer and Electron Injection Layer]

The hole injection layer is usually a layer formed by using a hole injection material. The hole injection material used for formation of the hole injection layer includes, for example, hole injection materials which the above-described composition of the first organic layer may comprise. The hole injection material may be used singly, or two or more hole injection materials may be used in combination.

The electron injection layer is usually a layer formed by using an electron injection material. The electron injection material used for formation of the electron injection layer includes, for example, electron injection materials which the above-described composition of the first organic layer may comprise. The electron injection material may be used singly, or two or more electron injection materials may be used in combination.

[Substrate/Electrode]

The substrate in the light-emitting device may advantageously be a substrate on which an electrode can be formed and which does not chemically change in forming an organic layer, and is a substrate made of a material such as, for example, glass, plastic and silicon. In the case of using an opaque substrate, it is preferable that an electrode most remote from the substrate is transparent or semi-transparent.

The material of the anode includes, for example, electrically conductive metal oxides and semi-transparent metals, preferably, indium oxide, zinc oxide and tin oxide; electrically conductive compounds such as indium-tin-oxide (ITO) and indium-zinc-oxide; a composite of silver, palladium and copper (APC); NESA, gold, platinum, silver and copper.

The material of the cathode includes, for example, metals such as lithium, sodium, potassium, rubidium, cesium, beryllium, magnesium, calcium, strontium, barium, aluminum, zinc and indium; alloys composed of two or more of them; alloys composed of one or more of them and at least one of silver, copper, manganese, titanium, cobalt, nickel, tungsten and tin; and graphite and graphite intercalation compounds. The alloy includes, for example, a magnesium-silver alloy, a magnesium-indium alloy, a magnesium-aluminum alloy, an indium-silver alloy, a lithium-aluminum alloy, a lithium-magnesium alloy, a lithium-indium alloy and a calcium-aluminum alloy.

The anode and the cathode each may be a laminated structure composed of two or more layers.

In the light-emitting device of the present embodiment, at least one of the anode and the cathode is usually transparent or semi-transparent, and it is preferable that the anode is transparent or semi-transparent.

Methods for forming the anode and the cathode include, for example, vacuum vapor deposition method, sputtering method, ion plating method, plating method, lamination method and the like.

[Production Method of Light-Emitting Device]

The method of forming each layer such as the first organic layer, the second organic layer, a hole transporting layer, an electron transporting layer, a hole injection layer and an electron injection layer in the light-emitting device of the present embodiment includes, for example, a vacuum vapor deposition method from a powder and a method of film formation from a solution or melted state when a low molecular weight compound is used, and includes, for example, a method of film formation from a solution or melted state when a polymer compound is used.

The first organic layer, the second organic layer, the hole transporting layer, the electron transporting layer, the hole injection layer and the electron injection layer can be formed by application methods typified by a spin coat method and an inkjet printing method using the ink of the first organic layer, the ink of the second organic layer, inks comprising the hole transporting material, the electron transporting material, the hole injection material and the electron injection material described above, respectively.

[Use of Light-Emitting Device]

For obtaining planar light emission by using a light-emitting device, a planar anode and a planar cathode are disposed so as to overlap with each other. Patterned light emission can be produced by a method of placing a mask with a patterned window on the surface of a planer light-emitting device, a method of forming an extremely thick layer intended to be a non-light emitting, thereby having the layer essentially no-light emitting or a method of forming an anode, a cathode or both electrodes in a patterned shape. By forming a pattern with any of these methods and disposing certain electrodes so as to switch ON/OFF independently, a segment type display capable of displaying numbers and letters and the like is provided. For producing a dot matrix display, both an anode and a cathode are formed in a stripe shape and disposed so as to cross with each other. Partial color display and multi-color display are made possible by a method of printing separately certain polymer compounds showing different emission or a method of using a color filter or a fluorescence conversion filter. The dot matrix display can be passively driven, or actively driven combined with TFT and the like. These displays can be used in computers, television sets, portable terminals and the like. The planar light-emitting device can be suitably used as a planer light source for backlight of a liquid crystal display or as a planar light source for illumination. If a flexible substrate is used, it can be used also as a curved light source and a curved display.

Hitherto, suitable embodiments of the present invention have been illustrated, but the present invention is not limited to the embodiments described above.

For example, one aspect of the present invention relates to the crosslinkable polymer compound described above. Further, another aspect of the present invention may be a planar light source having the light-emitting device described above, or may be a display having the light-emitting device described above.

### Examples

The present invention will be illustrated further in detail by examples below, but the present invention is not limited to examples.

In the present examples, the polystyrene-equivalent number average molecular weight (Mn) and the polystyrene-equivalent weight average molecular weight (Mw) of a polymer compound were measured by size exclusion chromatography (SEC) (manufactured by Shimadzu Corp., trade name: LC-10Avp). SEC measurement conditions are as follows:

[Measurement Condition]

The polymer compound to be measured was dissolved in THF (tetrahydrofuran) at a concentration of about 0.05 wt %, and 10 μL of the solution was injected into SEC. As the mobile phase of SEC, THF was used and allowed to flow at a flow rate of 2.0 mL/min. As the column, PLgel MIXED-B (manufactured by Polymer Laboratories) was used. As the detector, UV-VIS detector (manufactured by Shimadzu Corp., trade name: SPD-10Avp) was used.

Liquid chromatograph mass spectrometry (LC-MS) was carried out according to the following method.

A measurement sample was dissolved in chloroform or THF so as to give a concentration of about 2 mg/mL, and about 1 μL of the solution was injected into LC-MS (manufactured by Agilent Technologies, trade name: 1100LCMSD). As the mobile phase of LC-MS, acetonitrile and TH1F were used while changing the ratio thereof and allowed to flow at a flow rate of 0.2 mL/min. As the column, L-column 2 ODS (3 m) (manufactured by Chemicals Evaluation and Research Institute, internal diameter: 2.1 mm, length: 100 mm, particle size: 3 μm) was used.

Measurements of ¹H-NMR and ¹³C-NMR were carried out by the following method.

5 to 10 mg of a measurement sample was dissolved in about 0.5 mL of deuterated chloroform (CDCl₃), deuterated tetrahydrofuran, deuterated dimethyl sulfoxide, deuterated acetone, deuterated N,N-dimethylformamide, deuterated toluene, deuterated methanol, deuterated 2-propanol or deuterated methylene chloride, and the measurements were carried out by using an NMR apparatus (manufactured by Agilent Technologies, Inc., trade name: INOVA300 or MERCURY 400VX).

As the index of the purity of a compound, a value of the high performance liquid chromatography (HPLC) area percentage was used. This value is a value in high performance liquid chromatography (HPLC, manufactured by Shimadzu Corp., trade name: LC-20A) at 254 nm, unless otherwise stated. In this operation, the compound to be measured was dissolved in THF or chloroform so as to give a concentration of 0.01 to 0.2 wt %, and depending on the concentration, 1 to 10 μL of the solution was injected into HPLC. As the mobile phase of HPLC, acetonitrile and THF were used and allowed to flow at a flow rate of 1 mL/min as gradient analysis of acetonitrile/THF=100/0 to 0/100 (volume ratio). As the column, Kaseisorb LC ODS 2000 (manufactured by Tokyo Chemical Industry Co., Ltd.) or an ODS column having an equivalent performance was used. As the detector, a photo diode array detector (manufactured by Shimadzu Corp., trade name: SPD-M20A) was used.

(1) Phosphorescent Compound

<1-1> Phosphorescent Compound B1

As a phosphorescent compound B1, the following compound was purchased from Luminescence Technology Corp.

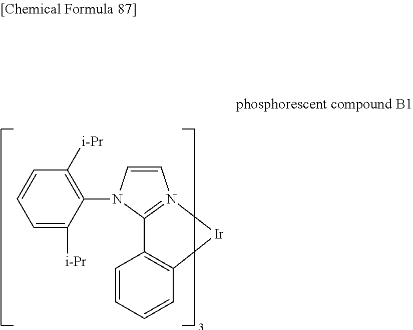

<1-2> Phosphorescent Compound B2

A phosphorescent compound B2 was synthesized according to the methods described in International Publication No. WO2006/121811 and Japanese Unexamined Patent Publication No. 2013-048190.

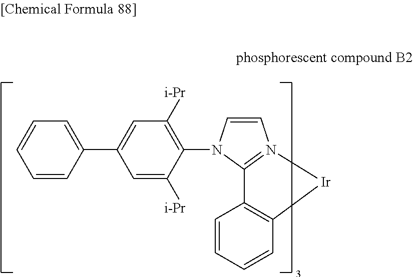

<1-3> Phosphorescent Compound B3

(B3-1) Synthesis of Compound S1

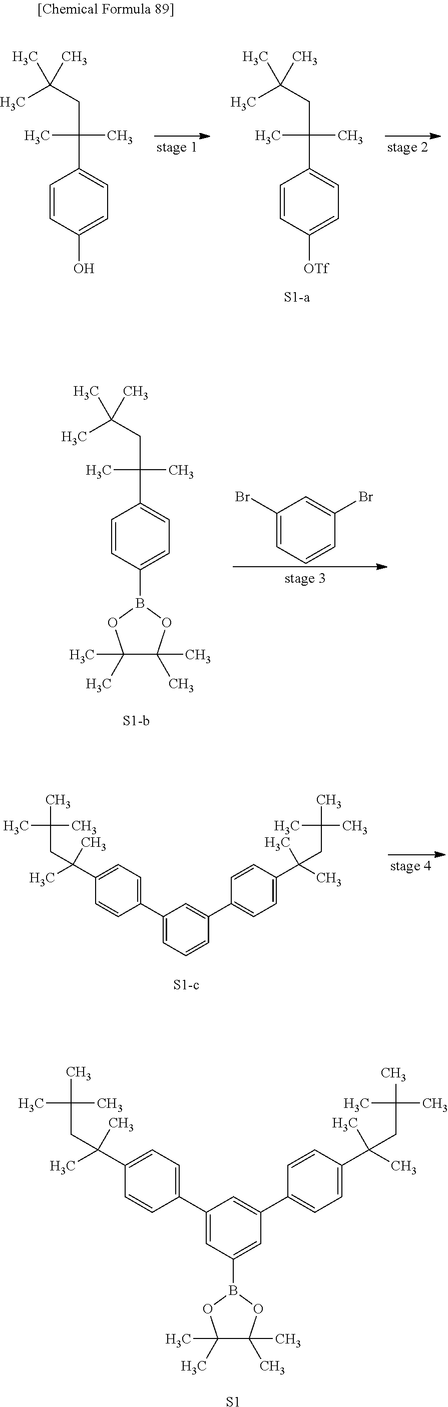

<Stage 1>

The atmosphere in a reaction vessel was turned into a nitrogen gas stream, then, 4-tert-octylphenol (250.00 g, manufactured by Aldrich), N,N-dimethyl-4-aminopyridine (177.64 g) and dichloromethane (3100 mL) were added, and this mixture was cooled down to 5° C. with ice. Thereafter, trifluoromethanesulfonic anhydride (376.06 g) was dropped into this over a period of 45 minutes. After completion of dropping, the mixture was stirred for 30 minutes under ice cool, then, returned to room temperature and further stirred for 1.5 hours. To the resultant reaction mixture was added hexane (3100 mL), and this reaction mixture was filtrated using 410 g of silica gel, and further, the silica gel was washed with a mixed solvent (2.5 L) of hexane and dichloromethane (1/1 (by volume)). The resultant filtrate and the wash solution were concentrated, to obtain a compound S1-a (410.94 g) as a colorless oil. The HPLC purity of the resultant compound S1-a was 99.5% or more.

<Stage 2>

The atmosphere in a reaction vessel was turned into a nitrogen gas stream, then, the compound S1-a (410.94 g), bis(pinacolato)diboron (338.47 g), potassium acetate (237.83 g), 1,4-dioxane (2600 mL), palladium acetate (4.08 g) and tricyclohexylphosphine (10.19 g) were added, and the mixture was refluxed for 2 hours. After cooling down to room temperature, the resultant reaction mixture was filtrated and the filtrate was collected, and further, the filtrated substance was washed with 1,4-dioxane (2.5 L), and the resultant filtrate and the wash solution were concentrated. The resultant residue was dissolved into a mixed solvent of hexane and dichloromethane (1/1 (by volume)), and the solution was filtrated using 770 g silica gel, and further, the silica gel was washed with a mixed solvent (2.5 L) of hexane and dichloromethane (1/1 (by volume)). The resultant filtrate and the wash solution were concentrated, and to the resultant residue was added methanol (1500 mL), and the mixture was ultrasonically cleaned for 30 minutes. Thereafter, this was filtrated to obtain a compound S1-b (274.27 g). The filtrate and the wash solution were concentrated, and methanol was added, and the mixture was ultrasonically cleaned and filtrated, and such an operation was repeated, to obtain a compound S1-b (14.29 g). The total yielded amount of the resultant compound S1-b was 288.56 g.

<Stage 3>

The atmosphere in a reaction vessel was turned into a nitrogen gas stream, then, 1,3-dibromobenzene (102.48 g), the compound S1-b (288.56 g), toluene (2100 mL), a 20 wt % tetraethyl ammonium hydroxide aqueous solution (962.38 g) and bis(triphenylphosphine)palladium(II) dichloride (3.04 g) were added, and the mixture was refluxed for 7 hours. After cooling down to room temperature, the aqueous layer and the organic layer were separated, and the organic layer was collected. To this aqueous layer was added toluene (1 L), and the organic layer was further extracted. The resultant organic layers were combined, and this mixture was washed with a mixed aqueous solution of distilled water and saturated saline (1.5 L/1.5 L). The resultant organic layer was filtrated through 400 g silica gel, and further, the silica gel was washed with toluene (2 L).

The resultant solution was concentrated, and the resultant residue was dissolved in hexane. This solution was purified by silica gel column chromatography. Impurities were eluted with a developing solvent hexane, then, developed with a mixed solvent of hexane and dichloromethane (10/1 (by volume)). The each resultant fraction was concentrated under reduced pressure to remove the solvent, obtaining a colorless crystalline compound S1-c (154.08 g, HPLC purity: 99.1%) and a coarse compound S1-c (38.64 g, LC purity: 83%). This coarse compound S1-c was column-purified again under the same developing conditions, and the solvent was distilled off under reduced pressure, to obtain a compound S1-c (28.4 g, LC purity: 99.6%). The total yielded amount the resultant compound S1-c was 182.48 g.

<Stage 4>

The atmosphere in a reaction vessel was turned into a nitrogen gas stream, then, the compound S1-c (182.48 g), bis(pinacolato)diboron (112.09 g), 4,4′-di-tert-butyl-2,2′-dipyridyl (3.23 g), cyclohexane (2000 mL) and bis(1,5-cyclooctadiene)di-μ-methoxydiiridium(I) (3.99 g) were added, and the mixture was refluxed for 2 hours. After cooling with air down to room temperature, silica gel (220 g) was added over a period of 20 minutes while stirring the resultant reaction mixture. The resultant suspension was filtrated through 440 g of silica gel, and further, the silica gel was washed with dichloromethane (2 L), and the solution was concentrated. To the resultant residue were added methanol (1100 mL) and dichloromethane (110 mL), and the mixture was refluxed for 1 hour. After cooling down to room temperature, this was filtrated. The resultant filtrated substance was washed with methanol (500 mL), and the resultant solid was dried, to obtain a compound S1 (220.85 g).

¹H-NMR (CDCl₃, 300 MHz): δ (ppm)=8.00 (s, 2H), 7.92 (s, 1H), 7.60 (d, J=8.5 Hz, 4H), 7.44 (d, J=8.5 Hz, 4H), 1.78 (s, 4H), 1.41 (s, 12H), 1.37 (s, 12H), 0.75 (s, 1814).

(B3-2) Synthesis of Phosphorescent Compound B3

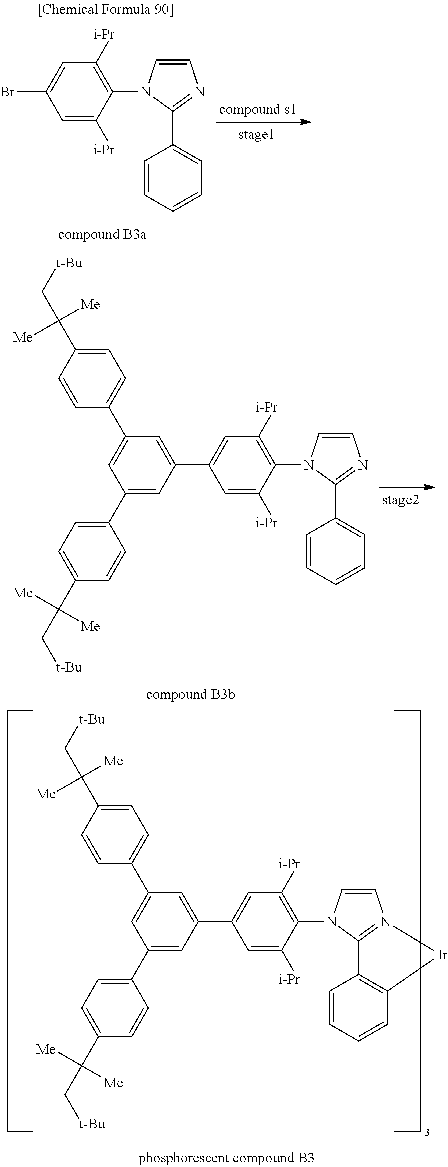

<Stage 1>

The atmosphere in a reaction vessel was turned into an argon gas atmosphere, then, a compound B5a (9.9 g) synthesized according to U.S. Unexamined Patent Application Publication No. 2011/0057559, the compound S1 (15 g), 2-dicyclohexylphosphino-2′,6′-dimethoxybiphenyl (0.11 g), tris(dibenzylideneacetone)dipalladium (0.12 g), a 20 wt % tetraethylammonium aqueous solution (20 mL), toluene (200 mL) and ethanol (50 mL) were added, and the mixture was stirred for 18 hours under reflux with heating. Thereafter, the mixture was cooled down to room temperature, and toluene was added and extraction was performed. The resultant organic layer was washed using ion-exchange water, then, concentrated under reduced pressure, to obtain a solid. The resultant solid was purified by silica gel chromatography (a mixed solvent of ethyl acetate and hexane), and further, recrystallized using a mixed solvent of toluene and acetonitrile, then, dried under reduced pressure, to obtain a compound B3b (17 g, yield: 90%).

<Stage 2>

The atmosphere in a reaction vessel was turned into an argon gas atmosphere, then, the compound B3b (10 g), iridium chloride hydrate (2.2 g), 2-ethoxyethanol (120 mL) and water (40 mL) were added, and the mixture was stirred for 14 hours under reflux with heating. Thereafter, the mixture was cooled down to room temperature, and methanol was added, to find generation of a precipitate. The resultant precipitate was filtrated, and the resultant solid was washed with methanol, then, dried under reduced pressure, to obtain an intermediate B3 (10 g, yellow powder).

The atmosphere in a reaction vessel was turned into an argon gas atmosphere, then, the intermediate B3 (9.5 g), silver trifluoromethanesulfonate (31 g), dichloromethane (100 mL) and methanol (30 mL) were added, and the mixture was stirred overnight at room temperature. The deposited precipitate was filtrated, then, the resultant filtrate was concentrated under reduced pressure. Thereafter, to this were added the compound B3b (7.8 g), 2,6-lutidine (6.7 mL) and diethylene glycol dimethyl ether (180 mL), and the mixture was stirred overnight under reflux with heating. Thereafter, the mixture was cooled down to room temperature, and a mixed solvent of ion-exchange water and methanol was added, and the deposited precipitate was filtrated. The resultant solid was purified by silica gel chromatography (a mixed solvent of dichloromethane and hexane), and further, recrystallized using a mixed solvent of toluene and acetonitrile, then, dried under reduced pressure, to obtain a phosphorescent compound B3 (1.2 g, yield: 6.5%).

¹H-NMR (600 MHz, (CD₃)₂CO-d₆): δ (ppm)=8.01-7.97 (m, 9H), 7.91 (d, 6H), 7.81 (d, 12H), 7.59 (d, 12H), 7.25 (s, 3H), 6.92-6.89 (m, 6H), 6.57 (t, 31H), 5.87-5.81 (m, 6H), 2.89-2.86 (m, 3H), 2.52-2.48 (m, 3H), 1.87 (s, 12H), 1.42 (s, 36H), 1.38 (d, 9H), 1.16 (d, 9H), 1.12 (d, 9H), 1.07 (d, 9H). 0.80 (54H).

(2) Crosslinkable Polymer Compound

<2-1> Synthesis of Compound Ma3

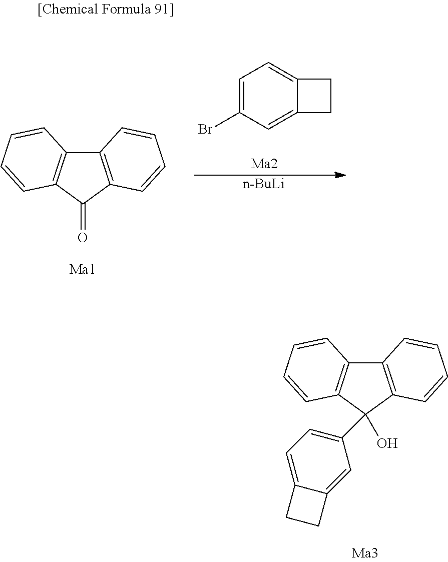

A gas in a flask equipped with a stirrer was purged with a nitrogen gas, then, a compound Ma2 (64.6 g) and tetrahydrofuran (615 mL) were added, and the mixture was cooled down to −70° C. Into this, a n-butyllithium hexane solution (1.6 M, 218 mL) was dropped over a period of 1 hour, then, the mixture was stirred at −70° C. for 2 hours. To this, a compound Ma1 (42.1 g) was added in several batches, then, the mixture was stirred at −70° C. for 2 hours. Into this, methanol (40 mL) was dropped over a period of 1 hour, then, the mixture was heated up to room temperature. Thereafter, the solvent was distilled off by concentrating under reduced pressure, and toluene and water were added. Thereafter, an aqueous layer was separated and the resultant organic layer was further washed with water. The resultant organic layer was concentrated under reduced pressure, and the resultant residue was purified by using a silica gel column (developing solvent: hexane/ethyl acetate), thereby obtaining 71 g of a compound Ma3 as a colorless oil. The resultant compound Ma3 had an HPLC area percentage value (UV: 254 nm) of 97.5%. This operation was repeated, thereby obtaining a necessary amount of the compound Ma3.

The ¹H-NMR measurement result of the resultant compound Ma3 is shown below.

¹H-NMR (CDCl₃, 300 MHz): δ (ppm): 2.43 (1H, s), 3.07-3.13 (4H, m), 6.95 (1H, d), 7.07 (1H. s), 7.18-7.28 (3H, m), 7.28-7.40 (4H, m), 7.66 (2H, s).

<2-2> Synthesis of Compound Ma4

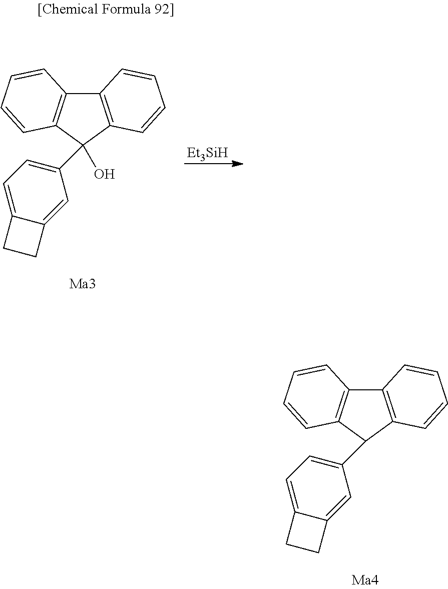

A gas in a flask equipped with a stirrer was purged with a nitrogen gas, then, the compound Ma3 (72.3 g), toluene (723 mL) and triethylsilane (118.0 g) were added, and the mixture was heated up to 70° C. Into this, methanesulfonic acid (97.7 g) was dropped over a period of 1.5 hours, then, the mixture was stirred at 70° C. for 0.5 hours. Thereafter, the mixture was cooled down to room temperature, and toluene (1 L) and water (1 L) were added, then, an aqueous layer was separated. The resultant organic layer was washed with water, a 5 wt % sodium hydrogen carbonate aqueous solution and water in this order. The resultant organic layer was concentrated under reduced pressure, and the resultant coarse product was recrystallized from a mixed solvent of toluene and ethanol, thereby obtaining 51.8 g of a compound Ma4 as a white solid. The resultant compound Ma4 had an HPLC area percentage value (UV: 254 nm) of 99.5% or more. This operation was repeated, thereby obtaining a necessary amount of the compound Ma4.

The ¹H-NMR measurement result of the resultant compound Ma4 is shown below.

¹H-NMR (CDCl₃, 300 MHz): δ (ppm): 3.03-3.14 (4H, m), 4.99 (1H, s), 6.68 (1H, s), 6.92-7.01 (2H, m), 7.20-7.28 (2H, m), 7.29-7.38 (4H, m), 7.78 (2H, d).

<2-3> Synthesis of Compound Mb3

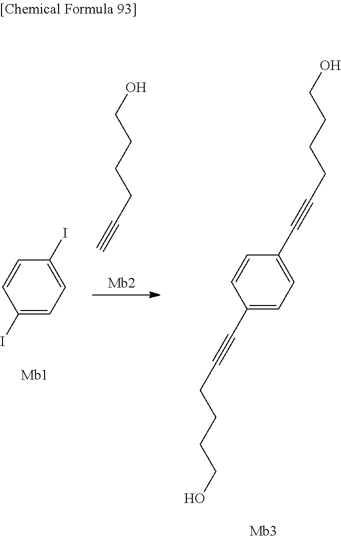

A gas in a flask equipped with a stirrer was purged with a nitrogen gas, then, a compound Mb1 (185.0 g), a compound Mb2 (121.1 g), CuI (3.2 g), dichloromethane (185 mL) and triethylamine (2.59 L) were added, and the mixture was heated up to the reflux temperature. Thereafter, the mixture was stirred at the reflux temperature for 0.5 hours, and cooled down to room temperature. To this was added dichloromethane (1.85 L), then, the mixture was filtrated through a filter paved with celite. To the resultant filtrate was added a 10 wt % sodium hydrogen carbonate aqueous solution, then, an aqueous layer was separated. The resultant organic layer was washed with water twice, washed with a saturated NaCl aqueous solution, then, magnesium sulfate was added. The resultant mixture was filtrated, and the resultant filtrate was concentrated under reduced pressure. The resultant residue was purified by using a silica gel column (developing solvent: chloroform/ethyl acetate), thereby obtaining a coarse product. The resultant coarse product was dissolved in ethanol (1.4 L), then, activated carbon (5 g) was added, and the mixture was filtrated. The resultant filtrate was concentrated under reduced pressure, and the resultant residue was recrystallized from hexane, thereby obtaining 99.0 g of a compound Mb3 as a white solid. The resultant compound Mb3 had an HPLC area percentage value (UV: 254 nm) of 99.5% or more.

This operation was repeated, thereby obtaining a necessary amount of the compound Mb3.

The ¹H-NMR measurement result of the resultant compound Mb3 is shown below.

¹H-NMR (DMSO-d6, 300 MHz): δ (ppm): 1.52-1.55 (8H, m), 2.42 (4H, t), 3.38-3.44 (4H, m), 4.39-4.43 (2H, m), 7.31 (4H, s).

<2-4> Synthesis of Compound Mb4

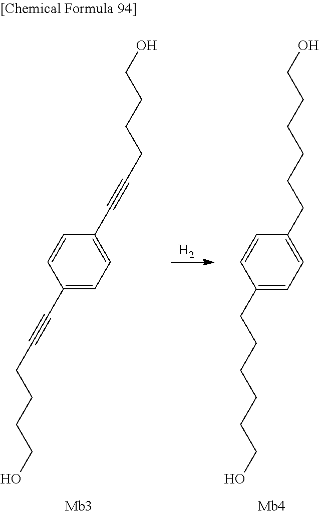 [SMILES: OCCCCC#Cc1ccc(C#CCCCCO)cc1 ; "H2" ; OCCCCCCc1ccc(CCCCCCO)cc1]

A gas in a flask equipped with a stirrer was purged with a nitrogen gas, then, the compound Mb3 (110.0 g), ethanol (1.65 L) and palladium/carbon (Pd weight: 10%) (11.0 g) were added, and the mixture was heated up to 30° C. Thereafter, a gas in the flask was purged with a hydrogen gas. Thereafter, the mixture was stirred at 30° C. for 3 hours while feeding a hydrogen gas into the flask. Thereafter, a gas in the flask was purged with a nitrogen gas. The resultant mixture was filtrated, and the resultant filtrate was concentrated under reduced pressure. The resultant residue was purified by using a silica gel column (developing solvent: chloroform/ethyl acetate), thereby obtaining a coarse product. The resultant coarse product was recrystallized from hexane, thereby obtaining 93.4 g of a compound Mb4 as a white solid. The resultant compound Mb4 had an HPLC area percentage value (UV: 254 nm) of 98.3%.

The ¹H-NMR and ¹³C-NMR measurement results of the resultant compound Mb4 are shown below.

¹H-NMR (CDCl₃, 300 MHz): δ (ppm): 1.30-1.40 (8H, m), 1.55-1.65 (8H, m), 2.58 (4H, t), 3.64 (4H, t), 7.09 (4H, s).

¹³C-NMR (CDCl₃, 75 MHz): δ (ppm): 25.53, 28.99, 31.39, 32.62, 35.37, 62.90, 128.18, 139.85.

<2-5> Synthesis of Compound Mb5

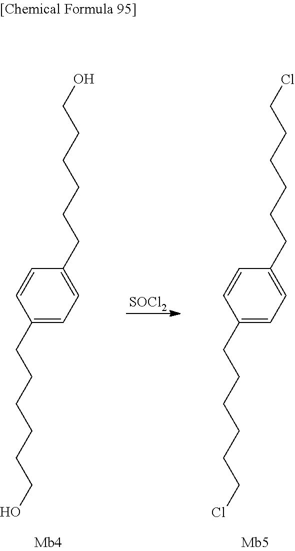

A gas in a flask equipped with a stirrer was purged with a nitrogen gas, then, the compound Mb4 (61.0 g), pyridine (0.9 g) and toluene (732 mL) were added, and the mixture was heated up to 60° C. Into this, thionyl chloride (91.4 g) was dropped over a period of 1.5 hours, then, the mixture was stirred at 60° C. for 5 hours. The resultant mixture was cooled down to room temperature, then, concentrated under reduced pressure. The resultant residue was purified by using a silica gel column (developing solvent: hexane/ethyl acetate), thereby obtaining 64.3 g of a compound Mb5 as a colorless oil. The resultant compound Mb5 had an HPLC area percentage value (UV: 254 nm) of 97.2%.

The ¹H-NMR measurement result of the resultant compound Mb5 is shown below.

¹H-NMR (CDCl₃, 300 MHz): δ (ppm): 1.35-1.40 (4H, m), 1.41-1.50 (4H, m), 1.60-1.68 (4H, m), 1.75-1.82 (4H, m), 2.60 (4H, t), 3.55 (4H, t), 7.11 (4H, s).

<2-6> Synthesis of Compound Mb6

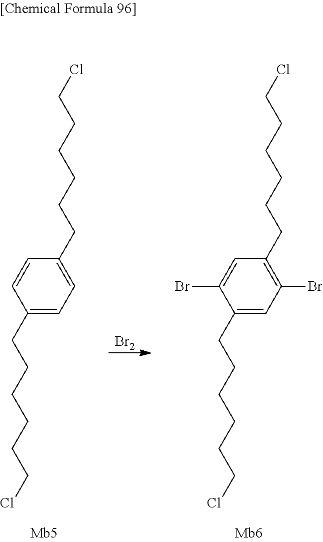 [SMILES: ClCCCCCCc1ccc(CCCCCCCl)cc1 ; "Br2" ; ClCCCCCCc1cc(Br)c(CCCCCCCl)cc1Br]

A gas in a flask equipped with a stirrer was purged with a nitrogen gas, then, the compound Mb5 (42.0 g), an iron powder (1.7 g), iodine (0.3 g) and dichloromethane (800 mL) were added. Thereafter, the whole flask was light-shielded, and cooled at 0 to 5° C. Into this, a mixed liquid of bromine (44.7 g) and dichloromethane (200 mL) was dropped over a period of 1 hour, then, the mixture was stirred at 0 to 5° C. overnight. The resultant mixed liquid was added to water (1.2 L) cooled at 0 to 5° C., then, an organic layer was separated. The resultant organic layer was washed with a 10 wt % sodium thiosulfate aqueous solution, and further, washed with a saturated sodium chloride aqueous solution and water in this order. To the resultant organic layer was added sodium sulfate, then, the mixture was filtrated, and the resultant filtrate was concentrated under reduced pressure. The resultant residue was purified by using a silica gel column (developing solvent; hexane), thereby obtaining a coarse product. The resultant coarse product was recrystallized from hexane, thereby obtaining 47.0 g of a compound Mb6 as a white solid. The resultant compound Mb6 had an HPLC area percentage value (UV: 254 nm) of 98.3%.

The ¹H-NMR measurement result of the resultant compound Mb6 is shown below.

¹H-NMR (CDCl₃, 300 MHz): δ (ppm): 1.38-1.45 (4H, m), 1.47-1.55 (4H, m), 1.57-1.67 (4H, m), 1.77-1.84 (4H, m), 2.66 (4H, t), 3.55 (4H, t), 7.36 (211, s).

<2-7> Synthesis of Compound Mb7

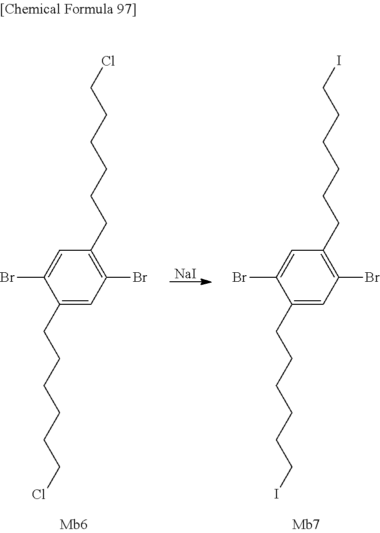

A gas in a flask equipped with a stirrer was purged with a nitrogen gas, then, sodium iodide (152.1 g) and acetone (600 mL) were added, and the mixture was stirred at room temperature for 0.5 hours. To this was added Mb6 (40.0 g), then, the mixture was heated up to the reflux temperature, and stirred at the reflux temperature for 24 hours. Thereafter, the mixture was cooled down to room temperature, and the resultant mixed liquid was added to water (1.2 L). The deposited solid was separated by filtration, then, washed with water, thereby obtaining a coarse product. The resultant coarse product was recrystallized from a mixed liquid of toluene and methanol, thereby obtaining 46.0 g of a compound Mb7 as a white solid. The resultant compound Mb7 had an HPLC area percentage value (UV: 254 nm) of 99.4%. This operation was repeated, thereby obtaining a necessary amount of the compound Mb7.

The ¹H-NMR measurement result of the resultant compound Mb7 is shown below.

¹H-NMR (CDCl₃, 300 MHz): δ (ppm): 1.35-1.50 (8H, m), 1.57-1.65 (4H, m), 1.80-1.89 (4H, m), 2.65 (4H, t), 3.20 (4H, t), 7.36 (2H, s).

<2-8> Synthesis of Compound Mb8

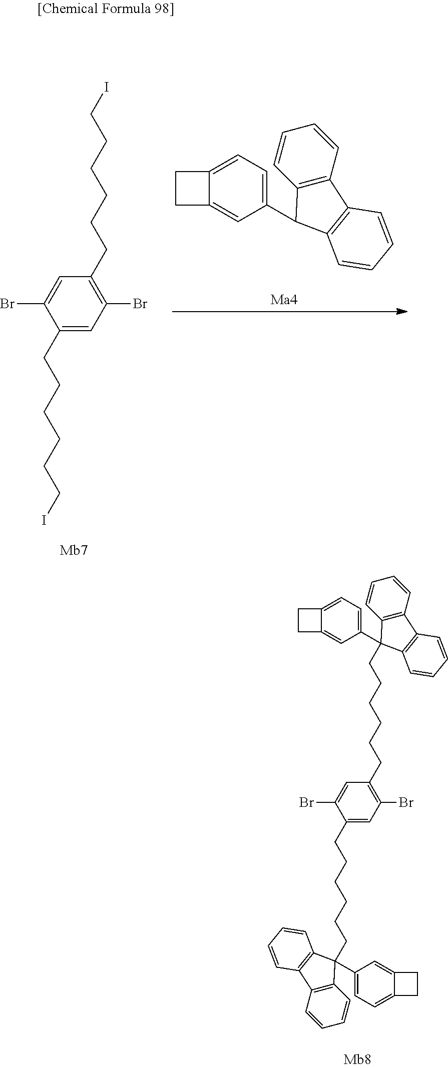

A gas in a flask equipped with a stirrer was purged with a nitrogen gas, then, sodium hydride (60 wt %, dispersed in liquid paraffin) (9.4 g), tetrahydrofuran (110 mL) and the compound Mb7 (63.2 g) were added. To this, a compound Ma4 (55.0 g) was added in several batches, then, the mixture was stirred for 12 hours. To this were added toluene (440 mL) and water (220 mL), then, an aqueous layer was separated. The resultant organic layer was washed with water, then, magnesium sulfate was added. The resultant mixed liquid was filtrated, and the resultant filtrate was concentrated under reduced pressure, thereby obtaining a coarse product. The resultant coarse product was purified by using a silica gel column (developing solvent: hexane/toluene). Thereafter, the product was recrystallized from heptane, thereby obtaining 84.1 g of a compound Mb8 as a white solid.

The resultant compound Mb8 had an HPLC area percentage value (UV: 254 nm) of 99.5% or more.

The ¹H-NMR measurement result of the resultant compound Mb8 is shown below.

¹H-NMR (CDCl₃, 300 MHz): δ (ppm): 0.70-0.76 (4H, m), 1.10-1.21 (8H, m), 1.32-1.44 (4H, m), 2.39-2.58 (8H, m), 3.00-3.12 (8H, m), 6.82-6.94 (4H, m), 7.00-7.05 (2H, m), 7.17-7.28 (10H, m), 7.30-7.38 (4H, m), 7.71-7.77 (4H, m).

<2-9> Synthesis of Compound MM1

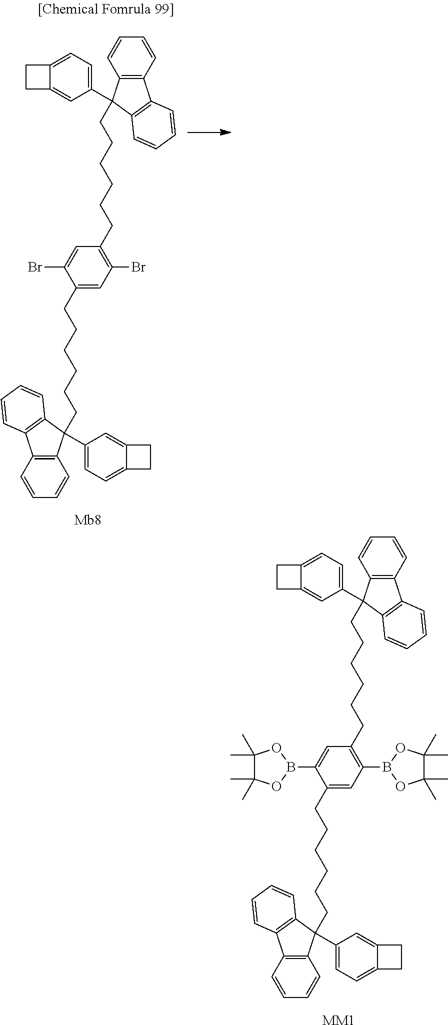

A gas in a flask equipped with a stirrer was purged with a nitrogen gas, then, the compound Mb8 (84.0 g), [1,1′-bis(diphenylphosphino)ferrocene]palladium(II) dichloride dichloromethane adduct (PdCl₂(dppf).CH₂Cl₂, 2.2 g), bispinacolatodiboron (68.3 g), potassium acetate (52.8 g) and cyclopentyl methyl ether (840 mL) were added, and the mixture was heated up to the reflux temperature, then, stirred at the reflux temperature for 5 hours. Thereafter, the mixture was cooled down to room temperature, and toluene (500 mL) and water (300 mL) were added, then, an aqueous layer was separated. The resultant organic layer was washed with water, then, activated carbon (18.5 g) was added. The resultant mixed liquid was filtrated, and the resultant filtrate was concentrated under reduced pressure, thereby obtaining a coarse product. The resultant coarse product was purified by using a silica gel column (developing solvent: hexane/toluene). Thereafter, an operation of recrystallizing from a mixed liquid of toluene and acetonitrile was repeated, thereby obtaining 45.8 g of a compound MM1 as a white solid. The resultant compound MM1 had an HPLC area percentage value (UV: 254 nm) of 99.4%.

The 1H-NMR measurement result of the resultant compound MM1 is shown below.

¹H-NMR (CDCl₃, 300 MHz): δ (ppm): 0.70-0.76 (4H, m), 1.24-1.40 (36H, m), 2.39-2.48 (4H, m), 2.66-2.75 (4H, m), 3.00-3.1.0 (8H, m), 6.76-6.90 (4H, m), 7.00-7.05 (2H, m), 7.19-7.30 (8H, m), 7.30-7.36 (4H, m), 7.43 (2H, s), 7.72 (4H, d).

<2-10> Synthesis of a Polymer Compound P1

A polymer compound P1 was synthesized through the following steps 1 to 4.

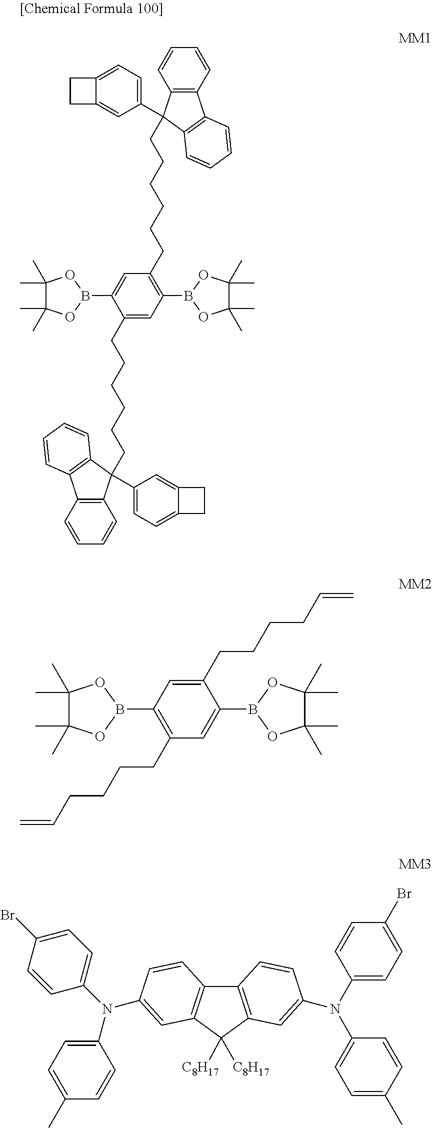

(Step 1) The atmosphere of a reaction vessel was turned into an inert gas atmosphere, and then, the compound MM1 (0.92303 g), the compound MM2 (0.04956 g) described in International Publication No. WO2013/146806, the compound MM3 (0.91722 g) described in International Publication No. WO2005/049546, dichlorobis(tris-o-methoxyphenylphophine)palladium (1.76 mg) and toluene (34 mL) were added and heated to 105° C.

(Step 2) A 20-wt % tetraethylammonium hydroxide aqueous solution (6.7 mL) was dropped into the reaction solution, and refluxed for 6 hours.

(Step 3) After the reaction, phenylboronic acid (48.8 mg) and dichlorobis(tris-o-methoxyphenylphophine)palladium (0.88 mg) were added thereto, and refluxed for 14.5 hours.

(Step 4) Thereafter, a sodium diethyldithiocarbamate aqueous solution was added thereto, and stirred at 80° C. for 2 hours. After cooling down, the resultant reaction solution was washed two times with water, two times with a 3-wt % acetic acid aqueous solution, and two times with water, and the resultant solution was dropped into methanol to find generation of a precipitate. The resultant precipitate was dissolved in toluene and passed through an alumina column and a silica gel column in order, to purify the resultant solution. The resultant solution was dropped into methanol, and stirred, and then, the resultant precipitate was filtered and dried, to obtain 1.23 g of a polymer compound P1.

The polystyrene-equivalent number-average molecular weight of the polymer compound P1 was 2.3×10⁴, and the polystyrene-equivalent weight-average molecular weight thereof was 1.2×10⁵.

The polymer compound P1 is a copolymer constituted of a constitutional unit derived from the compound MM1, a constitutional unit derived from the compound MM2, and a constitutional unit derived from the compound MM3 in a molar ratio of 45:5:50 on the theoretical value determined from amounts of raw materials fed. For the polymer compound P1, the average number of the crosslinkable groups per 1000 in molecular weight as calculated by the method described above was 1.36.

<2-11> Synthesis of a Polymer Compound P2

A polymer compound P2 was synthesized by the following method.

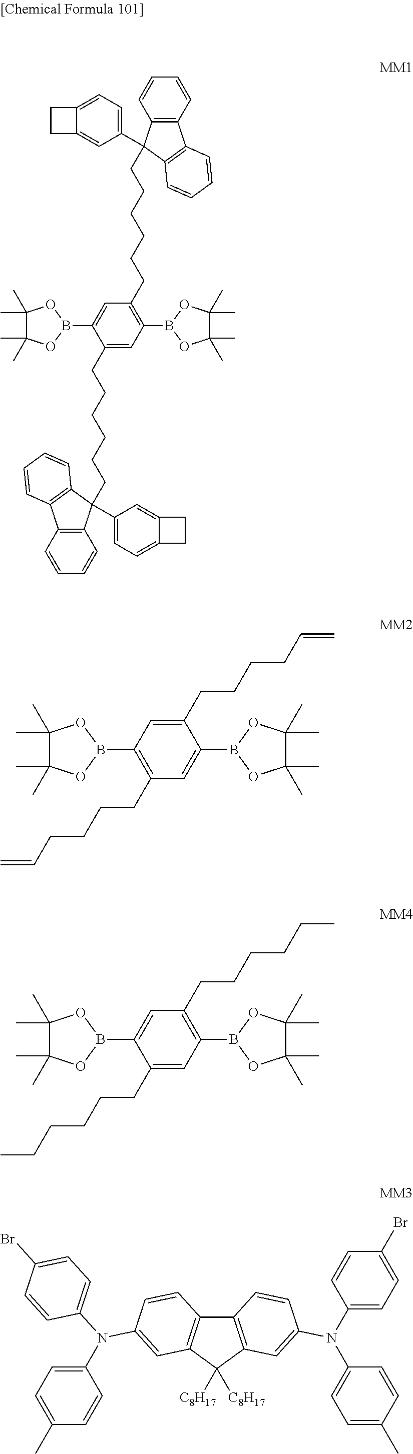

1.08 g of the polymer compound P2 was obtained by the same method as the synthesis of the polymer compound P1, except for altering (Step 1) in the synthesis of the polymer compound P1 to the following (Step 1-2).

(Step 1-2) The atmosphere of a reaction vessel was turned into an inert gas atmosphere, and then, the compound MM1 (0.51848 g), the compound MM2 (0.04955 g), the compound MMM4 (0.19480 g) described in Japanese Unexamined Patent Publication No. 2010-189630, the compound MM3 (0.91721 g), dichlorobis(tris-o-methoxyphenylphophine)palladium (1.76 mg) and toluene (30 mL) were added and heated to 105° C.

The polystyrene-equivalent number-average molecular weight of the polymer compound P2 was 2.5×10⁴, and the polystyrene-equivalent weight-average molecular weight thereof was 3.0×10⁵.

The polymer compound P2 is a copolymer constituted of a constitutional unit derived from the compound MM1, a constitutional unit derived from the compound MM2, a constitutional unit derived from the compound MM4, and a constitutional unit derived from the compound MM3 in a molar ratio of 25:5:20:50 on the theoretical value determined from amounts of raw materials fed. For the polymer compound P2, the average number of the crosslinkable groups per 1000 in molecular weight as calculated by the method described above was 0.95.

<2-12> Synthesis of a Polymer Compound P3

A polymer compound P3 was synthesized by the following method.

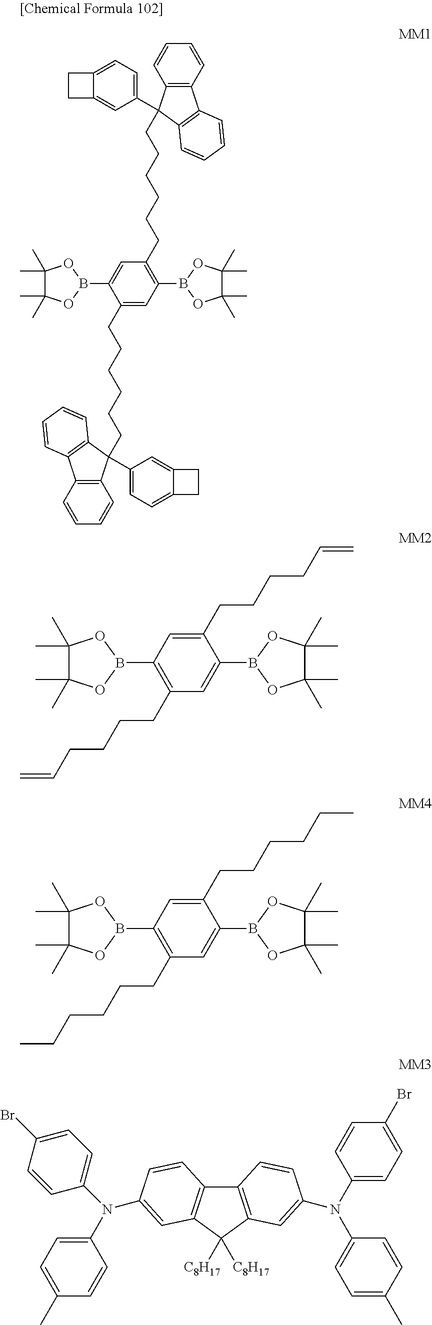

0.92 g of the polymer compound P3 was obtained by the same method as the synthesis of the polymer compound P1, except for altering (Step 1) in the synthesis of the polymer compound P1 to the following (Step 1-3).

(Step 1-3) The atmosphere of a reaction vessel was turned into an inert gas atmosphere, and then, the compound MM1 (0.31115 g), the compound MM2 (0.04959 g), the compound MM4 (0.29465 g), the compound MM3 (0.91719 g), dichlorobis(tris-o-methoxyphenylphophine)palladium (1.76 mg) and toluene (30 mL) were added and heated to 105° C.

The polystyrene-equivalent number-average molecular weight of the polymer compound P3 was 2.5×10⁴, and the polystyrene-equivalent weight-average molecular weight thereof was 1.3×10⁵.

The polymer compound P3 is a copolymer constituted of a constitutional unit derived from the compound MM1, a constitutional unit derived from the compound MM2, a constitutional unit derived from the compound MM4, and a constitutional unit derived from the compound MM3 in a molar ratio of 15:5:30:50 on the theoretical value determined from amounts of raw materials fed. For the polymer compound P3, the average number of the crosslinkable groups per 1000 in molecular weight as calculated by the method described above was 0.69.

<2-13> Synthesis of a Polymer Compound P4

A polymer compound P4 was synthesized by the following method.

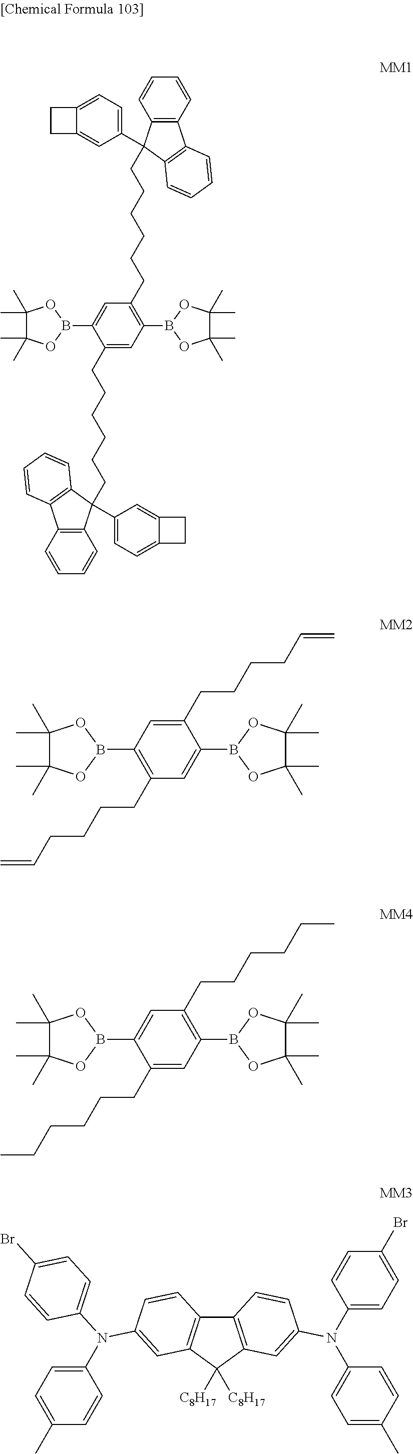

1.05 g of the polymer compound P4 was obtained by the same method as the synthesis of the polymer compound P1, except for altering (Step 1) in the synthesis of the polymer compound P1 to the following (Step 1-4), (Step 2) to the following (Step 2-2), and (Step 3) to the following (Step 3-2).

(Step 1-4) The atmosphere of a reaction vessel was turned into an inert gas atmosphere, and then, the compound MM1 (0.12976 g), the compound MM2 (0.06195 g), the compound MM4 (0.49334 g), the compound MM3 (1.14646 g), dichlorobis(tris-o-methoxyphenylphophine)palladium (2.20 mg) and toluene (30 mL) were added and heated to 105° C.

(Step 2-2) A 20-wt % tetraethylammonium hydroxide aqueous solution (8.3 mL) was dropped into the reaction solution, and refluxed for 6 hours.

(Step 3-2) After the reaction, phenylboronic acid (61.0 mg) and dichlorobis(triphenylphophine)palladium (1.1 mg) were added and refluxed for 14.5 hours.

The polystyrene-equivalent number-average molecular weight of the polymer compound P4 was 2.4×10⁴, and the polystyrene-equivalent weight-average molecular weight thereof was 1.8×10⁵.

The polymer compound P4 is a copolymer constituted of a constitutional unit derived from the compound MM1, a constitutional unit derived from the compound MM2, a constitutional unit derived from the compound MM4, and a constitutional unit derived from the compound MM3 in a molar ratio of 5:5:40:50 on the theoretical value determined from amounts of raw materials fed. For the polymer compound P4, the average number of the crosslinkable groups per 1000 in molecular weight as calculated by the method described above was 0.38.

(3) Other Polymer Compounds

<3-1> Synthesis of a Polymer Compound P5

A polymer compound P5 was synthesized by the following method.

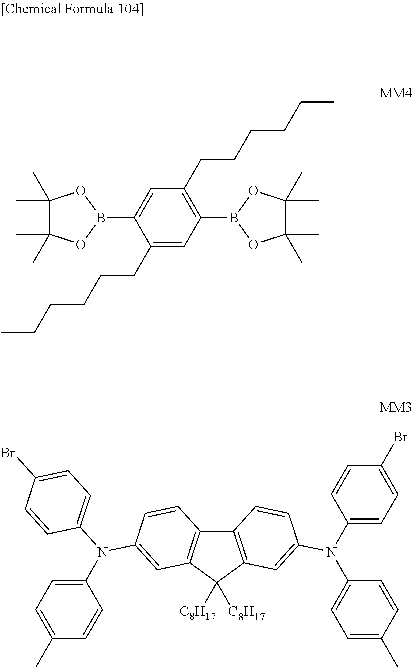

3.00 g of the polymer compound P5 was obtained by the same method as the synthesis of the polymer compound P1, except for altering (Step 1) in the synthesis of the polymer compound P1 to the following (Step 1-5), (Step 2) to the following (Step 2-3), and (Step 3) to the following (Step 3-3).

(Step 1-5) The atmosphere of a reaction vessel was turned into an inert gas atmosphere, and then, the compound MM4 (1.74 g), the compound MM3 (3.19 g), dichlorobis(triphenylphophine)palladium (2.5 mg) and toluene (40 mL) were added and heated to 80° C.

(Step 2-3) A 20-wt % tetraethylamrnonium hydroxide aqueous solution (12 mL) was dropped into the reaction solution, and refluxed for 8 hours.

(Step 3-3) After the reaction, phenylboronic acid (0.427 g) and dichlorobis(triphenylphophine)palladium (2.5 mg) were added and refluxed for 17 hours.

The polystyrene-equivalent number-average molecular weight of the polymer compound P5 was 4.5×10⁴, and the polystyrene-equivalent weight-average molecular weight thereof was 1.5×10⁵.

The polymer compound P5 is a copolymer constituted of a constitutional unit derived from the compound MM4 and a constitutional unit derived from the compound MM3 in a molar ratio of 50:50 on the theoretical value determined from amounts of raw materials fed. For the polymer compound P5, the average number of the crosslinkable groups per 1000 in molecular weight as calculated by the method described above was 0.

<3-2> Synthesis of a Polymer Compound E1

A polymer compound E1 was synthesized by the following method.

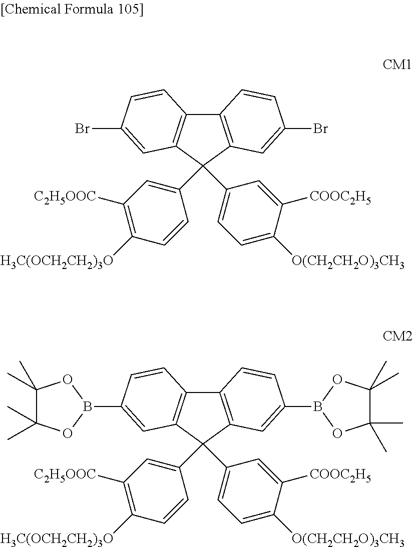

(Step 1) The atmosphere of a reaction vessel was turned into an inert gas atmosphere, and then, the compound CM1 (0.55 g) synthesized according to the method described in Japanese Unexamined Patent Publication No. 2012-33845, the compound CM2 (0.61 g) synthesized according to the method described in Japanese Unexamined Patent Publication No. 2012-33845, triphenylphophinepalladium (0.01 g), methyltrioctylammoniun chloride (manufactured by Sigma-Aldrich Corp., trade name: Aliquat 336®)(0.20 g) and toluene (10 mL) were added and heated to 105° C.

(Step 2) A 2M sodium carbonate aqueous solution (6 mL) was dropped into the reaction solution, and refluxed for 8 hours.

(Step 3) Thereafter, 4-ter-butylphenylboronic acid (0.01 g) was added thereto, and refluxed for 6 hours.

(Step 4) Thereafter, a sodium diethyldithiocarbamate aqueous solution (10 mL, concentration: 0.05 g/mL) was added thereto, and stirred for 2 hours. The resultant reaction solution was dropped into methanol (300 mL) and stirred for 1 hour. Thereafter, the deposited precipitate was filtrated, dried under reduced pressure for 2 hours, and dissolved in tetrahydrofuran (20 mL). The resultant solution was dropped into a mixed solvent of methanol (120 mL) and a 3-wt % acetic acid aqueous solution (50 mL), and stirred for 1 hour. Thereafter, the deposited precipitate was filtrated and dissolved in tetrahydrofuran (20 mL).

(Step 5) The resultant solution was dropped into methanol (200 mL) and stirred for 30 min. Thereafter, the deposited precipitate was filtrated. The resultant solid was dissolved in tetrahydrofuran, and thereafter, the resultant solution was passed through an alumina column and a silica gel column in order, to be purified. The resultant solution was dropped into methanol and stirred, and thereafter, the deposited precipitate was filtrated. The resultant solid was dried, to obtain 520 mg of a polymer compound E1.

The polystyrene-equivalent number-average molecular weight of the polymer compound E1 was 5.2×10⁴, and the polystyrene-equivalent weight-average molecular weight thereof was 1.5×10⁵.

The polymer compound E1 is a copolymer constituted of a constitutional unit derived from the compound CM1, and a constitutional unit derived from the compound CM2 in a molar ratio of 50:50 on the theoretical value determined from amounts of raw materials fed. Here, the structural units having the same structure were derived from the compound CM1 and the compound CM2.

<3-3> Synthesis of a Polymer Compound E2

The polymer compound E1 (200 mg) was added to a reaction vessel, and thereafter, the atmosphere of the reaction vessel was turned into a nitrogen gas atmosphere. Then, tetrahydrofuran (20 mL) and ethanol (20 mL) were added thereto, and heated to 55° C. Thereafter, a cesium hydroxide aqueous solution obtained by dissolving cesium hydroxide (200 mg) in water (2 mL) was added thereto, and stirred at 55° C. for 6 hours. The resultant reaction mixture was cooled to room temperature, and thereafter, the solvent was distilled off under reduced pressure. The resultant solid was washed with water, and thereafter dried under reduced pressure, to obtain a polymer compound E2 (150 mg). It was confirmed by ¹H-NMR analysis of the polymer compound E2 that the signal of ethyl ester sites in the polymer compound E2 disappeared and the reaction completed.

The polymer compound E2 is theoretically a copolymer consisting of a constitutional unit represented by the following.

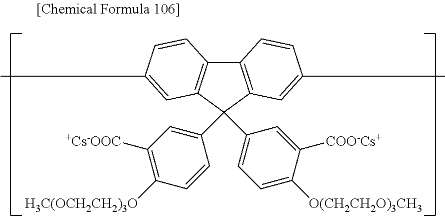

### [Example 1] Fabrication and Evaluation of a Light-Emitting Device 1

(Formation of an Anode and a Hole Injection Layer)

An ITO film was deposited with a thickness of 45 nm on a glass substrate by a sputtering method, to form an anode. A film of a polythiophene-sulfonic acid-based hole injection agent, AQ-1200 (manufactured by Plextronics, Inc.), was formed with a thickness of 35 nm on the anode, and heated in the air atmosphere on a hot plate at 170° C. for 15 min, to form a hole injection layer.

(Formation of a Hole Transporting Layer)

The polymer compound P1 was dissolved in a concentration of 0.7% by weight in xylene. By using the resultant xylene solution, a film was formed with a thickness of 20 nm on the hole injection layer by a spin coat method, and heated in a nitrogen gas atmosphere on a hot plate at 180° C. for 60 min, to form a hole transporting layer.

(Formation of a Light Emitting Layer)

2,8-Di(9H-carbazol-9-yl)dibenzo[b,d]thiophene (DCzDBT)(manufactured by Luminescence Technology Corp.) and the phosphorescent compound B1 (DCzDBT/phosphorescent compound B1=70 wt %/30 wt %) were dissolved in a concentration of 2.0% by weight in toluene. By using the resultant toluene solution, a film was formed with a thickness of 60 nm on the hole transporting layer by a spin coat method, and heated in a nitrogen atmosphere at 130° C. for 10 min, to form a light emitting layer.

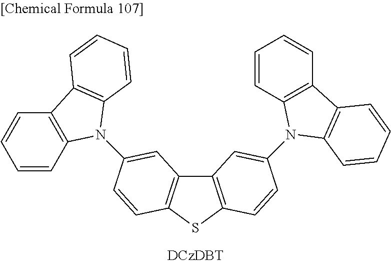 [SMILES: c1ccc2c(c1)c1ccccc1n2-c1ccc2sc3ccc(-n4c5ccccc5c5ccccc54)cc3c2c1]

(Formation of an Electron Transporting Layer)

The polymer compound E2 was dissolved in a concentration of 0.25% by weight in 2,2,3,3,4,4,5,5-octafluoro-1-pentanol. By using the resultant 2,2,3,3,4,4,5,5-octafluoro-1-pentanol solution, a film was formed with a thickness of 10 nm on the light emitting layer by a spin coat method, and heated in a nitrogen gas atmosphere at 130° C. for 10 min, to form an electron transporting layer.

(Formation of a Cathode)

The substrate having the electron transporting layer formed thereon was put in a vapor deposition machine whose pressure was then reduced to 1.0×10-4 Pa or less, and thereafter, as a cathode, sodium fluoride was vapor deposited in about 4 nm on the light emitting layer, and then, aluminum was vapor deposited in about 80 nm on the sodium fluoride layer. After the vapor deposition, the resultant was encapsulated with a glass substrate, to fabricate a light-emitting device 1.

(Evaluation of the Light-Emitting Device)

Electroluminescence was observed by applying a voltage to the light-emitting device 1. When the drive voltage was 3.4 [V], the highest external quantum efficiency was 2.3%, and the chromaticity coordinates (x, y) were (0.18, 0.38).

### [Example 2] Fabrication and Evaluation of a Light-Emitting Device 2

(Fabrication of a Light-Emitting Device)

A light-emitting device 2 was fabricated as in Example 1, except for using the polymer compound P2 in place of the polymer compound P1.

(Evaluation of the Light-Emitting Device)

Electroluminescence was observed by applying a voltage to the light-emitting device 2. When the drive voltage was 3.4 [V], the highest external quantum efficiency was 2.3%, and the chromaticity coordinates (x, y) were (0.19, 0.38).

### [Example 3] Fabrication and Evaluation of a Light-Emitting Device 3

(Fabrication of a Light-Emitting Device)

A light-emitting device 3 was fabricated as in Example 1, except for using the polymer compound P3 in place of the polymer compound P1.

(Evaluation of the Light-Emitting Device)

Electroluminescence was observed by applying a voltage to the light-emitting device 3. When the drive voltage was 3.4 [V], the highest external quantum efficiency was 1.9%, and the chromaticity coordinates (x, y) were (0.19, 0.38).

### [Comparative Example 1] Fabrication and Evaluation of a Light-Emitting Device C1

(Fabrication of a Light-Emitting Device)

A light-emitting device C1 was fabricated as in Example 1, except for using the polymer compound P4 in place of the polymer compound P1.

(Evaluation of the Light-Emitting Device)

Electroluminescence was observed by applying a voltage to the light-emitting device C1. When the drive voltage was 4.8 [V], the highest external quantum efficiency was 1.6%, and the chromaticity coordinates (x, y) were (0.20, 0.39).

The results of Examples 1 to 3 and Comparative Example 1 are shown in Table 3.

TABLE 3

| | | Hole transporting layer | | | |
|---|---|---|---|---|---|
| | | | Average | | External |
| | | Crosslinkable | number of | | quantum |
| | Light-emitting | polymer | crosslinkable | | efficiency |
| | device | compound | groups | Light emitting layer | (%) |
| Example 1 | Light-emitting | Polymer | 1.36 | DCzDBT/ | 2.3 |
| | device 1 | compound P1 | | phosphorescent | |
| Example 2 | Light-emitting | Polymer | 0.95 | compound B1 (mass | 2.3 |
| | device 2 | compound P2 | | ratio: 70/30) | |
| Example 3 | Light-emitting | Polymer | 0.69 | | 1.9 |
| | device 3 | compound P3 | | | |
| Comparative | Light-emitting | Polymer | 0.38 | | 1.6 |
| Example 1 | device C1 | compound P4 | | | |

### [Example 4] Fabrication and Evaluation of a Light-Emitting Device 4

(Fabrication of a Light-Emitting Device)

A light-emitting device 4 was fabricated as in Example 1, except for using the phosphorescent compound B2 in place of the phosphorescent compound B 1.

(Evaluation of the Light-Emitting Device)

Electroluminescence was observed by applying a voltage to the light-emitting device 4. When the drive voltage was 5.6 [V], the highest external quantum efficiency was 3.8%, and the chromaticity coordinates (x, y) were (0.18, 0.40).

### [Example 5] Fabrication and Evaluation of a Light-Emitting Device 5

(Fabrication of a Light-Emitting Device)

A light-emitting device 5 was fabricated as in Example 1, except for using the polymer compound P2 in place of the polymer compound P1 and using the phosphorescent compound B2 in place of the phosphorescent compound B 1.

(Evaluation of the Light-Emitting Device)

Electroluminescence was observed by applying a voltage to the light-emitting device 5. When the drive voltage was 5.8 [V], the highest external quantum efficiency was 3.2%, and the chromaticity coordinates (x, y) were (0.18, 0.40).

### [Example 6] Fabrication and Evaluation of a Light-Emitting Device 6

(Fabrication of a Light-Emitting Device)

A light-emitting device 6 was fabricated as in Example 1, except for using the polymer compound P3 in place of the polymer compound P1 and using the phosphorescent compound B2 in place of the phosphorescent compound B 1.

(Evaluation of the Light-Emitting Device)

Electroluminescence was observed by applying a voltage to the light-emitting device 6. When the drive voltage was 6.4 V, the highest external quantum efficiency was 2.2%, and the chromaticity coordinates (x, y) were (0.19, 0.40).

### [Comparative Example 2] Fabrication and Evaluation of a Light-Emitting Device C2

(Fabrication of a Light-Emitting Device)

A light-emitting device C2 was fabricated as in Example 1, except for using the polymer compound P4 in place of the polymer compound P1 and using the phosphorescent compound B2 in place of the phosphorescent compound B1.

(Evaluation of the Light-Emitting Device)

Electroluminescence was observed by applying a voltage to the light-emitting device C2. When the drive voltage was 6.6 [V], the highest external quantum efficiency was 1.8%, and the chromaticity coordinates (x, y) were (0.19, 0.40).

TABLE 4

| | | Hole transporting layer | | | |
|---|---|---|---|---|---|
| | | | Average | | External |
| | | Crosslinkable | number of | | quantum |
| | Light-emitting | polymer | crosslinkable | | efficiency |
| | device | compound | groups | Light emitting layer | (%) |
| Example 4 | Light-emitting | Polymer | 1.36 | DCzDBT/phosphorescent | 3.8 |
| | device 4 | compound P1 | | compound B2 (mass ratio: | |
| Example 5 | Light-emitting | Polymer | 0.95 | 70/30) | 3.2 |
| | device 5 | compound P2 | | | |
| Example 6 | Light-emitting | Polymer | 0.69 | | 2.2 |
| | device 6 | compound P3 | | | |
| Comparative | Light-emitting | Polymer | 0.38 | | 1.8 |
| Example 2 | device C2 | compound P4 | | | |

### [Example 7] Fabrication and Evaluation of a Light-Emitting Device 7

(Fabrication of a Light-Emitting Device)

A light-emitting device 7 was fabricated as in Example 1, except for using the phosphorescent compound B3 in place of the phosphorescent compound B1.

(Evaluation of the Light-Emitting Device)

Electroluminescence was observed by applying a voltage to the light-emitting device 7. When the drive voltage was 3.2 [V], the highest external quantum efficiency was 13.0%, and the chromaticity coordinates (x, y) were (0.18, 0.40).

### [Example 8] Fabrication and Evaluation of a Light-Emitting Device 8

(Fabrication of a Light-Emitting Device)

A light-emitting device 8 was fabricated as in Example 1, except for using the polymer compound P2 in place of the polymer compound P1 and using the phosphorescent compound B3 in place of the phosphorescent compound B1.

(Evaluation of the Light-Emitting Device)

Electroluminescence was observed by applying a voltage to the light-emitting device 8. When the drive voltage was 3.2 [V], the highest external quantum efficiency was 10.4%, and the chromaticity coordinates (x, y) were (0.18, 0.41).

### [Example 9] Fabrication and Evaluation of a Light-Emitting Device 9

(Fabrication of a Light-Emitting Device)

A light-emitting device 9 was fabricated as in Example 1, except for using the polymer compound P3 in place of the polymer compound P1 and using the phosphorescent compound B3 in place of the phosphorescent compound B1.

(Evaluation of the Light-Emitting Device)

Electroluminescence was observed by applying a voltage to the light-emitting device 9. When the drive voltage was 3.2 [V], the highest external quantum efficiency was 6.9%, and the chromaticity coordinates (x, y) were (0.19, 0.41).

### [Comparative Example 3] Fabrication and Evaluation of a Light-Emitting Device C3

(Fabrication of a Light-Emitting Device)

A light-emitting device C3 was fabricated as in Example 1, except for using the polymer compound P4 in place of the polymer compound P1 and using the phosphorescent compound B3 in place of the phosphorescent compound B1.

(Evaluation of the Light-Emitting Device)

Electroluminescence was observed by applying a voltage to the light-emitting device C3. When the drive voltage was 3.2 [V], the highest external quantum efficiency was 5.1%, and the chromaticity coordinates (x, y) were (0.19, 0.40).

### [Comparative Example 4] Fabrication and Evaluation of a Light-Emitting Device C4

(Fabrication of a Light-Emitting Device)

A light-emitting device C4 was fabricated as in Example 1, except for using the polymer compound P4 and the polymer compound P5 (polymer compound P4/polymer compound P5=50 wt %/50 wt %) in place of the polymer compound P1 and using the phosphorescent compound B3 in place of the phosphorescent compound B1.

(Evaluation of the Light-Emitting Device)

Electroluminescence was observed by applying a voltage to the light-emitting device C4. When the drive voltage was 3.2 [V], the highest external quantum efficiency was 5.3%, and the chromaticity coordinates (x, y) were (0.19, 0.41).

TABLE 5

| | | Hole transporting layer | | | |
|---|---|---|---|---|---|
| | | | Average | | External |
| | | | number of | | quantum |
| | Light-emitting | Crosslinkable polymer | crosslinkable | Light emitting | efficiency |
| | device | compound | groups | layer | (%) |
| Example 7 | Light-emitting | Polymer compound P1 | 1.36 | DCzDBT/phosphorescent | 13.0 |
| | device 4 | | | compound B3 | |
| Example 8 | Light-emitting | Polymer compound P2 | 0.95 | (mass ratio: | 10.4 |
| | device 5 | | | 70/30) | |
| Example 9 | Light-emitting | Polymer compound P3 | 0.69 | | 6.9 |
| | device 6 | | | | |
| Comparative | Light-emitting | Polymer compound P4 | 0.38 | | 5.1 |
| Example 3 | device C3 | | | | |
| Comparative | Light-emitting | Polymer compound P4/ | 0.19 | | 5.3 |
| Example 4 | device C4 | polymer compound P5 | | | |
| | | (weight ratio: 50/50) | | | |

### INDUSTRIAL APPLICABILITY

According to the present invention, a light-emitting device excellent in the external quantum efficiency is provided. The light-emitting device according to the present invention can suitably be utilized for planar light sources, displays and the like, and is excellent in the industrial applicability.

1. A light-emitting device, comprising:
an anode;
a cathode;
a first organic layer disposed between the anode and the cathode; and
a second organic layer disposed between the anode and the first organic layer and adjacent to the first organic layer,
wherein the first organic layer comprises a phosphorescent compound represented by the formula (1);
the second organic layer comprises a cured polymer product formed from a polymer composition in which one or two or more polymer compounds including a crosslinkable polymer compound having a crosslinkable group compounded; and
with respect to each monomer unit constituting the polymer compounds, a value x obtained by multiplying a molar ratio C of the each monomer unit to a total mol of all the monomer units by a molecular weight M of the each monomer unit, and a value y obtained by multiplying the molar ratio C by a number n of the crosslinkable groups in the each monomer unit are determined, a value of (Y₁×1000)/X₁ calculated from a total X₁ of the values x and a total Y₁ of the values y being 0.5 or more: 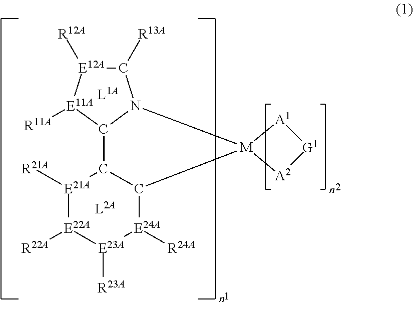
wherein,
M represents a ruthenium atom, a rhodium atom, a palladium atom, an iridium atom or a platinum atom;
n¹ represents an integer of 1 to 3, n² represents an integer of 0 to 2, and n¹+n² is 2 or 3; and n¹+n² is 3 when M is a ruthenium atom, a rhodium atom or an iridium atom, while n¹+n² is 2 when M is a palladium atom or a platinum atom;
E^{11A}, E^{12A}, E^{21A}, E^{22A}, E^{23A} and E^{24A} each independently represent a nitrogen atom or a carbon atom; when a plurality of E^{11A}, E^{12A}, E^{21A}, E^{22A}, E^{23A} and E^{24A} are present, they may be the same or different at each occurrence, provided that one of E^{11A} and E^{12A} is a carbon atom and the other is a nitrogen atom; and when E^{21A}, E^{22A}, E^{23A} and E^{24A} are nitrogen atoms, R^{21A}, R^{22A}, R^{23A} and R^{24A} are not present;
R^{11A}, R^{12A}, R^{13A}, R^{21A}, R^{22A}, R^{23A} and R^{24A} each independently represent a hydrogen atom, an alkyl group, a cycloalkyl group, an alkoxy group, a cycloalkoxy group, an aryl group, an aryloxy group, a monovalent heterocyclic group, a substituted amino group or a halogen atom, and these groups each optionally have a substituent; when a plurality of R^{11A}, R^{12A}, R^{13A}R^{21A}, R^{22A}, R^{23A} and R^{24A} are present, they may be the same or different at each occurrence; and R^{11A} and R^{12A}, R^{12A} and R^{13A}, R^{11A} and R^{21A}, R^{21A} and R^{22A}, R^{22A} and R^{23A}, and R^{23A} and R^{24A} each may be combined together to form a ring together with the atoms to which they are attached;
a ring L^{1A} represents an imidazole ring constituted of a nitrogen atom, two carbon atoms, E^{11A} and E^{12A};
a ring L^{2A} represents a benzene ring, a pyridine ring or a pyrimidine ring constituted of two carbon atoms, E^{21A}, E^{22A}, E^{23A} and E^{24A}; and
A¹-G¹-A² represents an anionic bidentate ligand; A¹ and A² each independently represent a carbon atom, an oxygen atom or a nitrogen atom, and these atoms may be atoms constituting a ring; G¹ represents a single bond, or an atomic group constituting the bidentate ligand together with A¹ and A²; and when a plurality of A-G¹-A² are present, they may be the same or different at each occurrence.

2. The light-emitting device according to claim 1, wherein the value of (Y₁×1000)/X₁ is 0.65 or more.

3. The light-emitting device according to claim 1, wherein at least one selected from the group consisting of the R^{11A}, R^{12A}, R^{13A}, R^{21A}, R^{22A}, R^{23A} and R^{24A} is a group represented by the formula (D-A) or (D-B): 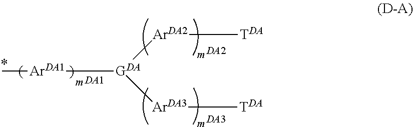
wherein,
m^{DA1}, m^{DA2} and m^{DA3} each independently represent an integer of 0 or more;
G^{DA} represents a nitrogen atom, an aromatic hydrocarbon group or a heterocyclic group, and these groups each optionally have a substituent;
Ar^{DA1}, Ar^{DA2} and Ar^{DA3} each independently represent an arylene group or a divalent heterocyclic group, and these groups each optionally have a substituent; and when a plurality of Ar^{DA1}, Ar^{DA2} and Ar^{DA3} are present, they may be the same or different at each occurrence; and
T^{DA} represents an aryl group or a monovalent heterocyclic group, and these groups each optionally have a substituent; and the plurality of T^{DA} may be the same or different; and
* represents a bonding position, and 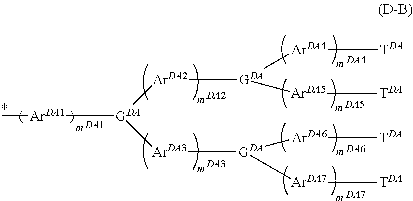
wherein,
m^{DA1}, m^{DA2}, m^{DA3}, m^{DA4}, m^{DA5}, m^{DA6} and m^{DA7} each independently represent an integer of 0 or more;
G^{DA} represents a nitrogen atom, an aromatic hydrocarbon group or a heterocyclic group, and these groups each optionally have a substituent, and the plurality of G^{DA} may be the same or different;
Ar^{DA1}, Ar^{DA2}, Ar^{DA3}, Ar^{DA4}, Ar^{DA5}, Ar^{DA6} and Ar^{DA7} each independently represent an arylene group or a divalent heterocyclic group, and these groups each optionally have a substituent; and when a plurality of Ar^{DA1}, Ar^{DA2}, Ar^{DA3}, Ar^{DA4}, Ar^{DA5}, Ar^{DA6} and Ar^{DA7} are present, they may be the same or different at each occurrence; and
T^{DA} represents an aryl group or a monovalent heterocyclic group, and these groups each optionally have a substituent, and the plurality of T^{DA} may be the same or different; and
* represents a bonding position.

4. The light-emitting device according to claim 1, wherein the phosphorescent compound is represented by the formula (1-1) or (1-2): 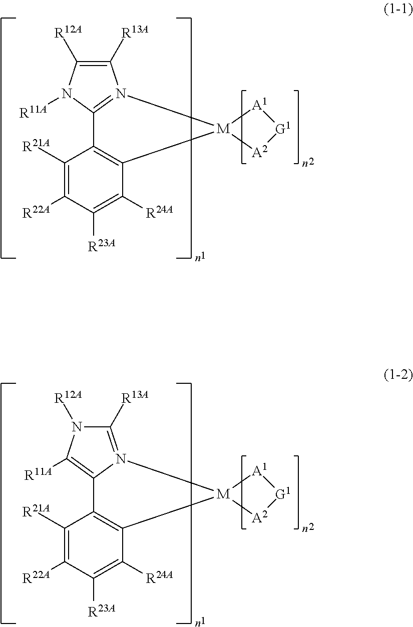
wherein M, n¹, n², R^{11A}, R^{12A}, R^{13A}, R^{21A}, R^{22A}, R^{23A}, R^{24A} and A¹-G¹-A² represent the same meanings as described above.

5. The light-emitting device according to claim 1, wherein the crosslinkable polymer compound comprises a constitutional unit represented by the formula (2): 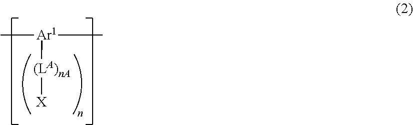
wherein,
nA represents an integer of 0 to 5, and n represents 1 or 2;
Ar¹ represents an aromatic hydrocarbon group or a heterocyclic group, and these groups each optionally have a substituent;
L^{A} represents an alkylene group, a cycloalkylene group, an arylene group, a divalent heterocyclic group, a group represented by —NR′—, an oxygen atom or a sulfur atom, and these groups each optionally have a substituent; R′ represents a hydrogen atom, an alkyl group, a cycloalkyl group, an aryl group or a monovalent heterocyclic group, and these groups each optionally have a substituent: and when a plurality of L^{A} are present, they may be the same or different; and
X represents a crosslinkable group, and when a plurality of X are present, they may be the same or different.

6. The light-emitting device according to claim 1, wherein the crosslinkable polymer compound comprises a constitutional unit represented by the formula (3): 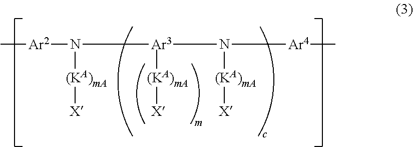
wherein,
mA represents an integer of 0 to 5, m represents an integer of 1 to 4, c represents 0 or 1, and when a plurality of mA are present, they may be the same or different;
Ar³ represents an aromatic hydrocarbon group, a heterocyclic group or a group in which at least one aromatic hydrocarbon ring and at least one heterocyclic ring are bonded directly to each other, and these groups each optionally have a substituent;
Ar² and Ar⁴ each independently represent an arylene group or a divalent heterocyclic group, and these groups each optionally have a substituent;
each of Ar², Ar³ and Ar⁴ may be bonded directly or via an oxygen atom or a sulfur atom to a group that is different from that group and that is attached to the nitrogen atom to which that group is attached, thereby forming a ring;
K^{A} represents an alkylene group, a cycloalkylene group, an arylene group, a divalent heterocyclic group, a group represented by —NR″—, an oxygen atom or a sulfur atom, and these groups each optionally have a substituent; and R″ represents a hydrogen atom, an alkyl group, a cycloalkyl group, an aryl group or a monovalent heterocyclic group, and these groups each optionally have a substituent; and when a plurality of K^{A} are present, they may be the same or different; and
X′ represents a crosslinkable group, a hydrogen atom, an alkyl group, a cycloalkyl group, an aryl group or a monovalent heterocyclic group, and these groups each optionally have a substituent; and when a plurality of X′ are present, they may be the same or different; provided that at least one X′ is a crosslinkable group.

7. The light-emitting device according to claim 1, wherein the polymer compound has at least one crosslinkable group selected from Group A of crosslinkable groups:
(Group A of crosslinkable groups) 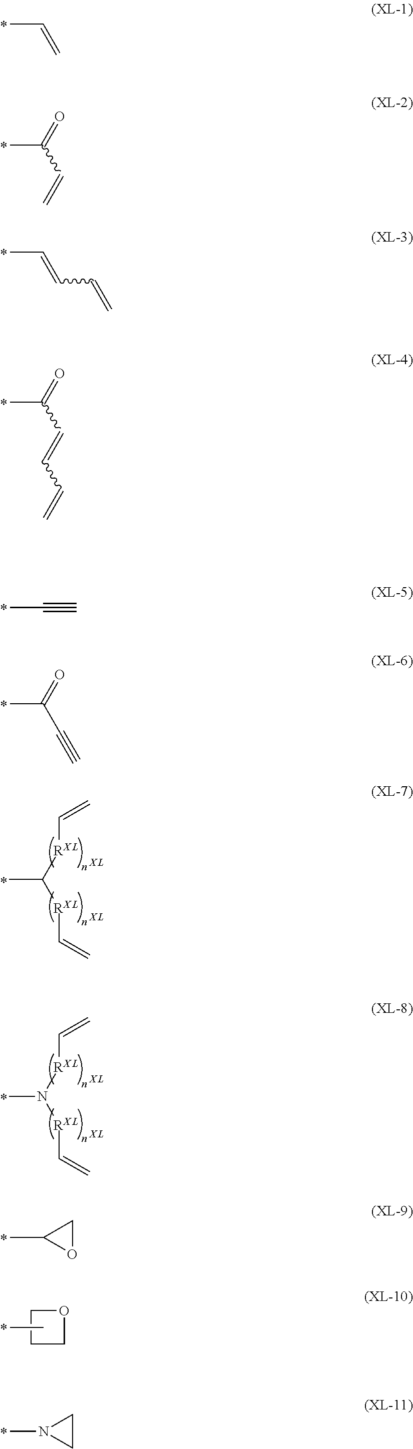 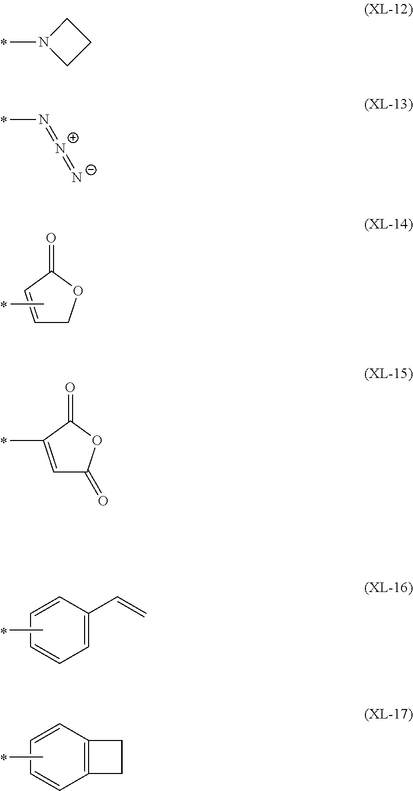
wherein R^{XL} represents a methylene group, an oxygen atom or a sulfur atom, and n^{XL} represents an integer of 0 to 5; when a plurality of R^{XL} are present, they may be the same or different; and when a plurality of n^{XL} are present, they may be the same or different; * represents a bonding position; and these crosslinkable groups each optionally have a substituent.

8. The light-emitting device according to claim 1, wherein the first organic layer further comprises a polymer compound comprising a constitutional unit represented by the formula (Y):
Ar^{Y1} (Y)
wherein A^{Y1} represents an arylene group, a divalent heterocyclic group or a divalent group in which at least one arylene group and at least one divalent heterocyclic group are bonded directly to each other, and these groups each optionally have a substituent.

9. The light-emitting device according to claim 1, wherein the first organic layer further comprises a compound represented by the formula (H-1): 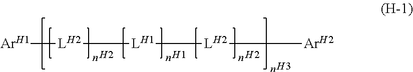
wherein,
Ar^{H1} and Ar^{H2} each independently represent an aryl group or a monovalent heterocyclic group, and these groups each optionally have a substituent;
n^{H1} and n^{H2} each independently represent 0 or 1; when a plurality of n^{H1} are present, they may be the same or different; and when a plurality of n^{H2} are present, they may be the same or different;
n^{H3} represents an integer of 0 or more;
L^{H1} represents an arylene group, a divalent heterocyclic group or a group represented by —[C(R^{H11})₂]n^{H11}—, and these groups each optionally have a substituent; and when a plurality of L^{H1} are present, they may be the same or different;
n^{H11} represents an integer of 1 to 10; R^{H11} represents a hydrogen atom, an alkyl group, a cycloalkyl group, an alkoxy group, a cycloalkoxy group, an aryl group or a monovalent heterocyclic group, and these groups each optionally have a substituent; the plurality of R^{H11} may be the same or different and may be combined together to form a ring together with the carbon atoms to which they are attached;
L^{H2} represents a group represented by —N(-L^{H21}-R^{H21})—; and when a plurality of L^{H2} are present, they may be the same or different; and
L^{H21} represents a single bond, an arylene group or a divalent heterocyclic group, and these groups each optionally have a substituent; and R^{H21} represents a hydrogen atom, an alkyl group, a cycloalkyl group, an aryl group or a monovalent heterocyclic group, and these groups each optionally have a substituent.
